(19) United States
(12) Patent Application Publication
(10) Pub. No.: US 2025/0056960 A1
(43) Pub. Date: Feb. 13, 2025

(54) LIGHT EMITTING DEVICE AND ELECTRONIC APPARATUS

(71) Applicant: Sony Semiconductor Solutions Corporations, Kanagawa (JP)

(72) Inventor: Isamu Kobori, Tokyo (JP)

(21) Appl. No.: 18/713,939

(22) PCT Filed: Jan. 5, 2023
(86) PCT No.: PCT/JP2023/000079

§ 371 Date: May 28, 2024

(30) Foreign Application Priority Data
Jan. 6, 2022 (JP) 2022-001008

(51) Int. Cl. H10K 50/13; H10K 50/19; H10K 59/35

(52) U.S. Cl. CPC H10K 50/13; H10K 50/19; H10K 59/351

(57) ABSTRACT

Display elements configured for light emitting element miniaturization and ease of manufacture are disclosed. In one example, a light emitting device includes a substrate, a first electrode, an organic layer, and a second electrode. The organic layer includes functional layers including a plurality of types of light emitting layers of different color types. In a case where the thickness direction of the substrate is set as a line-of-sight direction, a mixing layer is formed in at least a portion of the organic layer, with the portion extending in the plane direction of the organic layer.

### TECHNICAL FIELD

The present disclosure relates to a light emitting device and an electronic apparatus.

### BACKGROUND ART

There are organic EL display devices and the like that are known as light emitting devices using light emitting elements including organic light emitting diodes (OLED). For such light emitting devices, a technology for obtaining a light emitting element that emits light in the color corresponding to the color type of a sub-pixel is known.

Patent Document 1 discloses a technology for forming a structure in which light emitting layers corresponding to the respective emission colors of red, green, and blue are stacked as light emitting layers of an OLED. This technology uses laser irradiation. In this technology, a pixel of a predetermined color type is selectively subjected to a heating treatment using laser irradiation at a temperature determined in accordance with the color type of the pixel. In this manner, the emission color of the OLED is adjusted.

### CITATION LIST

### Patent Document

Patent Document 1: Japanese Patent Application Laid-Open No. 2015-15076

### SUMMARY OF THE INVENTION

### Problems to be Solved by the Invention

The technology according to Patent Document 1 has room for improvement, in terms of miniaturization of light emitting elements. This is because it is considered that, by the technology according to Patent Document 1, it is not easy to make light emitting elements smaller than the size of a light emitting element obtained at the limit of the aperture of the spot size of laser irradiation.

Also, it is considered that, by the technology according to Patent Document 1, laser irradiation is performed on individual pixels. Accordingly, as the number of pixels becomes larger, the number of steps at the time of manufacturing becomes larger, and the time required for manufacturing becomes longer. Therefore, the technology according to Patent Document 1 has room for improvement in terms of ease of manufacture.

The present disclosure has been made in view of the above aspects, and an object of the present disclosure is to provide a light emitting device that is capable of miniaturization of light emitting elements and has improved ease of manufacture, and an electronic apparatus.

### Solutions to Problems

The present disclosure relates to, for example,

(1) a light emitting device that includes:
a substrate; and
a first electrode, an organic layer, and a second electrode that are sequentially stacked on the substrate,
in which
the organic layer includes a plurality of functional layers including a plurality of types of light emitting layers of different color types, and,
in a case where the thickness direction of the substrate is set as a line-of-sight direction, a mixing layer is formed in at least a portion of the organic layer, the portion extending in the plane direction of the organic layer, the mixing layer being defined in accordance with the following conditions:
Conditions: In the organic layer, a first position and a second position are selected as two positions different in the plane direction of the organic layer, and the components of the organic layer at the first position and the second position are compared in the thickness direction of the organic layer. In that case, a layer in which components of the plurality of different functional layers forming the organic layer are mixed is observed only at either the first position or the second position. This layer is defined as the mixing layer.

The present disclosure may also relate to, for example, an electronic apparatus including the display device of (1) described above.

### BRIEF DESCRIPTION OF DRAWINGS

FIG. 1A is a plan view for explaining an example of a display device according to a first embodiment. FIG. 1B is an enlarged plan view schematically illustrating a state in which a dashed-line region XS in FIG. 1A is enlarged.

FIG. 2A is a plan view for explaining one pixel in an example of the display device according to the first embodiment.

FIG. 2B is a plan view for explaining a pixel in a case where insulating structures are not provided.

FIG. 3 is a view schematically illustrating a state of a longitudinal cross-section taken along line A-A defined in FIG. 2A.

FIG. 4 is a cross-sectional diagram for explaining an example of a mixing portion of an organic layer in an example of the display device according to the first embodiment.

FIG. 5 is a cross-sectional diagram for explaining an example of a non-mixing portion of an organic layer in an example of the display device according to the first embodiment.

FIG. 6 is a cross-sectional view for explaining an example of a display device according to Modification 1 of the first embodiment.

FIG. 7 is a plan view for explaining an example of a display device according to Modification 2 of the first embodiment.

FIG. 8 is a plan view for explaining an example of a display device according to Modification 3 of the first embodiment.

FIG. 9 is a cross-sectional view for explaining an example of the display device according to Modification 3 of the first embodiment.

FIG. 10 is a cross-sectional diagram for explaining an example of a display device according to Modification 4 of the first embodiment.

FIG. 11 is a plan view for explaining an example of a display device according to a second embodiment.

FIGS. 12A and 12B are plan views for explaining an example of the display device according to the second embodiment.

FIG. 13 is a cross-sectional diagram schematically illustrating a state of a longitudinal cross-section taken along the line B-B defined in FIG. 11.

FIG. 14 is a cross-sectional diagram for explaining an example of a mixing portion of an organic layer in an example of a display device according to a third embodiment.

FIG. 15 is a cross-sectional diagram for explaining an example of a non-mixing portion of an organic layer in an example of the display device according to the third embodiment.

FIG. 16 is a spectrum diagram for explaining the relationship between mixing regions and emission colors.

FIGS. 17A, 17B, and 17C are cross-sectional views for explaining sub-pixels in an example of a display device according to a fourth embodiment.

FIGS. 18A, 18B, and 18C are plan views for explaining sub-pixels in an example of the display device according to the fourth embodiment.

FIG. 19 is a plan view for explaining an example of adjacent sub-pixels in an example of the display device according to the fourth embodiment.

FIG. 20 is a cross-sectional view for explaining an example of adjacent sub-pixels in an example of the display device according to the fourth embodiment.

FIG. 21 is a cross-sectional view for explaining an example of an organic layer in an example of the display device according to the fourth embodiment.

FIGS. 22A, 22B, and 22C are cross-sectional views for explaining sub-pixels in an example of a display device according to Modification 1 of the fourth embodiment.

FIGS. 23A, 23B, and 23C are plan views for explaining sub-pixels in an example of the display device according to Modification 1 of the fourth embodiment.

FIG. 24 is a plan view for explaining an example of adjacent sub-pixels in an example of the display device according to Modification 1 of the fourth embodiment.

FIG. 25 is a cross-sectional view for explaining an example of adjacent sub-pixels in an example of the display device according to Modification 1 of the fourth embodiment.

FIG. 26 is a cross-sectional view for explaining an example of an organic layer in an example of the display device according to Modification 1 of the fourth embodiment.

FIG. 27 is a plan view for explaining an example of mixing regions formed in sub-pixels in an example of a display device according to Modification 2 of the fourth embodiment.

FIG. 28 is a plan view for explaining an example of mixing regions formed in sub-pixels in an example of the display device according to Modification 2 of the fourth embodiment.

FIGS. 29A, 29B, and 29C are cross-sectional views for explaining sub-pixels in an example of a display device according to a fifth embodiment.

FIGS. 30A, 30B, and 30C are plan views for explaining sub-pixels in an example of the display device according to the fifth embodiment.

FIG. 31 is a plan view for explaining an example of adjacent sub-pixels in an example of the display device according to the fifth embodiment.

FIG. 32 is a cross-sectional view for explaining an example of adjacent sub-pixels in an example of the display device according to the fifth embodiment.

FIG. 33 is a cross-sectional view for explaining an example of an organic layer in an example of the display device according to the fifth embodiment.

FIGS. 34A, 34B, and 34C are cross-sectional views for explaining sub-pixels in an example of a display device according to a modification of the fifth embodiment.

FIGS. 35A, 35B, and 35C are plan views for explaining sub-pixels in an example of the display device according to the modification of the fifth embodiment.

FIG. 36 is a plan view for explaining an example of adjacent sub-pixels in an example of the display device according to the modification of the fifth embodiment.

FIG. 37 is a cross-sectional view for explaining an example of adjacent sub-pixels in an example of the display device according to the modification of the fifth embodiment.

FIG. 38 is a cross-sectional view for explaining an example of an organic layer in an example of the display device according to the modification of the fifth embodiment.

FIGS. 39A and 39B are diagrams for explaining an example of a display device having resonator structures.

FIGS. 40A and 40B are diagrams for explaining an example of a display device having resonator structures.

FIGS. 41A and 41B are diagrams for explaining an example of a display device having resonator structures.

FIG. 42 is a diagram for explaining an example of a display device having resonator structures.

FIGS. 43A, 43B, and 43C are diagrams for explaining an example case where a display device includes wavelength selection units.

FIG. 44 is a diagram for explaining an example case where a display device includes wavelength selection units.

FIGS. 45A and 45B are diagrams for explaining an example case where a display device includes wavelength selection units.

FIG. 46 is a diagram for explaining an example case where a display device includes wavelength selection units.

FIGS. 47A and 47B are views for explaining an example application of a display device.

FIG. 48 is a view for explaining an example application of a display device.

FIG. 49 is a view for explaining an example application of a display device.

FIG. 50 is a view for explaining an example application of a display device.

FIG. 51 is a view for explaining an example application of a display device.

FIGS. 52A and 52B are views for explaining an example application of a display device.

### MODE FOR CARRYING OUT THE INVENTION

In the description below, an example and the like according to the present disclosure will be described with reference to the drawings. Note that explanation will be made in the following order. In the present specification and the drawings, components having substantially the same functional configurations are denoted by the same reference signs, and explanation of them will not be repeated.

Note that explanation will be made in the following order.
1. First Embodiment
2. Second Embodiment
3. Third Embodiment
4. Fourth Embodiment
5. Fifth Embodiment
6. Sixth Embodiment
7. Example cases where a display device has resonator structures
8. Examples of positional relationship in cases where a display device includes wavelength selection units
9. Example applications (electronic apparatuses)
10. Illuminating device
11. Display object

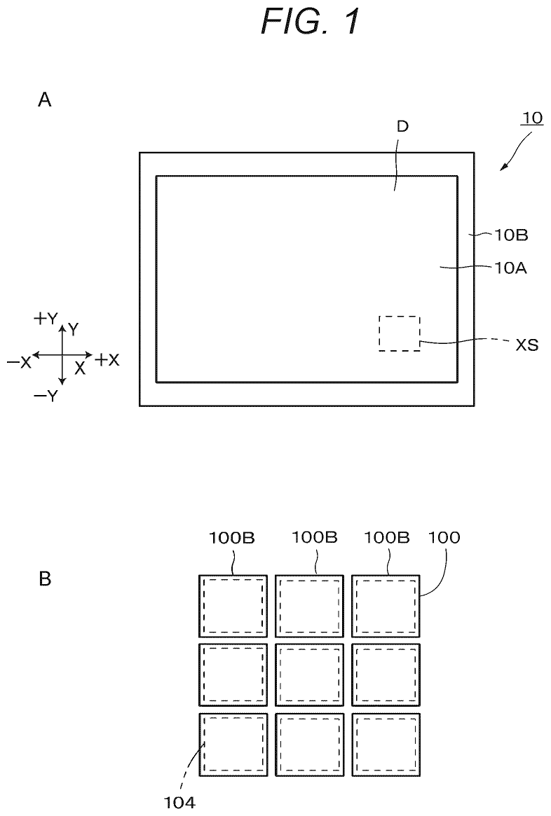

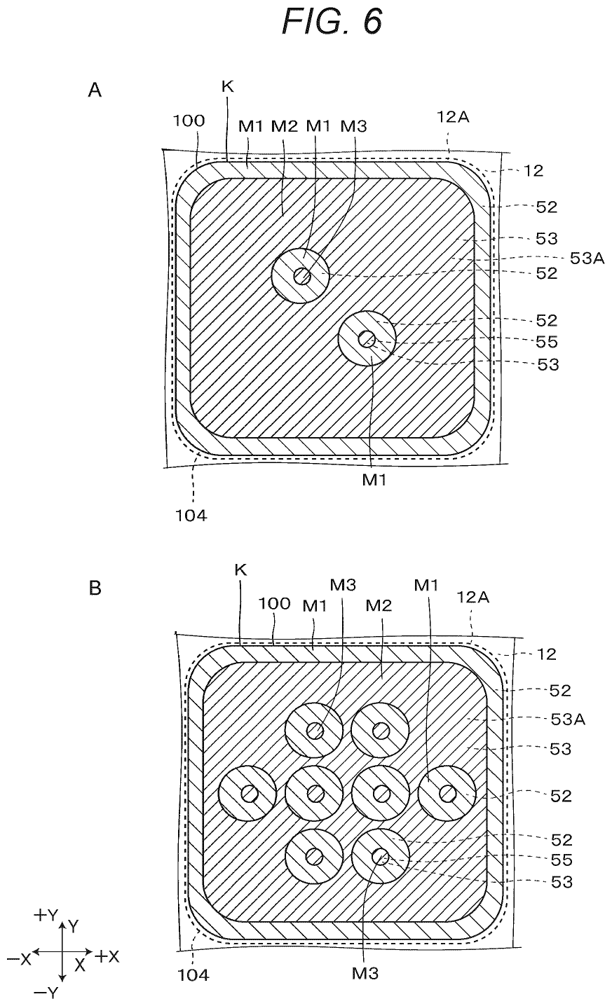

The following description concerns preferred specific examples of the present disclosure, and the contents of the present disclosure is not limited to these embodiments and the like. Also, in the following description, directions such as forward and backward, rightward and leftward, and upward and downward directions are used for ease of explanation, but the contents of the present disclosure are not limited by these directions. In examples in FIGS. 1, 2A, 2B, 3, 4, and 5, and others, it is assumed that the Z-axis direction is the upward and downward directions (the upper side is the +Z direction, and the lower side is the −Z direction), the X-axis direction is the forward and backward directions (the front side is the +X direction, and the back side is the −X direction), and the Y-axis direction is the rightward and leftward directions (the right side is the +Y direction, and the left side is the −Y direction). The explanation will be made on the basis of these directions. The same applies in FIGS. 6 to 42. A relative dimensional ratio of the size and thickness of each layer illustrated in each drawing of FIG. 1 and others is shown for convenience, and does not limit any actual dimensional ratios. This applies in each drawing of FIGS. 6 to 42 regarding the definitions of these directions and the dimensional ratios.

A light emitting device of the present disclosure may be used as a display device, or may be included in a display device, for example. In the description below, a case where a light emitting device is a display device, or more particularly, a case where a light emitting device is a display device including a light emitting element having an organic EL layer will be described as an example. Note that an organic EL layer is an organic electroluminescent layer. A light emitting element including an organic EL layer may be referred to as an organic light emitting diode (OLED) or an organic EL element.

### 1 First Embodiment

### [1-1 Configuration of a Display Element]

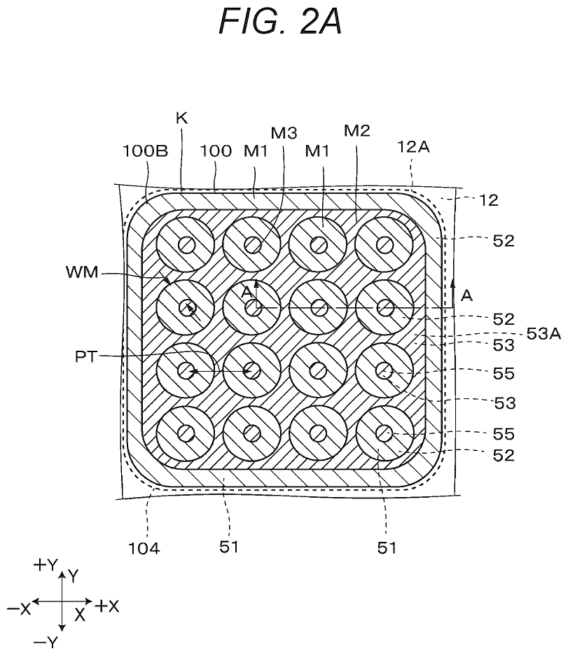

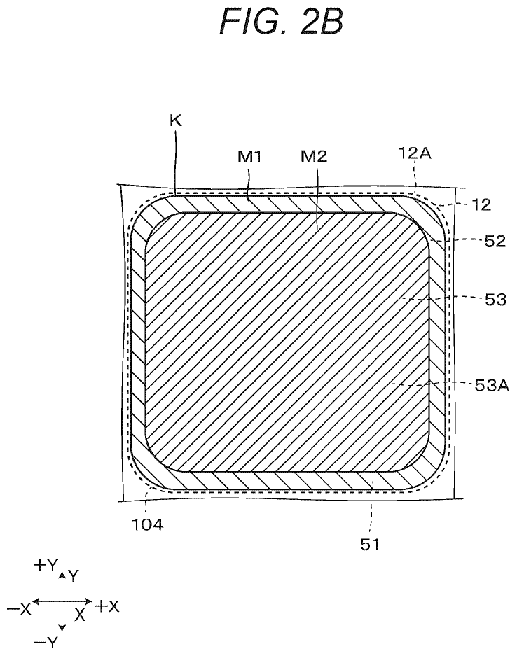

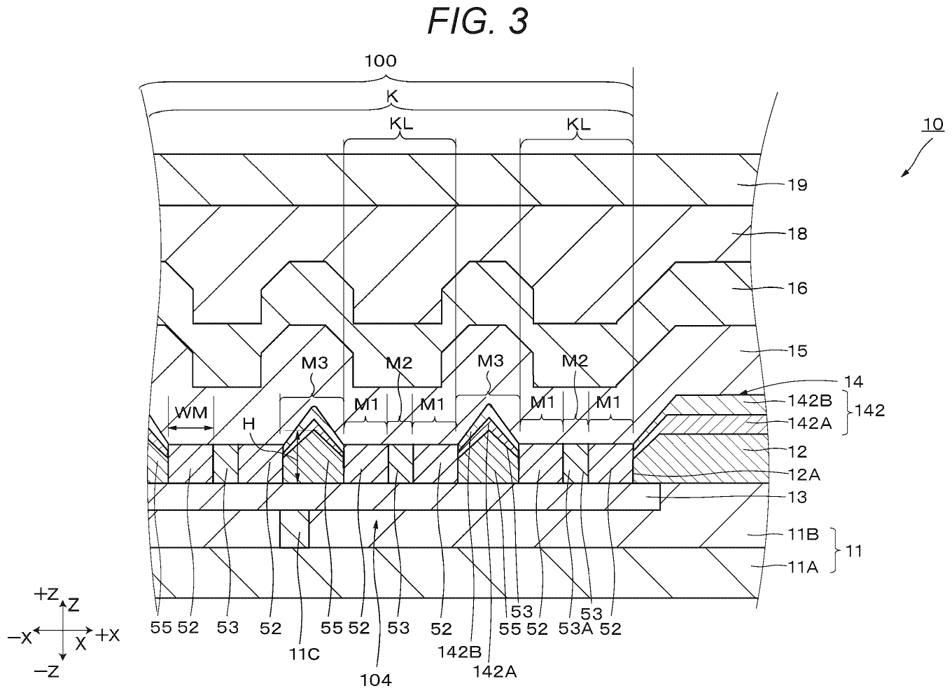

An organic EL (OLED) display element (hereinafter referred to simply as a “display device 10”) as an example of a display element according to an embodiment of the present disclosure is described below with reference to FIGS. 1, 2A, and 3, and others. FIG. 1 is a plan view illustrating an example configuration of the display device 10. FIG. 2A is a plan view illustrating the configuration of a pixel. FIG. 3 is a cross-sectional view for explaining the display device 10. FIG. 2A is a plan view illustrating a mixing portion 52 and the formation region thereof (a mixing region M1), and a first portion 53A of a non-mixing portion 53 and the formation region thereof (a non-mixing light emitting region M2), which will be described later. In FIG. 2A, the mixing region M1, the non-mixing light emitting region M2, and a no-light emitting region M3 formed in a counter region K corresponding to the region of one pixel 100 are indicated by solid lines and hatching. Also, in FIG. 2A, for ease of explanation, the portion in which a mixing layer 51 is formed is also shown, and a portion corresponding to a light emitting element 104 is indicated by a dashed line.

As illustrated in FIGS. 1, 2A, and 3, the display device 10 includes a drive substrate 11 that has the light emitting elements 104 and a light emitting surface D.

### (Display Region and Outer Region)

In the display device 10, a display region 10A and an outer region 10B are defined on the side of the light emitting surface D. The display region 10A is defined as the region where light generated from a plurality of light emitting elements 104 is emitted to the outside. The outer region 10B is defined as the region outside the display region 10A on the surface of a substrate 11A on the side of the light emitting surface D. In the example in FIG. 1A, the display region 10A is formed as a rectangular region, and, further, the region defined as a rectangular annular region outside the display region 10A is the outer region 10B. The position of the outer edge of the display region 10A is the position of the inner peripheral edge of the outer region 10B, and the display region 10A and the outer region 10B are in contact with each other at the boundary. Note that, among the surfaces of the substrate 11A, the light emitting surface D indicates the surface from which light generated from the light emitting elements 104 is extracted to the outside in the display device 10.

In the description below, a case where the display device 10 performs display by a top emission method is explained as an example. The top emission method indicates a method by which the light emitting elements 104 are disposed on the side of the light emitting surface D rather than the side of the substrate 11A. Accordingly, in the display device 10, the substrate 11A is located on the back surface side of the display device 10, and the direction (+Z direction) from the substrate 11A toward the light emitting elements 104 described later is the direction toward the front surface side (upper surface side) of the display device 10. In the display device 10, light generated from the light emitting elements 104 is directed in the +Z direction, and is emitted to the outside. In the description below, in each of the layers constituting the display device 10, the surface on the display surface side in the display region (display region 10A) of the display device 10 will be referred to as the first surface (upper surface), and the surface on the back surface side of the display device 10 will be referred to as the second surface (lower surface). Note that this does not exclude any case where the display device 10 according to the present disclosure is of a bottom emission type. The display device 10 is also applicable to a bottom emission type. By a bottom emission method, light generated from the light emitting elements 104 is directed in the −Z direction, and is emitted to the outside.

### (Configuration of Pixels)

In the example of the display device 10 illustrated in FIGS. 1A and 1B, each one pixel is formed as a pixel corresponding to one color type. In this example, blue is defined as a plurality of color types, and pixels 100B are provided as the pixels that perform blue-color display. However, the example in FIG. 1B is merely an example, and does not limit the color types of the pixels. Further, the wavelengths of light corresponding to the blue color types can be defined as wavelengths in the range of 440 nm to 480 nm, for example. Furthermore, the layout of the individual pixels 100B can be a layout in which pixels 100 each formed in a rectangular shape are arranged in a matrix fashion, for example. In the example in FIG. 1B, the pixels 100B are two-dimensionally provided in the display region 10A.

In a case where each pixel 100 includes a plurality of types of sub-pixels 101 as described later in Modifications 2 and 3 of the first embodiment and others, the components adopted for one pixel 100 are only required to be adopted for one sub-pixel 101. The same applies in the second and third embodiments described later.

### (Drive Substrate)

As illustrated in FIG. 3, in the drive substrate 11, an insulating layer 11B is provided on the substrate 11A, and various circuits for driving the plurality of light emitting elements 104 are provided in the insulating layer 11B. Examples of the various circuits include a drive circuit that controls driving of the light emitting elements 104, and a power supply circuit that supplies power to the plurality of light emitting elements 104 (none of which is shown in the drawings). The various circuits are restricted from being exposed to the outside by the insulating layer 11B. Also, the drive substrate 11 has a plurality of contact plugs 11C for connecting the light emitting elements 104 and the circuits and the wiring lines provided on the substrate 11A to first electrodes 13 and the like.

The substrate 11A may be formed with glass or resin having low moisture and oxygen permeability, or may be formed with a semiconductor in which transistors and the like are easily formed, for example. Specifically, the substrate 11A may be a glass substrate, a semiconductor substrate, a resin substrate, or the like.

### (Insulating Layer)

The insulating layer 11B is formed with an organic material or an inorganic material, for example. The organic material contains at least one material of polyimide or acrylic resin, for example. The inorganic material contains at least one material of silicon oxide, silicon nitride, silicon oxynitride, or aluminum oxide, for example.

### (Light Emitting Elements)

A plurality of light emitting elements 104 is disposed on the first surface of the drive substrate 11. In the examples in FIGS. 1B, 2, and 3, and others, the light emitting elements 104 are organic electroluminescence elements (organic EL elements). Also, in this example, light emitting elements that emit blue light corresponding to the pixels 100B as the light emitted from the light emitting surface are provided as the plurality of light emitting elements 104. The plurality of light emitting elements 104 is two-dimensionally arranged in a prescribed arrangement pattern such as a matrix form or the like, for example.

The light emitting elements 104 each include a first electrode 13, an organic layer 14, and a second electrode 15. The first electrode 13, the organic layer 14, and the second electrode 15 are stacked in this order in the direction from the side of the drive substrate 11 in the direction from the second surface toward the first surface.

### (First Electrodes)

A plurality of the first electrodes 13 is provided on the first surface side of the drive substrate 11. In the example in FIG. 3, the first electrodes 13 are anode electrodes.

The first electrodes 13 each include at least one of a metal layer or a metal oxide layer. The first electrodes 13 may each include a single-layer film of a metal layer or a metal oxide layer, or a film stack of a metal layer and a metal oxide layer.

The metal layer contains at least one metal element selected from the group consisting of chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag), for example. The metal layer may contain the at least one metal element described above as a constituent element of an alloy. Specific examples of the alloy include an aluminum alloy and a silver alloy. Specific examples of the aluminum alloy include AlNd and AlCu, for example.

The metal oxide layer contains at least one of a mixture of indium oxide and tin oxide (ITO), a mixture of indium oxide and zinc oxide (IZO), or titanium oxide (TiO), for example.

In FIG. 2, the first electrodes 13 are electrically separated for the respective pixels 100. That is, a plurality of the first electrodes 13 is provided on the first surface side of the drive substrate 11, and is provided for the respective pixels 100.

Further, a layer having insulating properties is preferably formed between adjacent first electrodes 13. In the example in FIG. 2, an insulating layer 12 is formed between adjacent first electrodes 13. However, the insulating layer 12 may be a layer formed with the same material as the insulating layer 11B, or may be a layer formed with a material different from the insulating layer 11B. In a case where the insulating layer 12 is the same as the insulating layer 11B, the insulating layer 12 may be integrated with the insulating layer 11B. In the example in FIG. 3 and others, the insulating layer 12 electrically insulates each first electrode 13 for each corresponding light emitting element 104 (that is, for each corresponding pixel 100). Also, as illustrated in FIG. 3, openings 12A are formed in the insulating layer 12 on the first surface side, the first surfaces of the first electrodes 13 (the surfaces facing the second electrode 15) are exposed through the openings 12A of the insulating layer 12, and the portions of the first electrodes 13 exposed through the openings 12A face the organic layer 14 described later while avoiding interposition of the insulating layer 11B. At this point of time, the region where the portions of the first electrodes 13 exposed through the openings 12A face the organic layer 14 while avoiding interposition of the insulating layer 11B is defined as the counter region K. Note that the insulating layer 11B may be formed not only between the adjacent first electrodes 13, but also onto the edges of the first electrodes 13. The edge portion of each first electrode 13 is defined by a portion from the outer peripheral edge of the first electrode 13 to a predetermined position closer to the center side of the first electrode 13. In this case, the insulating layer 11B also has the openings 12A, and the first surfaces of the first electrodes 13 are exposed through the openings 12A.

### (Organic Layer)

The organic layer 14 is disposed between the first electrodes 13 and the second electrode 15. The organic layer 14 is provided as a layer shared among the pixels 100. In the example in FIGS. 1, 2, and 3, the organic layer 14 is shared among the individual pixels 100B.

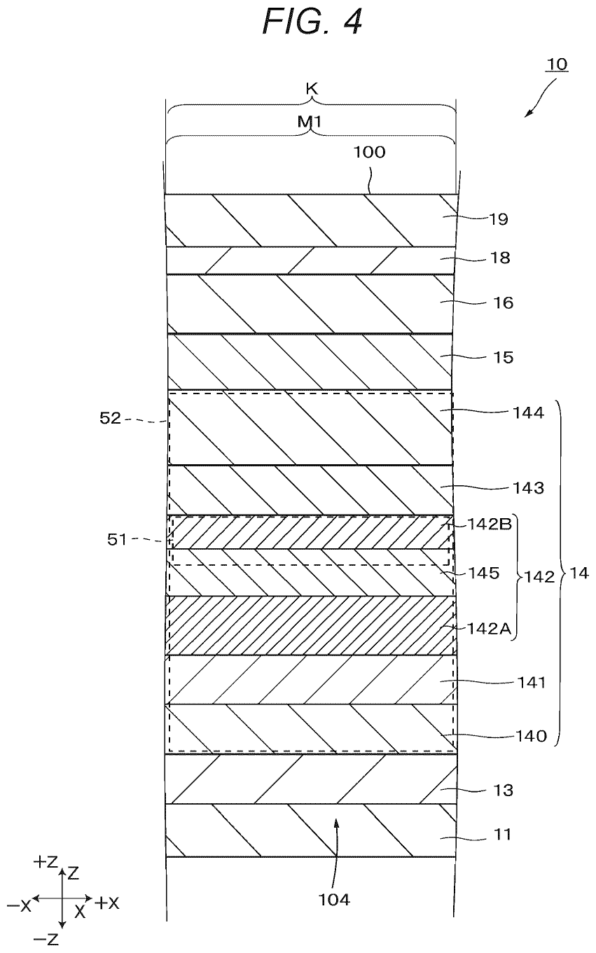

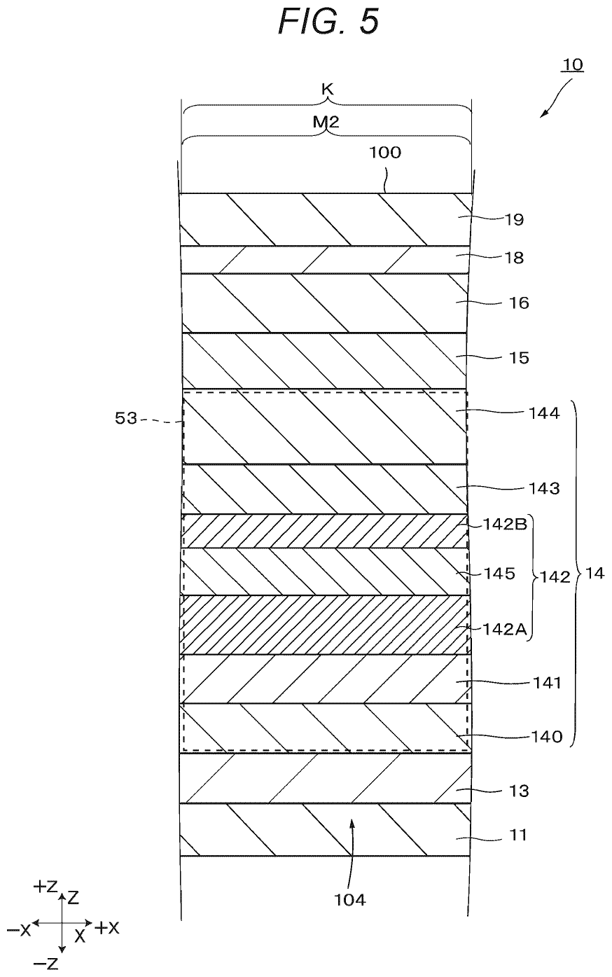

The organic layer 14 includes a plurality of functional layers including a plurality of types of light emitting layers that differ in color type. In the example illustrated in FIGS. 3, 4, and 5, the organic layer 14 has a configuration in which a hole injection layer 140, a hole transport layer 141, a light emitting layer 142, and an electron transport layer 143 are stacked in this order in the direction from the first electrode 13 toward the second electrode 15 (from the side closer to the first electrode 13). An electron injection layer 144 may be disposed between the electron transport layer 143 and the second electrode 15, as illustrated in FIGS. 4 and 5. In this case, the organic layer 14 includes the hole injection layer 140, the hole transport layer 141, the light emitting layer 142, the electron transport layer 143, and the electron injection layer 144 as the functional layers. Note that, in FIG. 3, for ease of explanation, the respective layers, except for the light emitting layer 142, are not shown in the portion of the organic layer 14 formed outside the counter region K and the portions of the organic layer 14 corresponding to no-light emitting regions M3 in a plan view of the display device 10 (in a case where the thickness direction of the substrate 11A is the line-of-sight direction). Also, regarding the portion of the organic layer 14 formed inside the counter region K, mixing portions 52 and non-mixing portions 53 described later are shown, and the respective layers in each portion of the mixing portions 52 and the non-mixing portions 53 are not shown. FIG. 4 is a cross-sectional diagram schematically illustrating the respective layer components in a mixing portion 52 in the organic layer 14, and the layer components before the formation of the mixing layer 51 are indicated by solid lines, and the mixing layer 51 is indicated by a dashed line. FIG. 5 is a cross-sectional diagram schematically illustrating the configuration of the respective layers in a non-mixing portion 53 in the organic layer 14.

The electron injection layer 144 is for increasing electron injection efficiency. Examples of the material of the electron injection layer 144 can include a simple substance of an alkali metal or an alkaline earth metal, such as lithium or lithium fluoride, and a compound including those simple substances.

The hole injection layer 140 is a buffer layer for enhancing efficiency of hole injection into the light emitting layer 142 and reducing leakage. Examples of the material of the hole injection layer 140 can include hexaazatriphenylene (HAT). The hole transport layer 141 is for enhancing efficiency of hole transport to the light emitting layer 142. Examples of the material of the hole transport layer 141 can include N,N′-di(1-naphthyl)-N,N′-diphenyl-1,1′-biphenyl-4,4′-diamine (α-NPD).

The electron transport layer 143 is for enhancing efficiency of electron transport to the light emitting layer 142. Examples of the material of the electron transport layer 143 can include aluminum quinolinol, bathophenanthroline, and the like.

In the first embodiment, the organic layer 14 includes a plurality of types of light emitting layers 142 that differ in color type. For example, the light emitting layer 142 includes a first light emitting layer 142A and a second light emitting layer 142B. Further, the organic layer 14 includes an intermediate layer 145 between the first light emitting layer 142A and the second light emitting layer 142B. The organic layer 14 has a configuration in which the hole injection layer 140, the hole transport layer 141, the first light emitting layer 142A, the intermediate layer 145, the second light emitting layer 142B, and the electron transport layer 143 are stacked in this order in the direction from the first electrode 13 toward the second electrode 15. Note that, in the present specification, in a case where the first light emitting layer 142A and the second light emitting layer 142B are not distinguished from each other, the first light emitting layer 142A and the second light emitting layer 142B are collectively referred to as the light emitting layers 142.

The light emitting layers 142 generate light by recombination of electrons and holes when an electric field is applied. The light emitting layers 142 are organic compound layers containing an organic light emitting material.

### (First Light Emitting Layer and Second Light Emitting Layer)

In the example illustrated in FIGS. 4 and 5, the first light emitting layer 142A is a blue light emitting layer having blue as its emission color. The second light emitting layer 142B is a yellow light emitting layer having yellow as its emission color.

### (Blue Light Emitting Layer)

In the blue light emitting layer, when an electric field is applied, some of holes injected from the first electrode 13 through the hole injection layer 140 and the hole transport layer 141, and some of electrons injected from the second electrode 15 through the electron transport layer 143 are recombined to generate blue light. The blue light emitting layer contains at least one of a blue light emitting material, a hole transport material, an electron transport material, or both-charges transport material, for example. The blue light emitting material may be a fluorescent material or a phosphorescent material, but a fluorescent material is preferably used to facilitate formation of the mixing layer 51 described later. Specifically, the blue light emitting layer can be a layer formed with a mixture of DPVBi and 2.5 wt % of 4,4′-bis[2-{4-(N,N-diphenylamino) phenyl}vinyl]biphenyl (DPAVBi), for example. In a case where the blue light emitting material is a fluorescent material, the first light emitting layer 142A is a fluorescent light emitting layer.

### (Yellow Light Emitting Layer)

In the yellow light emitting layer, when an electric field is applied, some of holes injected from the first electrode 13 through the hole injection layer 140 and the hole transport layer 141, and some of electrons injected from the second electrode 15 through the electron transport layer 143 are recombined to generate yellow light. The yellow light emitting layer contains at least one of a yellow light emitting material, a hole transport material, an electron transport material, or both-charges transport material, for example. As the yellow light emitting material, a phosphorescent material is preferably used to facilitate the formation of the mixing layer 51 described later. In a case where the yellow light emitting material is a fluorescent material, the second light emitting layer 142B is a phosphorescent light emitting layer.

### (Intermediate Layer)

The intermediate layer 145 is a layer for adjusting injection of carriers into the light emitting layers 142, and electrons or holes are injected into each of the layers constituting the light emitting layers 142 through the intermediate layer 145, so that balance of emission among the respective colors is adjusted. The intermediate layer 145 is formed with a 4,4′-bis [N-(1-naphthyl)-N-phenyl-amino]biphenyl derivative, or the like, for example.

In the intermediate layer 145, the energy level at the T1 level (lowest triplet excited state) of the intermediate layer 145 is preferably higher than the energy level at the T1 level of the second light emitting layer 142B, and the energy level at the S1 level (primary electron excited state) of the intermediate layer 145 is preferably higher than the energy level at the S1 level of the first light emitting layer 142A. As such an intermediate layer 145 is formed, light emission by the component (the yellow light emitting material or the like) that causes light emission from the second light emitting layer 142B and the component (the blue light emitting material or the like) that causes light emission from the first light emitting layer 142A can be efficiently achieved.

### (Second Electrode)

In the light emitting element 104, the second electrode 15 is disposed to face the first electrodes 13. The second electrode 15 is provided as an electrode shared among the plurality of pixels 100. The second electrode 15 is a cathode electrode. The second electrode 15 is preferably a transparent electrode having transparency to light generated in the organic layer 14. The transparent electrode herein may be a transparent electrode formed with a transparent conductive layer, or a transparent electrode formed with a stack structure including a transparent conductive layer and a semi-transmissive reflective layer.

As the transparent conductive layer, a transparent conductive material having good optical transparency and a small work function is preferably used. The transparent conductive layer can be formed with a metal oxide, for example. Specifically, examples of the material of the transparent conductive layer can include a material containing at least one of a mixture of indium oxide and tin oxide (ITO), a mixture of indium oxide and zinc oxide (IZO), or zinc oxide (ZnO).

The semi-transmissive reflective layer can be formed with a metal layer, for example. Specifically, examples of the material of the semi-transmissive reflective layer can include a material containing at least one metal element selected from the group consisting of magnesium (Mg), aluminum (Al), silver (Ag), gold (Au), and copper (Cu). The metal layer may contain the at least one metal element described above as a constituent element of an alloy. Specific examples of the alloy include a MgAg alloy, an AgPdCu alloy, and the like.

### (Protective Layer)

In the example illustrated in FIG. 2, a protective layer 16 is preferably formed so as to cover the first surfaces of the light emitting elements 104. The protective layer 16 shields the light emitting elements 104 from the outside air, and prevents moisture from entering the light emitting elements 104 from the external environment.

The protective layer 16 is formed with an insulating material. As the insulating material, thermosetting resin or the like can be used, for example. Other than that, the insulating material may be SiO, SiON, AlO, TiO, or the like. In this case, examples of the protective layer 16 include a CVD film containing SiO, SiON, or the like, and an ALD film containing AlO, TiO, SiO, or the like. Note that a CVD film means a film formed by chemical vapor deposition. An ALD film means a film formed by atomic layer deposition.

### (Counter Substrate)

A counter substrate 19 may be provided on the first surface side of the light emitting elements 104. As the material of the counter substrate, the material of the substrate 11A of the drive substrate 11 or the like can be used. For example, a glass substrate can be used as the counter substrate. The material of the glass substrate is not limited to any particular material, as long as the glass substrate is formed with a material that transmits light emitted from the organic layer 14. Examples of the material of the glass substrate include various glass substrates such as high strain point glass, soda glass, borosilicate glass, and lead glass, and quartz substrates.

### (Mixing Portions)

In the light emitting element 104 in each pixel 100, a mixing portion 52 is formed.

The mixing portion 52 is observed at least in a portion of the organic layer 14 in a case where the thickness direction of the substrate 11A is the line-of-sight direction.

As illustrated in FIG. 3, the mixing portions 52 indicate portions (sections) in which the mixing layer 51 is formed in the organic layer 14 in a plan view of the pixels 100 (in a case where the thickness direction of the substrate 11A is the line-of-sight direction).

The mixing portions 52 are defined in accordance with the portions in which the mixing layer 51 is formed. For example, if the mixing layer 51 is formed in a discrete layout, the mixing portions 52 are also formed in a discrete layout corresponding to the layout of the mixing layer 51.

### (Mixing Layer)

In the display device 10, in a case where the thickness direction of the substrate 11A is the line-of-sight direction, the mixing layer 51 is formed at least in a portion extending in the plane direction of the organic layer 14. The mixing layer 51 is a layer that is specified on the basis of the following conditions (prescribed conditions).

Prescribed conditions: In the organic layer, a first position and a second position are selected as two positions different in the plane direction of the organic layer, and the components of the organic layer at the first position and the second position are compared in the thickness direction of the organic layer. In that case, a layer in which components of the different functional layers forming the organic layer are mixed is observed only at either the first position or the second position. This layer is defined as the mixing layer.

For example, in a case where the first position is selected from a mixing region M1 described later as illustrated in FIG. 4, and the second position is selected from a non-mixing light emitting region M2 described later as illustrated in FIG. 5 as different positions in the plane direction of the organic layer 14, a layer obtained by mixing a component (organic material) forming the electron transport layer 143 and a component (organic material) forming the second light emitting layer 142B in the layers constituting the organic layer 14 is observed at the first position. This layer is not observed at the second position. In this case, the layer that is observed at the first position is defined as the mixing layer 51.

Note that the mixing layer 51 may be a layer in which components are mixed across three or more different functional layers.

Therefore, the mixing layer 51 is a layer defined by a portion in which a component forming at least one layer among the respective layers constituting the organic layer 14 and a component forming at least a layer adjacent to the one layer are mixed. In the example illustrated in FIG. 4, in the mixing layer 51, components constituting a layer located on the side of the second electrode 15 are mixed with components constituting a layer located on the side of the first electrode 13.

Further, in this example, the mixing layer 51 includes a layer defined by a portion in which a component forming at least one layer of the plurality of types of light emitting layers 142 is mixed with a component forming at least a layer adjacent to the one layer on the side of the second electrode 15. In the state illustrated in FIG. 4, the component forming the electron transport layer 143 is diffused into the second light emitting layer 142B, and further reaches the intermediate layer 145.

Therefore, in the example in FIG. 4, the mixing layer 51 is a layer formed by combining a layer in which a component forming the electron transport layer 143 is mixed with the second light emitting layer 142B, and a layer in which a component forming the electron transport layer 143 is mixed with part of the intermediate layer 145. However, this example does not limit the mixing layer 51 to that in a case where a component forming the electron transport layer 143 reaches the intermediate layer 145.

### (Checking of the Mixing Layer)

The presence of the mixing layer 51 can be checked by a method such as cross-sectional TEM (TEM is an abbreviation for transmission electron microscopy), GCIB-TOF-SIMS, or the like. Note that GCIB-TOF-SIMS is time-of-flight secondary ion mass spectrometry (TOF-SIMS) using gas cluster ion beams.

The mixing layer 51 in the pixel 100 is formed at least in the counter region K in which the first electrode 13 and the organic layer 14 face each other in a plan view of the pixel 100 (in a case where the Z-axis direction is the line-of-sight direction). In the example in FIGS. 2 and 3, the mixing layer 51 is further formed in an annular shape along the opening 12A. The mixing layer 51 formed along the opening 12A is formed, as the insulating layer 12 functions as insulating structures 55.

In the display device 10 according to the first embodiment, as illustrated in FIG. 2, the mixing portion 52, which is a portion in which the mixing layer 51 is formed, is substantially specified as a portion having a predetermined contour shape around each insulating structure 55 described later, in a case where the thickness direction of the substrate 11A is the line-of-sight direction. In the example in FIG. 2, the mixing layer 51 is formed in an annular shape around each insulating structure 55. Also, the mixing layer 51 is discretely formed at a plurality of places in accordance with the layout of the insulating structures 55. As illustrated in FIG. 2, the mixing layer 51 is discretely formed at 4×4 places in a vertical×horizontal layout (in the X-axis direction and the Y-axis direction), for ease of explanation. However, this does not prohibit at least some portions of the mixing layer 51 formed around the respective insulating structures 55 from being joined to each other. All or some portions of the mixing layers 51 formed around the insulating structures 55 may be joined to each other.

Note that, in the example in FIGS. 2 and 3, the mixing layer 51 is formed along the openings 12A, and the mixing portions 52 corresponding to the mixing layer 51 are formed. The mixing portions 52 formed along the openings 12A are formed, as the insulating layer 12 functions like the insulating structures 55. In this case, the mixing portions 52 are formed outside the non-mixing portions 53 described later. However, this does not prohibit the mixing portions 52 from being not formed outside the non-mixing portions 53.

### (Non-Mixing Portions)

In each pixel 100, a non-mixing portion 53 is formed in the organic layer 14. As illustrated in FIG. 2, the non-mixing portion 53 is defined as a portion of each pixel 100 excluding the mixing portion 52. The non-mixing portion 53 includes a first portion 53A formed in a pixel light emitting region KL, and a second portion excluding the first portion 53A. The second portion is a portion corresponding to the portion of the organic layer 14 in which an insulating structure 55 is provided.

### (Pixel Light Emitting Region)

In the example in FIG. 2, the mixing portion 52 and the first portion 53A of the non-mixing portion 53 are formed in the light emitting region (pixel light emitting region KL) in the pixel 100. In the region forming a pixel 100B, the region excluding the no-light emitting regions M3 is the light emitting region (pixel light emitting region KL) in the pixel 100B. Here, in a plan view of the pixel 100B (which is a case where the thickness direction of the substrate 11A is the line-of-sight direction), the regions corresponding to the portions in which the insulating structures 55 are provided are the no-light emitting regions M3. Accordingly, the pixel light emitting region KL indicates the region corresponding to the portion corresponding to the counter region K forming one pixel 100, excluding the regions corresponding to the portions in which the insulating structures 55 are formed.

### (Mixing Regions and Non-Mixing Light Emitting Regions)

In the display device 10, the pixel light emitting region KL in the region forming each pixel 100B is divided into a mixing region M1 and a non-mixing light emitting region M2 as illustrated in FIG. 2. The mixing portions 52 are formed at least around the insulating structures 55, and the mixing region M1 is defined as a region that is observed in a case where the thickness direction of the organic layer 14 is the line-of-sight direction, and as a region in which the mixing layer 51 is formed (which is a region in which the mixing portions 52 are formed). In the example in FIG. 2, the mixing portions 52 are also formed in the vicinity of the opening 12A. Therefore, the mixing region M1 is also formed in the region corresponding to the vicinity of the opening 12A. The non-mixing light emitting region M2 is defined as a region in which the first portion 53A is formed, of the region in which the non-mixing portions 53 are formed. The non-mixing light emitting region M2 is defined as the region forming the pixel 100 excluding the mixing regions M1 and the no-light emitting regions M3.

### (Size of a Mixing Region)

The size of the mixing regions M1 in each pixel 100 may be determined in accordance with conditions such as the size of the pixel 100. In a case where the mixing regions M1 are formed in an annular shape as illustrated in FIGS. 2 and 3, the width WM of each mixing region M1 is preferably about 0.5 μm or greater. This can be achieved by appropriately adjusting the conditions of the heating treatment in the manufacturing method described later.

### (Emission Colors)

In the organic layer 14, the emission color (first color) to be generated in the non-mixing portions 53 is different from the emission color (second color) to be generated in the mixing portions 52. The emission color generated from the organic layer 14 is a mixed color of the first color and the second color. As for the emission color from a pixel 100, the intensity of the second color becomes higher, as the proportion of the mixing regions M1 (the occupancy rate of the mixing regions M1) in the pixel light emitting region KL becomes larger, with respect to the ratio between the mixing regions M1 and the non-mixing light emitting region M2. The intensity of the first color becomes higher, as the occupancy rate of the mixing regions M1 becomes lower (as the proportion of the non-mixing light emitting region M2 becomes larger). Note that the occupancy rate of the mixing regions M1 can be determined by the area of the mixing regions M1 with respect to the total area of the mixing regions M1 and the non-mixing light emitting region M2 (the area of the pixel light emitting region KL).

In a case where the organic layer 14 has layer components as illustrated in FIG. 3, the emission color in the mixing regions M1 in the pixel 100 is blue or whitish blue as compared with that in the non-mixing light emitting region M2. The emission color in the non-mixing light emitting region M2 in the pixel 100 is yellow or whitish yellow as compared with that the mixing regions M1. The emission color to be generated in the non-mixing portions 53 can be set to yellow by adjustment of the thicknesses of the layers of the first light emitting layer 142A and the second light emitting layer 142B. The emission color from the pixel 100 is closer to blue or whitish blue, when the occupancy rate of the mixing regions M1 is higher. As the occupancy rate of the mixing regions M1 becomes lower, the emission color therein becomes closer to yellow or whitish yellow. In a sub-pixel 101B of the display device 10, the mixing portions 52 are formed in the counter region K. Therefore, the emission color from the organic layer 14 is blue or whitish blue, and the emission color from the pixel 100 is normally blue or whitish blue.

To further increase the occupancy rate of the mixing regions M1, it is preferable to further increase the number of the insulating structures 55. This can be achieved by shortening the distance (or pitch, denoted by reference sign PT in FIG. 2) between adjacent insulating structures 55, and arranging the insulating structures 55 more densely, for example. In this case, the shorter the pitch PT, the higher the occupancy rate of the mixing regions M1.

### (Insulating Structures)

In the display device 10 according to the first embodiment, at least one insulating structure 55 is formed between the first electrode 13 and the organic layer 14, as illustrated in FIGS. 2 and 3. The insulating structures 55 are formed in the counter region K in which the first electrode 13 and the organic layer 14 face each other. The insulating structures 55 are structures formed with an insulating material. The insulating material is not limited to any particular material, and examples thereof include silicon nitride and silicon oxide, for example. Each insulating structure 55 may be a structure formed with one of these insulating materials, or may be a structure in which structures formed with insulating materials are stacked. Specifically, each insulating structure 55 may have a structure in which a silicon nitride layer and a silicon oxide layer are stacked, for example. The insulating structures 55 may be formed with the same material as the material of the insulating layer 12. Also, the insulating structures 55 are structures in which addition of a light emitting material is restricted. Here, an example of the light emitting material can be a material forming the light emitting layers 142 of the organic layer 14.

The layout of the insulating structures 55 is not limited to any particular layout. In the example in FIGS. 2 and 3, the layout of the plurality of insulating structures 55 is such that the insulating structures 55 are discretely arranged in a lattice form in the X-axis direction and the Y-axis direction in each pixel 100.

### (Shape of the Insulating Structures)

In the example in FIGS. 2 and 3, the insulating structures 55 each have a portion formed in a substantially columnar shape. Note that, in the example in FIG. 3, at the end portion on the first surface side, each insulating structure 55 has a portion in a shape (conical shape) that is tapered in the direction from the second surface side toward the first surface side. A case where each insulating structure 55 is formed in a columnar shape includes a case where each insulating structure 55 includes a portion having a non-uniform cross-sectional diameter, such as a case where each insulating structure 55 has a tapered tip as illustrated in FIG. 3. Note that this does not limit the shape of the insulating structures 55. The shape of the insulating structures 55 is not limited to any particular shape, and may be a shape different from a columnar shape, or may be a prismatic shape or the like, for example. Also, the shape of the insulating structures 55 may be a shape in which the conical portion is omitted.

### (Dimensions of the Insulating Structures)

As for the dimensions of the insulating structures 55, each insulating structure 55 has a smaller cross-sectional area than the counter region K in which the first electrode 13 and the organic layer 14 face each other. In the example in FIG. 2, the area of a cross-section (transverse section) of each insulating structure 55 in a plane parallel to the X-Y plane is smaller than the area of the counter region K. Accordingly, the mixing layer 51 can be easily accommodated within the region of one pixel 100, and the mixing portions 52 and the non-mixing portions 53 can be formed inside one pixel.

### (Height of the Insulating Structures)

The height H of the insulating structures 55 is preferably a value exceeding 15 nm. This makes it easier to form the mixing layer 51 within the region of one pixel 100.

### [1-2 Method for Manufacturing the Display Element]

Next, an example of a method for manufacturing the display device 10 according to the first embodiment is described in detail.

The substrate 11A is prepared. For example, a technique such as a sputtering method, a lithography method, an etching method, or a vapor deposition method is used as necessary, to form the insulating layer 11B and the first electrodes 13 on the substrate 11A. The insulating layer 12 is formed on the first electrode 13 with the same material as that of the insulating layer 11B, and the insulating structures 55 are formed. The insulating structures 55 can be formed by a lithography method, an etching method, or the like. Further, the hole injection layer 140, the hole transport layer 141, the first light emitting layer 142A, the intermediate layer 145, the second light emitting layer 142B, the electron transport layer 143, and the like are sequentially formed, so that the organic layer 14 is formed. The second electrode 15 is stacked on the organic layer 14 on the first surface side, and the protective layer 16 is further formed. As a result, a structure in which the counter substrate 19 is provided on the first surface side of the protective layer 16 with a filling resin layer 18 interposed in between, and the organic layer 14 is interposed between the drive substrate 11 and the counter substrate 19 is obtained. The structure is then subjected to a heating treatment. Conditions for the heating treatment are determined as appropriate, in accordance with the size and the like of the structure. In an example, the heating treatment can be performed by heating at a temperature of 100° C. or higher, for example. The duration of the heating treatment may be ten minutes or so, for example, or may be adjusted as appropriate. As the heating treatment is performed, the mixing portions 52 are formed in the structure. In this manner, the display device 10 can be obtained.

### [1-3 Functions and Effects]

In each pixel 100 in the display device 10 according to the first embodiment, the mixing portions 52 are formed in part of the pixel 100, and the non-mixing portion 53 is also formed, in a case where the thickness direction of the substrate 11A is the line-of-sight direction (in a case where the Z-axis direction is the line-of-sight direction).

In the mixing region M1 corresponding to the mixing portions 52, light emission in the first light emitting layer 142A is stronger than light emission in the non-mixing light emitting region M2, and light emission in the second light emitting layer 142B is weaker than light emission in the first light emitting layer 142A. Accordingly, the color of light emission from the organic layer 14 is closer to the emission color in the first light emitting layer 142A. In the example in FIGS. 3, 4, and 5, and others, the emission color in the first light emitting layer 142A is blue, and the emission color in the second light emitting layer 142B is yellow. Accordingly, the emission color in the non-mixing light emitting region M2 in the organic layer 14 is a color close to yellow, and the emission color in the mixing region M1 is a color closer to blue than the emission color in the non-mixing light emitting region M2.

In the mixing portions 52, the component (organic material) forming the second light emitting layer 142B and the component (organic material) forming the electron transport layer 143 are mixed. It is considered that the portion (recombination portion) in which light emission associated with coupling between electrons and holes is mainly performed changes (moves to the side of the first light emitting layer 142A) with the change caused in the carrier transporting properties in the mixing portions 52 by the mixing, and the blue light emitting layer as the first light emitting layer 142A emits light with high intensity. In the non-mixing portions 53, the above-described mixing of organic materials is less likely to occur, the recombination portion is more likely to be formed on the side of the second light emitting layer 142B than in the mixing portions 52, and the yellow light emitting layer as the second light emitting layer 142B is more likely to emit light with high intensity. In view of the above, it can be considered that the non-mixing light emitting region M2 corresponding to the first portions 53A of the non-mixing portions 53 emits yellow light, or a color of light obtained by mixing blue light and yellow light.

For this reason, in the display device 10, an emission color (blue or yellow in the example in FIGS. 3, 4, and 5) corresponding to the pixels 100 can be obtained as the color of light emission from the organic layer 14.

Also, in the display device 10, it is possible to adjust the color of light emission from the organic layer 14 of the light emitting elements 104 by adjusting the layout of the insulating structures 55 even when the light emitting elements 104 are miniaturized. Accordingly, the display device 10 can be easily manufactured, and thus, the display device 10 can be easily made to achieve high definition and be made smaller in size.

Next, modifications of the display device 10 according to the first embodiment are described.

### [1-4 Modifications]

### (Modification 1)

In a display device 10 according to Modification 3 of the first embodiment, one or more of the density, the number, the pitch, and the layout of insulating structures 55 may be set to a density, a number, a pitch, and a layout different from those in the example in FIG. 2, as illustrated in FIGS. 6A and 6B. This mode is referred to as Modification 1 of the first embodiment.

In the example illustrated in FIG. 6B, the number of insulating structures 55 provided in one pixel is larger than that in the example illustrated in FIG. 6A. Also, in either of the examples illustrated in FIGS. 6A and 6B, the number of insulating structures 55 provided in one pixel is smaller than that in the example illustrated in FIG. 2. In this case, the occupancy rate of the mixing region M1 in one pixel is larger in the example illustrated in FIG. 6B than in the example illustrated in FIG. 6A, and is larger in the example illustrated in FIG. 2 than in either of the examples illustrated in FIGS. 6A and 6B. That is, regarding the balance between the mixing region M1 and the non-mixing light emitting region M2, the occupancy rate of the mixing region M1 increases in the order of the example illustrated in FIG. 6A, the example illustrated in FIG. 6B, and the example illustrated in FIG. 2. In conjunction with this, the intensity of the blue color as the emission color of the pixel 100 becomes lower in the order of the example illustrated in FIG. 2, the example illustrated in FIG. 6B, and the example illustrated in FIG. 6A.

### (Functions and Effects)

In the display device 10 according to Modification 1 of the first embodiment, the occupancy rate of the mixing region M1 is adjusted, so that the intermediate color between the color type of the first light emitting layer 142A and the color type of the second light emitting layer 142B, and the intermediate color between yellow and blue in the examples of FIGS. 6A and 6B can be adjusted as the emission color of the light emitting element 104.

### (Modification 2)

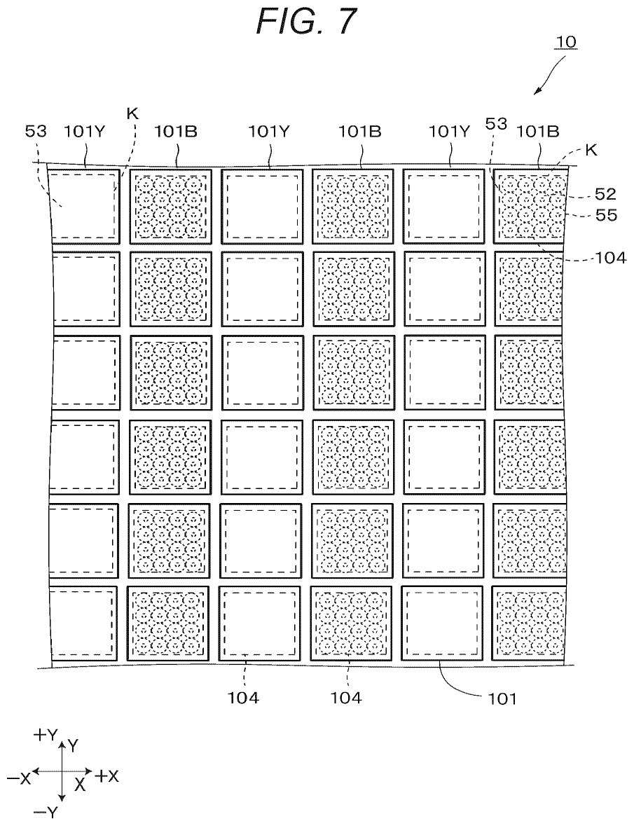

In the display device 10 according to the first embodiment, each pixel may include a plurality of sub-pixels 101 corresponding to a plurality of color types, as illustrated in FIG. 7. This embodiment is referred to as Modification 2 of the first embodiment. FIG. 7 is a plan view for explaining an example of a display device 10 according to Modification 1 of the first embodiment. In a case where each pixel includes sub-pixels, the layer components of the pixel 100 described above in the display device according to the first embodiment are adopted in at least one type of each sub-pixel. The same applies in Modification 3 described later.

### (Configuration of Sub-Pixels)

In the display device 10 illustrated in FIG. 7, each pixel is formed with a combination of a sub-pixel 101Y and a sub-pixel 101B as two types of sub-pixels 101. The sub-pixel 101Y corresponds to a yellow sub-pixel that is a sub-pixel 101 in which yellow is the emission color, and the sub-pixel 101B corresponds to a blue sub-pixel that is a sub-pixel 101 in which blue is the emission color. The display device 10 according to Modification 1 of the first embodiment may be formed in a manner similar to the display device 10 of the first embodiment described above, except for the configuration of the light emitting elements 104. Note that, in FIG. 7, for ease of explanation, the mixing portions 52 formed along the outer peripheral edges of the counter regions K of the sub-pixels 101 are not shown.

### (Light Emitting Elements)

The light emitting elements 104 of the sub-pixels 101B are formed in a manner similar to the light emitting elements 104 of the pixels 100B described in the first embodiment. That is, in the display device 10 according to Modification 1 of the first embodiment, the light emitting elements 104 of the sub-pixels 101B form the mixing layer 51 in part of the organic layer 14.

Accordingly, in the display device 10 according to Modification 1 of the first embodiment, in a case where the thickness direction of the substrate 11A is the line-of-sight direction, the mixing portions 52 are formed in the sub-pixels 101B corresponding to at least one of the color types of the sub-pixels 101Y and the sub-pixels 101B.

The light emitting elements 104 of the sub-pixels 101Y are designed in a manner similar to those of the pixels 100B described in the first embodiment, except that the formation of the mixing layer 51 formed around the insulating structures 55 is avoided as the formation of the insulating structures 55 is avoided. Each sub-pixel 101Y has a configuration in which, of the mixing region M1 in the pixel 100B, the mixing region M1 formed around the insulating structures 55, and the no-light emitting region M3 are set as the non-mixing light emitting region M2, as illustrated in FIG. 2B. In the sub-pixel 101Y, the mixing region M1 is annularly formed only in a portion along the openings 12A, and the non-mixing light emitting region M2 spreads over the entire region on the inner side of the mixing region M1, as illustrated in FIG. 2B. In the sub-pixel 101Y, the emission color of the organic layer 14 is normally yellow or whitish yellow.

In the display device 10 according to Modification 2 of the first embodiment, the sub-pixels corresponding to at least one color type may have a first occupancy rate as the occupancy rate of the mixing regions M1, and the sub-pixels corresponding to at least another color type may have a second occupancy rate as its occupancy rate that is different from the first occupancy rate. In this case, the first occupancy rate can be adjusted in accordance with the number, the pitch, and the like of the insulating structures 55, for example. The same applies to the second occupancy rate. Note that this case includes a case where one of the first occupancy rate and the second occupancy rate is zero.

Specifically, this can be achieved in the following manner: in a case where the sub-pixels 101B and 101Y are formed on the same substrate 11A, the occupancy rate that is defined so that the emission color corresponding to the sub-pixels 101B is obtained is set as the first occupancy rate in the sub-pixels 101B, the occupancy rate that is defined so that the emission color corresponding to the sub-pixel 101Y is obtained is set as the second occupancy rate in the sub-pixels 101Y, the distribution of the occupancy rate of the mixing regions M1 in the organic layer 14 (the distribution of the first occupancy rate and the second occupancy rate) is determined, and the organic layer 14 is formed so as to satisfy this distribution.

Also, among the sub-pixels 101 corresponding to the respective color types, the occupancy rate of the mixing regions M1 may be adjusted as described in Modification 1 of the first embodiment. This can be achieved by determining the number, the pitch, and the like of the insulating structures 55 in accordance with the color types of the sub-pixels 101 (not illustrated). The same applies in Modification 3 of the first embodiment described next.

### (Functions and Effects)

In the display device 10 according to Modification 1 of the first embodiment, the sub-pixels 101 (the sub-pixels 101Y and the sub-pixels 101B) corresponding to a plurality of color types can be formed in accordance with the layout of the insulating structures 55, while the layer components constituting the organic layer 14 are shared.

### (Modification 3)

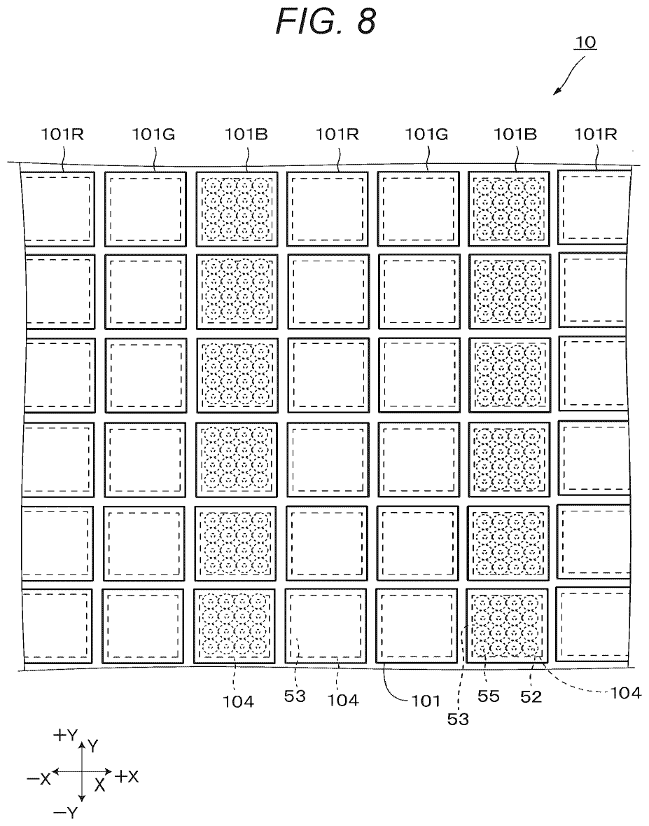

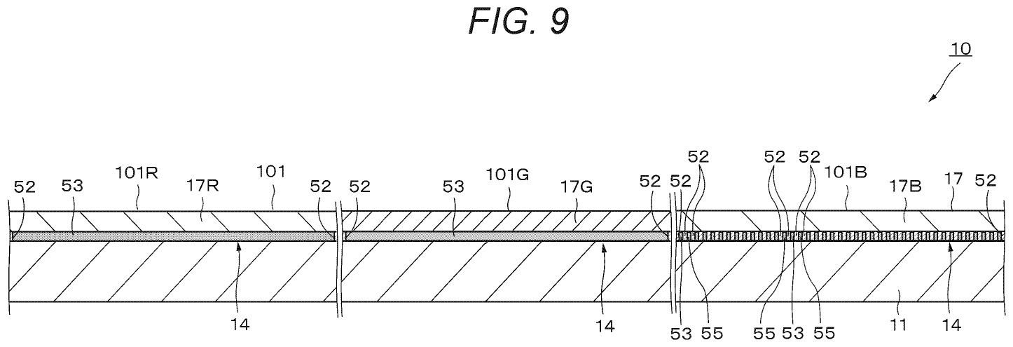

In the display device 10 according to Modification 1 of the first embodiment, three or more types of sub-pixels may be provided as the sub-pixels 101 corresponding to a plurality of color types, as illustrated in FIGS. 8 and 9. In Modification 3, color filters 17 are preferably provided as described later. FIG. 8 is a plan view for explaining an example of a display device 10 according to Modification 3 of the first embodiment. FIG. 9 is a cross-sectional view for explaining an example of a display device 10 according to Modification 3 of the first embodiment. In FIG. 9, for ease of explanation, the insulating layer 12, the first electrodes 13, the second electrode 15, the protective layer 16, the filling resin layer 18, and the counter substrate 19 are not shown. Furthermore, the respective layers constituting the organic layer 14, and the components between the adjacent sub-pixels 101 are not shown.

### (Configuration of Sub-Pixels)

In the example of the display device 10 illustrated in FIGS. 8 and 9, one pixel is formed with a combination of a plurality of sub-pixels corresponding to a plurality of color types on the same drive substrate 11. In the example in FIGS. 8 and 9, the three colors of red, green, and blue are defined as the plurality of color types, and the three types of sub-pixels 101R, sub-pixels 101G, and sub-pixels 101B are provided as the sub-pixels 101. The sub-pixels 101R, the sub-pixels 101G, and the sub-pixels 101B are red sub-pixels, green sub-pixels, and blue sub-pixels, respectively, and display the red color, the green color, and the blue color, respectively. However, the example in FIGS. 8 and 9 is an example, and does not limit the color types of the plurality of sub-pixels. Further, the wavelengths of light beams corresponding to the respective color types of red, green, and blue can be determined as wavelengths in the range of 610 nm to 650 nm, the range of 510 nm to 590 nm, and the range of 440 nm to 480 nm, respectively, for example. Furthermore, examples of layouts of the individual sub-pixels 101R, 101G, and 101B include a layout in which combinations of sub-pixels 101 formed in a striped shape are arranged in a matrix fashion, for example. In the example in FIG. 8, the sub-pixels 101R, 101G, and 101B are two-dimensionally disposed in the display region 10A.

In the description below, the term “sub-pixels 101” will be used in a case where the sub-pixels 101R, 101G, and 101B are not specifically distinguished from one another.

As for the other components (such as the protective layer 16) except for the light emitting elements 104 and the color filters 17, the display device 10 according to Modification 1 of the first embodiment may be formed in a manner similar to the display device 10 of the first embodiment described above.

### (Light Emitting Elements)

The light emitting elements 104 corresponding to the sub-pixels 101R, 101G, and 101B are disposed on the first surface side of the same drive substrate 11. The light emitting elements 104 of the sub-pixels 101B are formed in a manner similar to the light emitting elements 104 of the pixels 100B described in the first embodiment. That is, in the display device 10 according to Modification 3 of the first embodiment, the light emitting elements 104 of the sub-pixels 101B have the mixing portions 52 in part of the organic layer 14, as in Modification 2 described above.

Accordingly, in the display device 10 according to Modification 3 of the first embodiment, in a case where the thickness direction of the substrate 11A is the line-of-sight direction, the mixing portions 52 are formed in the sub-pixels 101B corresponding to at least one of the color types of the sub-pixels 101R, the sub-pixels 101G, and the sub-pixels 101B.

The light emitting elements 104 of the sub-pixels 101R and 101G are designed in a manner similar to the light emitting elements 104 of the pixel 100B described in the first embodiment, except for avoiding formation of the insulating structures 55. In the light emitting elements 104 of the sub-pixels 101R and 101G, formation of the mixing portions 52 around the insulating structures 55 is avoided. Also, formation of the no-light emitting regions M3 accompanying installation of the insulating structures 55 is avoided. The light emitting elements 104 of the sub-pixels 101R and 101G each have the same configuration as that of each light emitting element 104 of the pixels 100B, except that the mixing region M1 and the no-light emitting region M3 are replaced with the non-mixing light emitting region M2, as in the case of the sub-pixels 101Y of Modification 2 described above. Accordingly, the light emitting elements 104 of the sub-pixels 101R and 101G each have a configuration similar to that of the light emitting element 104 used in each of the sub-pixels 101Y described in Modification 2. In the sub-pixels 101R and 101G, the emission color of the organic layer 14 is normally yellow or whitish yellow.

### (Color Filters)

In the display device 10 according to Modification 3 of the first embodiment, the color filters 17 are provided on the first surface side of the light emitting elements 104, as illustrated in FIG. 9. In the example in FIG. 9, the protective layer 16 is provided on the first surfaces of the light emitting elements 104, and the color filters 17 are further formed on the first surface of the protective layer 16. Also, in this example, the color filters 17 corresponding to the color types of the sub-pixels 101 are provided. In each sub-pixel 101R, a red-color filter 17R is provided as the color filter 17. In each sub-pixel 101G, a green-color filter 17G is provided as the color filter 17. In each sub-pixel 101B, a blue-color filter 17B is provided as the color filter 17. Note that a planarizing layer that smooths the surface on which the color filters 17 are to be formed may be formed between the color filters 17 and the counter substrate 19. Also, the filling resin layer 18 may be provided between the counter substrate 19 and the planarizing layer. For the planarizing layer and the filling resin layer 18, a material that can be used as the material forming the protective layer 16 may be used.

### (Functions and Effects)

In the display device 10 according to Modification 3 of the first embodiment, when the layer components constituting the organic layer 14 are formed on the same substrate and are shared among a plurality of sub-pixels, the emission color of the light emitting elements 104 can be yellow in the sub-pixels 101R and the sub-pixels 101G, and the emission color of the light emitting elements 104 can be blue in the sub-pixels 101B, depending on the layout of the insulating structures 55. With this arrangement, it becomes easier to reduce light loss when the light generated from the light emitting elements 104 passes through the color filters 17, and thus, full-color display can be performed with efficient use of light.

### (Modification 4)

In the display device 10 according to the first embodiment, the second light emitting layer 142B may include a plurality of light emitting layers 142 corresponding to a plurality of color types. This mode is referred to as Modification 4 of the first embodiment. In the display device 10 according to Modification 4 of the first embodiment, the other components except for the second light emitting layer 142B may be similar to the respective components of the display device 10 described in the first embodiment.

### (Second Light Emitting Layer)

In the display device 10 of Modification 4 of the first embodiment, the second light emitting layer 142B has a stack structure formed with a plurality of phosphorescent light emitting layers, and each phosphorescent light emitting layer has a stack structure formed with a green phosphorescent light emitting layer having a green emission color and a red phosphorescent light emitting layer having a red emission color. The emission color of the second light emitting layer 142B is a color obtained by combining red and green.

### (Functions and Effects)

In the display device 10 according to Modification 4 of the first embodiment, in the mixing region M1, the light emission in the first light emitting layer 142A is stronger than in the non-mixing light emitting region M2, and the light emission in the second light emitting layer 142B is likely to be weaker than the light emission in the first light emitting layer 142A, as described in the functions and effects of the first embodiment. Thus, the emission color from the organic layer 14 is a color close to the emission color in the first light emitting layer 142A.

In the display device 10 according to Modification 4 of the first embodiment, the emission color in the first light emitting layer 142A is blue, and the emission color in the second light emitting layer 142B is the color of light obtained by combining red-color light and green-color light. Accordingly, the emission color in the non-mixing light emitting region M2 in the organic layer 14 is normally a color close to white, and the emission color in the mixing region M1 is a color closer to blue than the emission color in the non-mixing light emitting region M2. Because of this, the mixing layer 51 is formed in accordance with the color type of the pixel 100 or the sub-pixel 101, so that the emission color of the light emitting element 104 can be the emission color corresponding to the color type of the pixel 100 or the sub-pixel 101, as in the functions and effects described in the explanation of the display device 10 according to the first embodiment.

### (Modification 5)

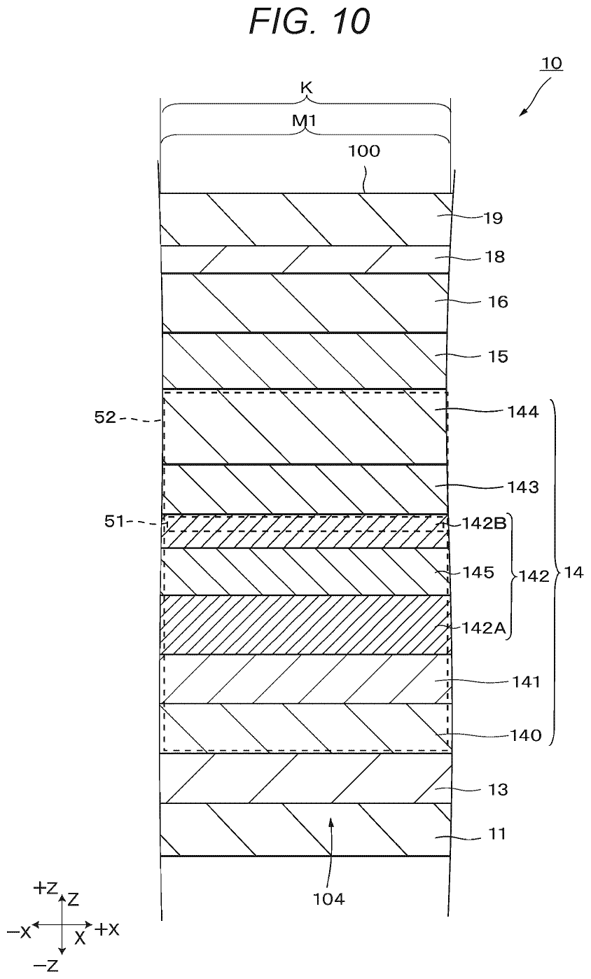

In the display device 10 according to Modification 4 of the first embodiment, the mixing layer 51 of the mixing portions 52 may be formed while the component forming one of the layers constituting the organic layer 14 is mixed with the component to the depth of part of a layer adjacent to the one of the layers, as illustrated in FIG. 10. FIG. 10 is a cross-sectional diagram schematically illustrating the layer components of a mixing portion 52 in the organic layer 14 in a display device 10 according to Modification 5 of the first embodiment. In the example in FIG. 10, the mixing layer 51 is a layer defined by its portion mixed with the component forming the electron transport layer 143 in the second light emitting layer 142B, and is thinner than the example of the mixing layer 51 illustrated in FIG. 4.

### (Example Simulation)

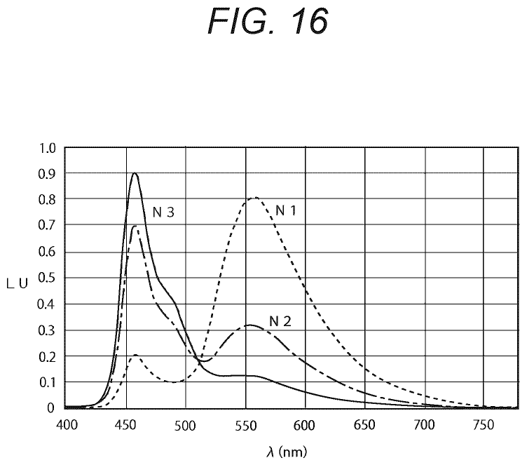

With the display device 10, the emission colors of the pixels can be adjusted in accordance with the thickness of the mixing layer 51, as illustrated in FIG. 16. FIG. 16 is a graph showing comparisons among spectra of emission colors for different thicknesses of the mixing layer 51. In FIG. 16, a spectrum N1 is indicated by a dashed line, a spectrum N2 is indicated by a dot-and-dash line, and a spectrum N3 is indicated by a solid line. In FIG. 16, the abscissa axis indicates the wavelength A (run) of light, and the ordinate axis indicates the intensity LU of light. The spectrum N1 in FIG. 16 indicates the spectrum of the emission color in the non-mixing light emitting region M2. The spectrum N2 indicates the spectrum of the emission color in the mixing region M1 in a case where the thickness of the mixing layer 51 is the thickness corresponding to that in the example illustrated in FIG. 10 (first case). The spectrum N3 indicates the spectrum of the emission color in the mixing region M1 in a case where the thickness of the mixing layer 51 is the thickness corresponding to that in the example illustrated in FIG. 4 (second case). Note that, in the example in FIG. 16, the thickness of the mixing layer 51 illustrated in FIG. 4 is about 2.2 times the thickness of the mixing layer 51 illustrated in FIG. 10. As indicated by the spectrum N1 in FIG. 16, in the non-mixing light emitting region M2, light generated in the green wavelength region (about 510 nm to 590 nm) is stronger than light generated in the blue wavelength region (about 440 nm to 480 nm). As can be seen from the comparison between the spectrum N1 and the spectra N2 and N3 in FIG. 16, in the mixing region M1, the light generated in the blue wavelength region is stronger than the light generated in the green wavelength region, compared with that in the non-mixing light emitting region M2. Also, as can be seen from the comparison between the spectra N2 and N3, in the case where the thickness of the mixing layer 51 is greater (the second case), the light generated in the blue wavelength region is stronger than the light generated in the green wavelength region, compared with that in the case where the thickness of the mixing layer 51 is smaller (the first case). In this manner, as the thickness of the mixing layer 51 becomes greater, the emission color of light generated in the mixing region M1 approaches the color of the first light emitting layer 142A.

### (Functions and Effects)

In the display device 10 according to Modification 5 of the first embodiment, the thickness of the mixing layer 51 is adjusted, so that functions and effects similar to the functions and effects described in the explanation of the display device 10 according to the first embodiment can be generated while the effects are adjusted.

### 2 Second Embodiment

### [2-1 Configuration of a Display Element]

As illustrated in FIGS. 11 and 13, a display device 10 according to a second embodiment is formed so an insulating structure 60 extends along the X-Y plane in a case where the thickness direction of the substrate 11A is the line-of-sight direction (a case where the Z-axis direction is the line-of-sight direction). Also, a mixing layer 61 that matches the shape of the insulating structure 60 is formed, and mixing portions 62 and non-mixing portions 63 are formed.

FIG. 11 is a plan view illustrating the mixing portions 62 and the formation regions thereof (mixing regions M21), and the formation regions of first portions 63A of the non-mixing portions 63 (non-mixing light emitting regions M22) in a case where pixels 100 of the display device 10 according to the second embodiment are viewed in the line-of-sight direction that is the direction from the light emitting surface D toward the substrate 11A. In FIG. 11, the mixing regions M21, the non-mixing light emitting regions M22, and no-light emitting regions M23 formed in the counter region K corresponding to the region of one pixel 100 are indicated by solid lines and hatching. Further, in FIG. 11, a portion in which the mixing layer 61 is formed is also shown. The above aspects described regarding FIG. 11 also apply in FIGS. 12A and 12B.

FIG. 13 is a cross-sectional diagram schematically illustrating a longitudinal cross-section taken along the line B-B defined in FIG. 11. In the display device 10 according to the second embodiment, the respective layer components of the other components (the first electrodes 13, the respective layers in the organic layer 14, and the second electrode 15, for example) excluding the insulating structure 60, the mixing portions 62, and the non-mixing portions 63 may be similar to those of the display device 10 according to the first embodiment. Therefore, the same reference numerals as those used in the first embodiment are given to the above components, and detailed explanation thereof is not made herein. Note that, in FIG. 13, for ease of explanation, the respective layers, except for the light emitting layers 142, are not shown in the portion of the organic layer 14 formed outside the counter region K and the portion of the organic layer 14 corresponding to the no-light emitting region M23 in a plan view of the display device 10 (in a case where the thickness direction of the substrate 11A is the line-of-sight direction), as in FIG. 3. Also, regarding the portion of the organic layer 14 formed inside the counter region K, the mixing portions 62 and non-mixing portions 63 described later are shown, and the respective layers in each portion of the mixing portions 62 and the non-mixing portions 63 are not shown.

### (Insulating Structures)

In the display device 10 according to the second embodiment, the insulating structure 60 is provided between the first electrodes 13 and the organic layer 14. The insulating structure 60 is formed in the counter region K in which the first electrodes 13 and the organic layer 14 face each other. The material of the insulating structure 60 may be similar to the material of the insulating structures 55 described in the first embodiment, and the insulating structure 60 may be formed by a method similar to that used for forming the insulating structures 55. The preferred height of the insulating structure 60 is also similar to that of the insulating structures 55.

The insulating structure 60 is formed in a shape extending in the plane direction of the first electrodes 13, and is formed in a wall-like shape. Also, the insulating structure 60 is formed in a shape extending in a plurality of directions intersecting each other in the plane direction of the first electrodes 13. In the example in FIG. 11, the insulating structure 60 includes a first structure 64A extending in the X-axis direction, a second structure 64B extending in the Y-axis direction, and a third structure 64C formed at the portion where the first structure 64A and the second structure 64B intersect.

The insulating structure 60 is preferably formed so as to divide the counter region K, with the thickness direction (Z-axis direction) of the substrate 11A being the line-of-sight direction. In the example in FIG. 11, the insulating structure 60 divides (partitions) the counter region K into four sections. Note that the regions divided by the insulating structure 60 are referred to as divided regions KD. In the example in FIG. 11A, divided regions KD1, KD2, KD3, and KD4 are formed as the divided regions KD. In FIG. 11, the divided regions KD are indicated by dot-and-dash lines. The divided regions KD1, KD2, KD3, and KD4 are formed to have substantially the same shapes and substantially the same sizes.

Also, in the insulating structure 60, the end portions of the insulating structure 60 in the longitudinal direction of each of the first structure 64A and the second structure 64B of the insulating structure 60 are preferably joined to the insulating layer 12. Here, the insulating layer 12 illustrated in the example in FIGS. 11 and 13 is designed in a manner similar to the insulating layer 12 in the first embodiment. The insulating layer 12 is formed so as to fill the spaces between the adjacent first electrodes 13, and is further formed so as to cover the peripheral edges of the first electrodes 13.

### (Size of Divided Regions)

The size of the divided regions KD is preferably 5 μm or smaller in width WK. As the size of the divided regions KD is designed so that the width WK is 5 μm or smaller, it is easy to increase the occupancy rate of the mixing regions M21.

### (Mixing Portions)

In the light emitting element 104 in each pixel 100, the mixing portions 62 are formed in part of the organic layer 14 in a case where the thickness direction of the substrate 11A is the line-of-sight direction (a case where a direction parallel to the Z-axis direction is the line-of-sight direction in FIG. 13).

The mixing portions 62 are specified as portions that satisfy conditions (prescribed conditions) similar to those for the mixing portions 52 in the first embodiment described above. The mixing portions 62 are observed at least in part of the organic layer 14 in a case where the thickness direction of the substrate 11A is the line-of-sight direction.

Therefore, the mixing portions 62 are defined in conformity with the portion at which the mixing layer 61 is formed. For example, if the mixing layer 61 is formed in a layout in which layers having a substantially rectangular annular shape are arranged in a lattice-like form, the mixing portions 62 are also formed in a layout in which rectangular annular portions corresponding to the layout of the mixing layer 61 are arranged in a lattice-like form in a plan view of the pixel 100.

### (Mixing Layer)

The mixing layer 61 is a layer defined in a manner similar to the mixing layer 51 of the display device 10 according to the first embodiment.

That is, in a case where a first position and a second position are selected as two positions different in the plane direction of the organic layer 14, and components of the organic layer 14 at the first position and the second position are compared, a layer that is observed only at one of the first position and the second position, and have components of different functional layers of the organic layer 14 mixed therein is defined as the mixing layer 61.

For example, in a case where the first position is selected from the mixing region M21 described later, and the second position is selected from the non-mixing light emitting region M22, the mixing layer 61 is specified as a layer that is formed at the first position but is not formed at the second position. The mixing layer 61 is a layer that is defined by a layer in which a component forming the second light emitting layer 142B between the first light emitting layer 142A and the second light emitting layer 142B, and a component forming the electron transport layer 143 adjacent to the second light emitting layer 142B are mixed, and the electron transport layer 143.

The mixing layer 61 in the pixel 100 is formed in the counter region K in which the first electrode 13 and the organic layer 14 face each other in a plan view of the pixel 100.

The mixing layer 61 has at least a portion formed along the periphery of the insulating structure 60. In the example in FIG. 11, the opening 12A of the insulating layer 12 is located along the outer peripheral edge of the counter region K along the outer peripheral edge of the pixel 100. As the insulating layer 12 functions as the insulating structure 60, the mixing layer 61 is further formed in a portion along the opening 12A of the insulating layer 12 in the outer peripheral edge of the counter region K.

In the example in FIG. 11, the mixing layer 61 formed in each divided region KD includes a first portion 61A extending along the first structure 64A and a second portion 61B formed in a direction extending along the second structure 64B. In the example in FIG. 11, the mixing layer 61 further includes a third portion 61C formed in an L shape. The third portion 61C of the mixing layer 61 is a portion in which the mixing layer 61 is formed as the insulating layer 12 functions as the insulating structure 60. In the mixing layer 61, the first portion 61A, the second portion 61B, and the third portion 61C are joined to one another, and are formed in an annular and rectangular shape.

Note that the example illustrated in FIG. 11 is an example of the mixing layer 61, and the mixing layer 61 is not limited to this. For example, the mixing layer 61 formed in at least a portion of the divided region KD may not include the mixing layer formed in the portion along the opening 12A of the insulating layer 12.

### (Non-Mixing Portions)

The non-mixing portions 63 are formed in each pixel 100. The non-mixing portions 63 are defined as the portions of one pixel 100 excluding the mixing portions 62, which is similar to the aspect described in the first embodiment. The non-mixing portions 63 include the first portions 63A formed in the portions corresponding to the pixel light emitting region KL in one pixel 100, and a second portion excluding the first portions. The second portion is the portion corresponding to the portion in which the insulating structure 60 is formed. In the example in FIGS. 11 and 13, the first portions 63A are formed in a columnar shape inside the mixing portions 62 in the pixel 100. However, this does not prohibit the first portions 63A of the non-mixing portions 63 from being not formed inside the mixing portions 62.

### (Mixing Regions and Non-Mixing Light Emitting Regions)

In the display device 10, each pixel light emitting region KL in the counter region K forming each pixel 100 is divided into a mixing region M21 and a non-mixing light emitting region M22, which is similar to the aspect described in the first embodiment. The mixing regions M21 and the non-mixing light emitting regions M22 are defined in a manner similar to the mixing regions M1 and the non-mixing light emitting regions M2 described in the first embodiment. As for the size of the mixing regions M21, the width WM is preferably 0.5 μm or greater, as described in the first embodiment. Note that, in a region excluding the pixel light emitting regions KL from the counter region K, the no-light emitting region M23 is formed in the region corresponding to the portion in which the insulating structure 60 is provided in a plan view of the pixel 100 (which is a case where the thickness direction of the substrate 11A is the line-of-sight direction).

### [2-2 Functions and Effects]

In the display device 10 according to the second embodiment, in each pixel, in a case where the thickness direction of the substrate 11A is set as the line-of-sight direction, which is a case where the normal direction with respect to the light emitting surface D of the display device 10 is set as the line-of-sight direction, the mixing portions 62 are formed in part of the pixel 100, so that the emission color from the organic layer 14 can be made the emission color corresponding to the pixel 100, as in the first embodiment. Also, the display device 10 according to the second embodiment can be easily manufactured as in the first embodiment, and can be easily made to achieve a higher definition and a smaller size.

### [2-3 Modifications]

In the display device 10 according to the second embodiment, the contents of Modifications 1 to 5 of the first embodiment may be adopted. This is described below in greater detail.

### (Modification 1)

In the display device 10 according to the second embodiment, as illustrated in FIGS. 12A and 12B, the layout of the insulating structure 60 may be different from the layout in the example in FIG. 11, as in Modification 1 of the first embodiment. This mode is referred to as Modification 1 of the second embodiment. FIGS. 12A and 12B are plan views for schematically explaining a pixel 100 in an example of the display device 10 according to Modification 1 of the second embodiment.

In the example illustrated in FIG. 12B, the layout of the first structures 64A and the second structures 64B constituting the insulating structures 60 provided in one pixel 100 is more dense, and the divided regions KD are smaller (the number of divisions of the counter region K is larger), compared with those in the example illustrated in FIG. 12A. Furthermore, in either of the examples illustrated in FIGS. 12A and 12B, the insulating structures 60 are provided in the pixel 100 so that the divided regions KD becomes smaller than those in the example illustrated in FIG. 11. As the divided regions KD become smaller (the width WK becomes smaller) in the order of FIG. 11, FIG. 12A, and FIG. 12C, the proportion of the mixing portions 62 in the organic layer 14 increases, and the occupancy rate of the mixing regions M21 in the pixel light emitting region KL of one pixel 100 becomes higher. The occupancy rate of the mixing regions M21 is defined in a manner similar to that described in the first embodiment. With respect to the occupancy rate of the mixing regions M21, the emission color of the pixel 100 becomes stronger in blue in the order of the example illustrated in FIG. 11A, the example illustrated in FIG. 11B, and the example illustrated in FIG. 11C. That is, blue is stronger in the emission color of the pixel 100 illustrated in FIG. 11C than in the emission color of the pixel 100 illustrated in FIG. 11A. The emission color of the pixel 100 illustrated in FIG. 11B is stronger in blue than the emitting color illustrated in FIG. 11A, and is weaker in blue (stronger in yellow) than the emission color of the pixel 100 illustrated in FIG. 11C.

### (Functions and Effects)

In the display device 10 according to the modification of the second embodiment, the occupancy rate of the mixing regions M21 is adjusted, so that the intermediate color between the color type of the first light emitting layer 142A and the color type of the second light emitting layer 142B can be adjusted as the emission color of the light emitting element 104 in the pixel 100.

### (Modification 2)

In the display device 10 according to the second embodiment, each pixel 100 may include a plurality of sub-pixels 101 corresponding to a plurality of color types, as in Modification 2 and Modification 3 of the first embodiment. This mode is referred to as Modification 2 of the second embodiment. Also, in the display device 10 according to Modification 2 of the second embodiment, color filters 17 (not shown) may be provided, as in Modification 3 of the first embodiment. In this case, the configuration of the pixel 100 described in the second embodiment is adopted for each sub-pixel 101.

In the display device 10 according to Modification 2 of the second embodiment, the sub-pixels corresponding to at least one color type may have a first occupancy rate as the occupancy rate of the mixing regions M1, and the sub-pixels corresponding to at least another color type may have a second occupancy rate as its occupancy rate that is different from the first occupancy rate. In this case, the first occupancy rate can be adjusted in accordance with the size of the divided regions KD (the number of divisions of the counter region K). The same applies to the second occupancy rate. Note that this case includes a case where one of the first occupancy rate and the second occupancy rate is zero.

### (Modification 3)

In the display device 10 according to the second embodiment, the second light emitting layer 142B may include a plurality of light emitting layers 142 corresponding to a plurality of color types, as in Modification 4 of the first embodiment.

### (Modification 4)

In a display device 10 according to Modification 4 of the second embodiment, the mixing layer 51 may be a layer defined by a portion in which components forming the electron transport layer 143 are mixed in the second light emitting layer 142B, as in Modification 5 of the first embodiment.

### 3 Third Embodiment

### [3-1 Configuration of a Display Device]

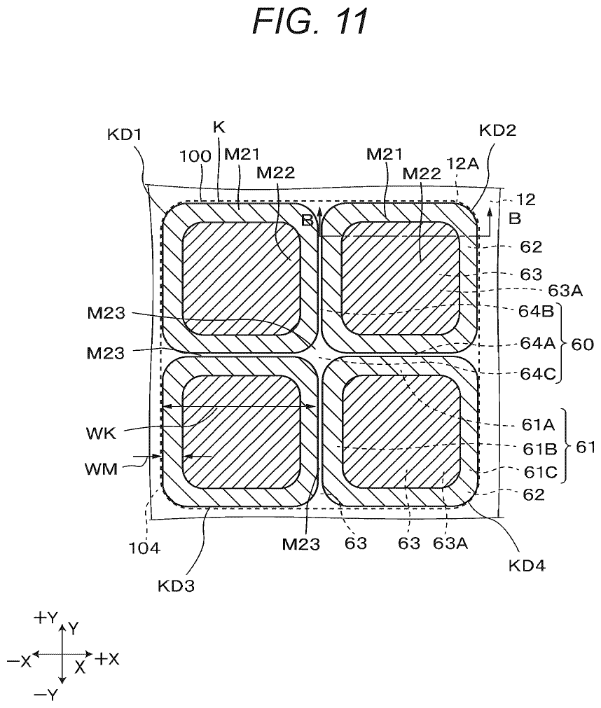

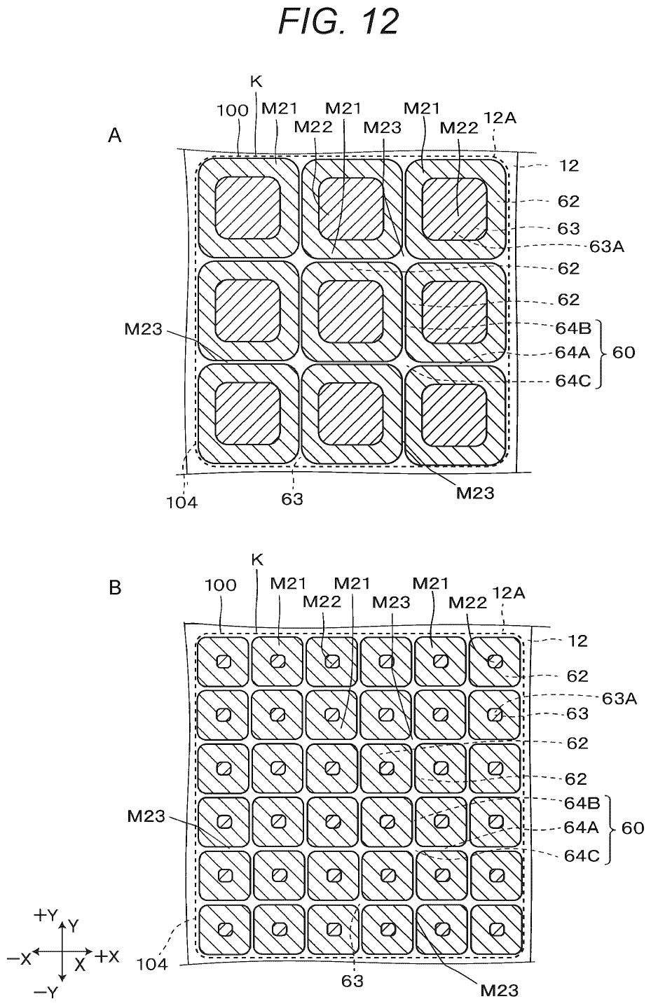

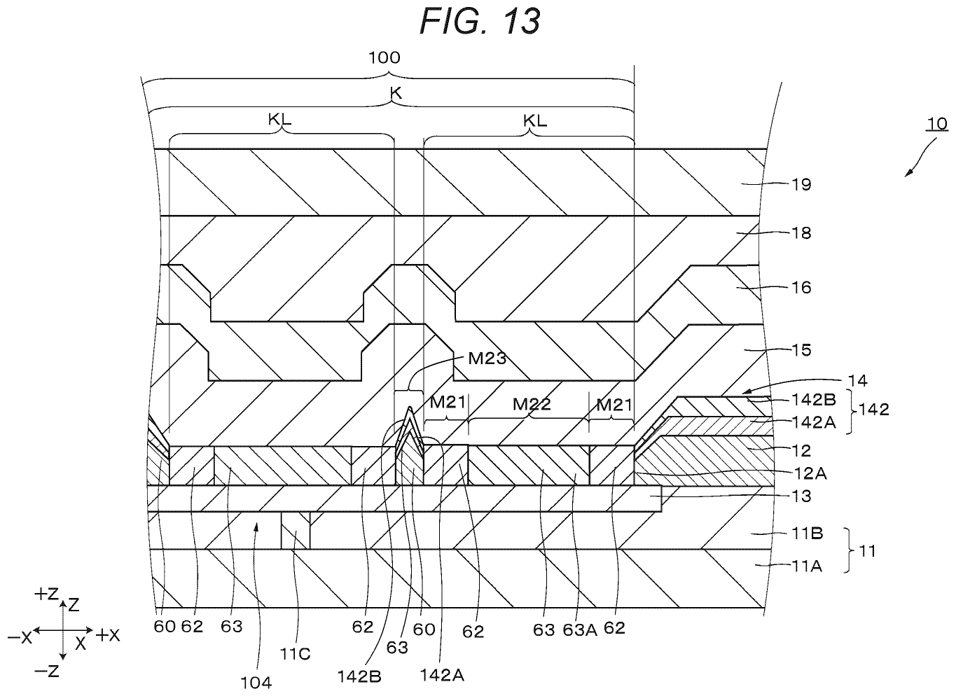

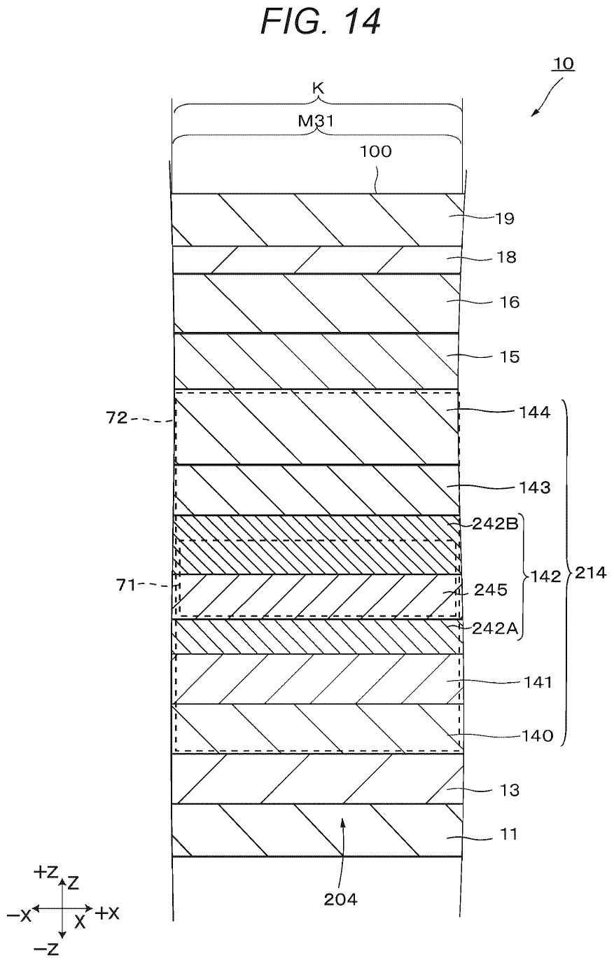

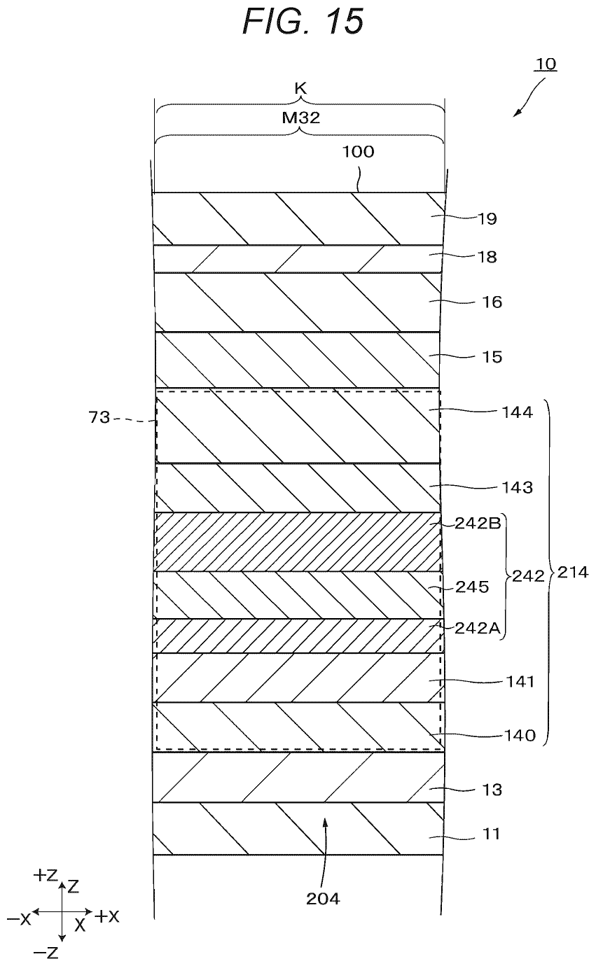

In a display device 10 according to a third embodiment, in a mixing layer 71 formed in a mixing portion 72 in an organic layer 214, a component forming a layer located on the side of the first electrodes 13 are mixed with a component forming the layer located on the side of the second electrode 15, as illustrated in FIG. 14. FIG. 14 is a cross-sectional diagram schematically illustrating the respective layer components of the mixing portion 72 in the organic layer 14 in the display device 10 according to the third embodiment. In FIG. 14, the layer components before the mixing layer 71 is formed are indicated by solid lines, and the mixing layer 71 is indicated by a dashed line. FIG. 15 is a cross-sectional diagram schematically illustrating the respective layer components of a non-mixing portion 73 in the organic layer 214 in the display device 10 according to the third embodiment.

In the display device 10 according to the third embodiment, the other layer components (such as the first electrodes 13 and the second electrode 15, for example) and structures excluding the organic layer 214 formed in the light emitting elements 204 may be similar to those of the display device 10 according to the first embodiment or the second embodiment illustrated in FIGS. 3, 13, or the like. Therefore, the same reference numerals as those used in the first embodiment or the second embodiment denote those components, and detailed explanation of them is not made herein.

### (Configuration of Pixels)

In the example of the display device 10 illustrated in FIGS. 14 and 15, each one pixel 100 is formed as a pixel corresponding to one color type. In this example, red is defined as a plurality of color types, and pixels 100 are provided as the pixels that perform red-color display. However, this is an example, and does not exclude cases where the emission color of the pixels 100 is other than red.

### (Light Emitting Elements)

In the display device 10 according to the third embodiment, a plurality of light emitting elements 204 is provided on the first surface of the drive substrate 11. The light emitting elements 204 are organic electroluminescence elements (organic EL elements), as described in the first embodiment. The light emitting elements 204 has a configuration similar to that of the light emitting elements 104 described in the first embodiment, except for the configuration of the organic layer 214. Also, in this example, light emitting elements that can emit red light corresponding to the pixels 100 as the light emitted from the light emitting surface are provided as the plurality of light emitting elements 204. The plurality of light emitting elements 204 is two-dimensionally arranged in a prescribed arrangement pattern such as a matrix form or the like, for example.

The light emitting elements 204 each include the first electrode 13, the organic layer 214, and the second electrode 15. The first electrode 13, the organic layer 14, and the second electrode 15 are stacked in this order in the direction from the side of the drive substrate 11 in the direction from the second surface toward the first surface.

### (Organic Layer)

The organic layer 214 in the display device 10 according to the third embodiment includes a plurality of functional layers including a plurality of light emitting layers, as in the first embodiment. In the example illustrated in FIGS. 14 and 15, the organic layer 214 has a configuration in which a hole injection layer 140, a hole transport layer 141, a light emitting layer 242, and an electron transport layer 143 are stacked in this order in the direction from the first electrode 13 toward the second electrode 15 (the side closer to the first electrode 13). As illustrated in FIGS. 14 and 15, an electron injection layer 144 is preferably provided between the electron transport layer and the second electrode 15. In this example, the organic layer 214 includes the hole injection layer 140, the hole transport layer 141, the light emitting layer 242, the electron transport layer 143, and the electron injection layer 144 as the functional layers. As the electron injection layer 144, the hole injection layer 140, the hole transport layer 141, and the electron transport layer 143, layers similar to those described in the first embodiment may be used.

### (Light Emitting Layers)

The organic layer 214 includes a plurality of types of light emitting layers 242 that differ in color type. In the example in FIGS. 14 and 15, a first light emitting layer 242A and a second light emitting layer 242B are included as the light emitting layer 242. Further, the organic layer 214 includes an intermediate layer 245 between the first light emitting layer 242A and the second light emitting layer 242B. The organic layer 214 has a configuration in which the hole injection layer 140, the hole transport layer 141, the first light emitting layer 242A, the intermediate layer 245, the second light emitting layer 242B, and the electron transport layer 143 are stacked in this order in the direction from the first electrode 13 toward the second electrode 15. Note that, in the present specification, in a case where the first light emitting layer 242A and the second light emitting layer 242B are not distinguished from each other, the first light emitting layer 242A and the second light emitting layer 242B are collectively referred to as the light emitting layer 242.

In the light emitting layer 242, recombination of electrons and holes occurs when an electric field is applied, and thus, light is generated, as in the light emitting layer 142 described in the first embodiment. The light emitting layer 242 is an organic compound layer containing an organic light emitting material.

### (First Light Emitting Layer and Second Light Emitting Layer)

In the example illustrated in FIGS. 14 and 15, the first light emitting layer 242A is a red light emitting layer having red as its emission color. The second light emitting layer 242B is a blue light emitting layer having blue as its emission color. In this case, the light emission color of the light emitting elements 204 is red or reddish pink.

### (Red Light Emitting Layer)

In the red light emitting layer, when an electric field is applied, some of holes injected from the first electrode 13 through the hole injection layer 140 and the hole transport layer 141, and some of electrons injected from the second electrode 15 through the electron transport layer 143 are recombined to generate red light. The red light emitting layer contains at least one of a red light emitting material, a hole transport material, an electron transport material, or both-charges transport material, for example. Specifically, as the red light emitting material, a material obtained by mixing 4,4-bis(2,2-diphenylvinin) biphenyl (DPVBi) with 30 weight % of 2,6-bis[(4′-methoxydiphenylamino) styryl]-1,5-dicyanonaphthalene (BSN) can be used. As the red light emitting material, a phosphorescent material is preferably used to facilitate the formation of the mixing layer described later. In a case where the red light emitting material is a fluorescent material, the first light emitting layer 242A is a fluorescent light emitting layer.

### (Blue Light Emitting Layer)

The blue light emitting layer may be formed in a manner similar to the blue light emitting layer described in the first embodiment. As described in the first embodiment, in a case where the blue light emitting material is a fluorescent material, the second light emitting layer 242B is a fluorescent light emitting layer.

### (Intermediate Layer)

The intermediate layer 245 is a layer for adjusting injection of carriers into the light emitting layer 242, and electrons or holes are injected into each of the layers constituting the light emitting layer 242 through the intermediate layer 245, so that balance of emission among the respective colors is adjusted.

In the intermediate layer 245, the energy level at the S1 level (primary electron excited state) of the intermediate layer 245 is preferably higher than the energy level at the S1 level of the second light emitting layer 242B, and the energy level at the S1 level of the intermediate layer 245 is preferably higher than the energy level at the S1 level of the first light emitting layer 242A. As such an intermediate layer 245 is formed, light emission by the component (the blue light emitting material or the like) that causes light emission from the second light emitting layer 242B and the component (the red light emitting material or the like) that causes light emission from the first light emitting layer 242A can be efficiently achieved.

### (Insulating Structures)

In the display device 10 according to the third embodiment, at least one insulating structure 55 is formed between the first electrode 13 and the organic layer 214, as in the first embodiment. Since the configuration of the insulating structure 55 is similar to that of the first embodiment, explanation thereof is not made herein. Note that, in the display device according to the third embodiment, the insulating structure 55 may be replaced with or be used in conjunction with the insulating structure 60 described in the second embodiment. However, a case where the insulating structure 55 is provided in the display device according to the third embodiment is described as an example herein, and this description will be continued below.

### (Mixing Portions)

In the organic layer 214 in each pixel 100, the mixing portions 72 including the mixing layer 71 are formed in part of the organic layer 214 in a case where the thickness direction of the drive substrate 11 is the line-of-sight direction (a case where a direction parallel to the Z-axis direction is the line-of-sight direction in FIG. 14), as in the first embodiment. The mixing portions 72 are defined in a manner similar to the mixing portions 72 described in the first embodiment.

### (Mixing Layer)

The mixing layer 71 is defined in accordance with conditions (prescribed conditions) similar to those for the mixing layer 51 described in the first embodiment.

In the third embodiment, the mixing layer 71 has a layer that is defined by a portion where a component forming at least one layer of the plurality of types of light emitting layers 242 and a component forming at least an adjacent layer to the one layer are mixed.

More specifically, in a case where a first position is selected from a mixing region M31 described later as illustrated in FIG. 14, and a second position is selected from a non-mixing light emitting region M32 described later as illustrated in FIG. 15 as different positions in the plane direction of the organic layer 14, for example, a layer obtained by mixing a component (organic material) forming the first light emitting layer 242A and a component (organic material) forming the intermediate layer 245 in the functional layers constituting the organic layer 214 is observed at the first position. This layer is not observed at the second position. At this point of time, this layer is the mixing layer 71. Of the portion of the organic layer 214 extending in the plane direction of the organic layer 214, the portion in which the mixing layer 71 is formed serves as the mixing portion 72.

In the example in FIGS. 14 and 15, a component forming the first light emitting layer 242A is diffused into the second light emitting layer 242B. The mixing layer 71 is a layer obtained by combining a layer in which a component forming the first light emitting layer 242A and a component forming the intermediate layer 245 adjacent to the first light emitting layer 242A are mixed, and a layer formed with a portion in which a component forming the first light emitting layer 242A and a component forming the second light emitting layer 242B are mixed. However, FIG. 14 shows an example of the mixing layer 71, and does not limit the embodiment to a case where the component forming the first light emitting layer 242A is diffused into the second light emitting layer 242B.

Also, the mixing layer 71 in the pixel 100 is formed in the counter region K in which the first electrode 13 and the organic layer 214 face each other in a plan view of the pixel 100.

The mixing portions 72, which are the portions in which the mixing layer 71 is formed, are formed around the insulating structures 55, for example, in a case where the thickness direction of the substrate 11A is the line-of-sight direction, which is similar to the aspect described in the first embodiment.

### (Non-Mixing Portions)

The non-mixing portions 73 are formed in the pixels 100. As in the first embodiment, the non-mixing portions 73 are defined as portions obtained by removing the mixing portions 72 from the organic layer 214.

### (Mixing Regions and Non-Mixing Light Emitting Regions)

In the display device 10, a pixel light emitting region KL of the counter region K forming each pixel 100 is divided into a mixing region M31 and a non-mixing light emitting region M32, as in the first embodiment. The mixing regions M31 and the non-mixing light emitting regions M32 are defined in a manner similar to the mixing regions M1 and the non-mixing light emitting regions M2 described in the first embodiment, respectively. Note that, although not shown in the drawings, the no-light emitting regions excluding the pixel light emitting regions KL from the counter region K is also defined in a manner similar to the no-light emitting regions M3 described in the first embodiment.

### (Emission Colors)

In the organic layer 214, the emission color (first color) to be generated in the non-mixing portions 73 is different from the emission color (second color) to be generated in the mixing portions 72, which is similar to the aspect described in the first embodiment. The emission color generated from the organic layer 14 is a mixed color of the first color and the second color. In a case where the organic layer 214 includes a red light emitting layer as the first light emitting layer 242A, and a blue light emitting layer as the second light emitting layer 242B, the emission color in the mixing regions M31 in the pixel 100 is normally red light. The emission color in the non-mixing light emitting regions M32 in the pixels 100 is normally the color of light (pink light) obtained by combining red light and blue light. The emission color of the pixel 100 becomes closer to red as the occupancy rate of the mixing regions M31 becomes higher. As the occupancy rate of the mixing regions M31 becomes lower, the color becomes closer to pink. In the pixels 100 of the display device 10, the mixing regions M31 are formed in the counter region K. Accordingly, the emission color of the organic layer 14 is red, and the emission color of each pixel 100 is substantially red, or is pink with increased redness. Note that the occupancy rate of the mixing regions M31 is determined in a manner similar to the manner in which the occupancy rate of the mixing regions M1 described in the first embodiment is determined.

### [3-2 Functions and Effects]

In each pixel in the display device 10 according to the third embodiment, the mixing portions 72 are formed in part of the pixel 100, and the non-mixing portion 73 is also formed, in a case where the normal direction with respect to the thickness direction of the substrate 11A is the line-of-sight direction, which is a case where the normal direction with respect to the light emitting surface D of the display device 10 is the line-of-sight direction. In the mixing regions M31 corresponding to the mixing portions 72, light emission in the first light emitting layer 242A is stronger than light emission in the non-mixing light emitting regions M32, and light emission in the second light emitting layer 242B is weaker. Accordingly, the color of light emission from the organic layer 214 is closer to the emission color in the first light emitting layer 242A. In the example in FIGS. 14 and 15, the emission color in the first light emitting layer 242A is red, and the emission color in the second light emitting layer 242B is blue. Accordingly, the emission color in the non-mixing light emitting regions M32 in the organic layer 214 is normally a color close to pink, and the emission color in the mixing regions M31 is a color closer to red than the emission color in the non-mixing light emitting regions M32. As the mixing regions M31 are formed in the pixels 100 as illustrated in FIG. 14, the emission color is substantially red.

As described above, in the display device 10, the color of light emission from the organic layer 214 can be made an emission color corresponding to the pixels 100.

Also, in the display device 10, it is possible to adjust the color of light emission from the light emitting elements 204 by adjusting the layout of the insulating structures 55 and the like even when the light emitting elements 204 are miniaturized. Accordingly, the display device can be easily manufactured, and thus, the display device can be easily made to achieve high definition and be made smaller in size.

### [3-3 Modifications]

Note that, as described below, any of the configurations of Modifications 1 to 4 of the first embodiment and Modifications 1 to 3 of the second embodiment may be applied to the display device 10 according to the third embodiment.

### (Modification 1)

In the display device 10 according to the third embodiment, each pixel 100 may include a plurality of sub-pixels 101 corresponding to a plurality of color types, as in Modification 2 of the first embodiment, Modification 2 of the second embodiment, and others. For example, in a case where the first light emitting layer 242A is a red light emitting layer while the second light emitting layer 242B is a blue light emitting layer as described above, the display device 10 may has red sub-pixels (sub-pixels having red as the emission color) and pink sub-pixels (sub-pixels having pink as the emission color) as the sub-pixels corresponding to a plurality of color types. In this case, the sub-pixels that include light emitting elements provided with the insulating structures 55 can be set as the red sub-pixels, and the sub-pixels that include the light emitting elements not provided with the insulating structures 55 can be set as pink sub-pixels. By adjusting the insulating structures 55, it is possible to form the sub-pixels corresponding to a plurality of color types on the same substrate.

Also, in the display device 10 according to Modification 2 of the third embodiment, color filters 17 may be provided, as in Modification 3 of the first embodiment, Modification 2 of the second embodiment, and others.

### (Modification 2)

In the display device 10 according to the third embodiment, the second light emitting layer 242B may include a plurality of light emitting layers corresponding to a plurality of color types, as in Modification 4 of the first embodiment and others. For example, the first light emitting layer 242A may be a red light emitting layer having red as its emission color, and the second light emitting layer 242B may have a stack structure that is formed with a green fluorescent light emitting layer having green as its emission color and a blue fluorescent light emitting layer having blue as its emission color. In addition to the above, the second light emitting layer 242B may be a light emitting layer having blue-green as its emission color.

### 4 Fourth Embodiment

### [4-1 Configuration of a Display Device]

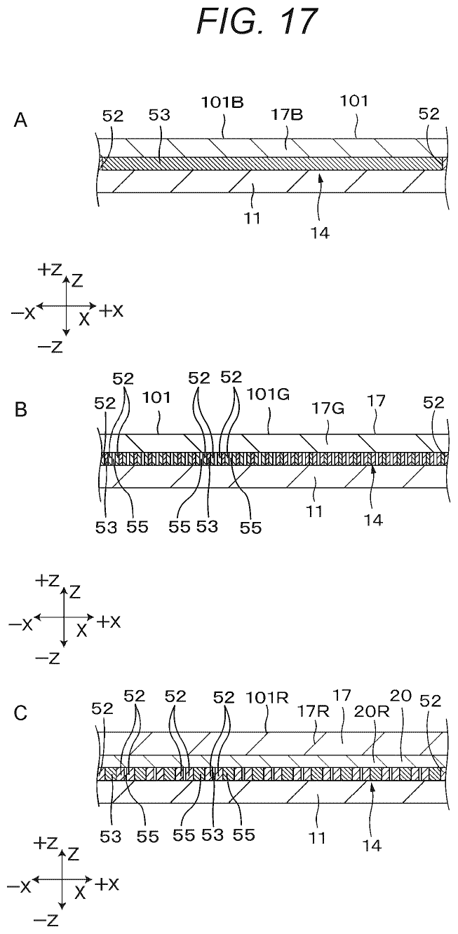

In a display device 10 according to a fourth embodiment, a plurality of sub-pixels 101 corresponding to a plurality of color types is provided, as illustrated in FIG. 17A to 17C. Also, each of the sub-pixels 101 includes a drive substrate 11 including a substrate 11A, a first electrode 13, an organic layer 14, and a second electrode 15, and has a sub-pixel light emitting region KS as the light emitting region, and a mixing layer 51 is formed in sub-pixels 101 corresponding to at least one color type. Further, as illustrated in FIGS. 17A to 17C, in the display device 10 according to the fourth embodiment, a color conversion layer 20 is provided in at least one type of the sub-pixels 101. FIGS. 17A to 17C are cross-sectional views for explaining an example of a sub-pixel 101 of each color type in the display device 10 according to the fourth embodiment. In FIG. 17A to 17C, for ease of explanation, the insulating layer 12, the first electrodes 13, the second electrode 15, the protective layer 16, the filling resin layer 18, and the counter substrate 19 are not shown. Further, the respective layers constituting the organic layer 14 and the components between adjacent sub-pixels 101 are not shown, and the organic layer 14 covering the insulating structures 55 is not shown.

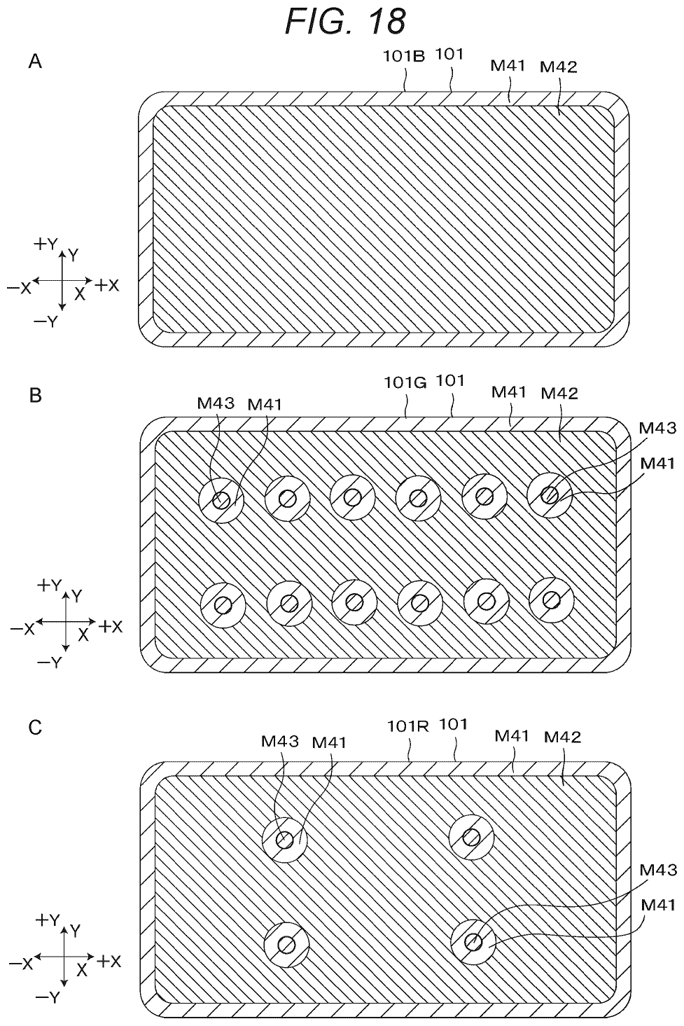

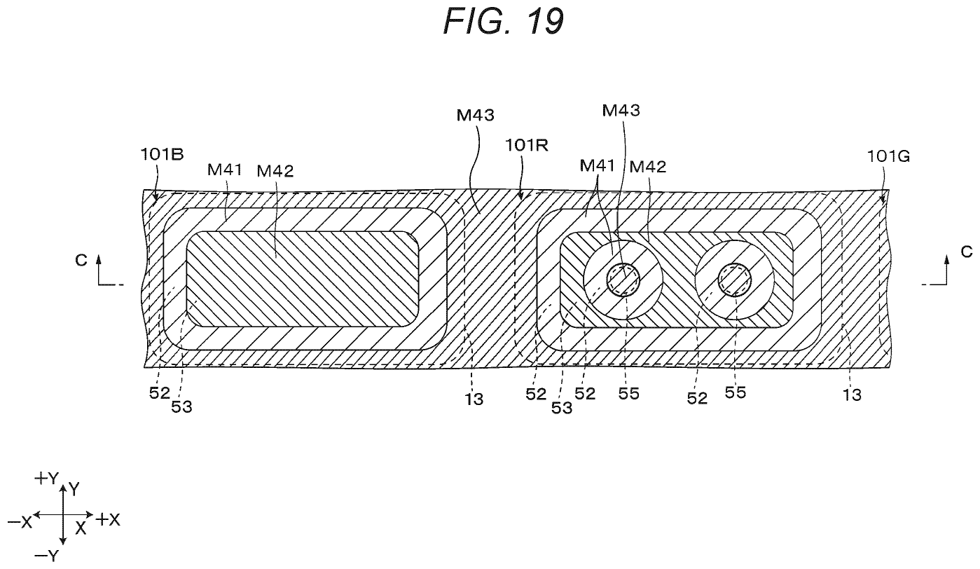

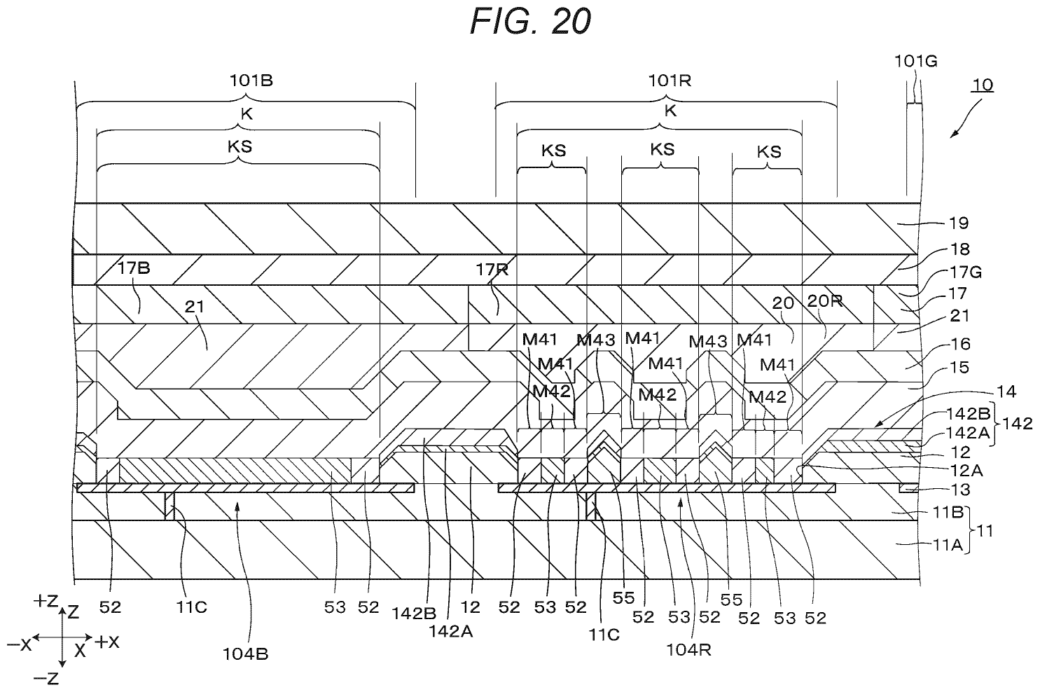

FIG. 19 is a plan view for explaining adjacent sub-pixels 101. FIG. 20 is a cross-sectional diagram schematically illustrating a longitudinal cross-section taken along the line C-C defined in FIG. 19. In the display device 10 according to the fourth embodiment, the respective structures of the insulating structures 55, the mixing portions 52, and the non-mixing portions 53 may be similar to those of the display device 10 according to the first embodiment. In the fourth embodiment, the insulating structures 55, the mixing portions 52, and the non-mixing portions 53 are denoted by the same reference numerals as those in the first embodiment in FIG. 19, FIG. 20, and others, and detailed explanation of them is not made herein.

Further, as illustrated in FIGS. 19 and 20, in the display device 10 according to the fourth embodiment, the layer structures excluding the color conversion layer 20 and a planarizing layer 21, which are the structures of the respective layers such as the drive substrate 11 including the substrate 11A, the first electrodes 13, the respective layers constituting the organic layer 14, and the second electrode 15, for example, may be similar to those of the display device 10 according to the first embodiment. In the fourth embodiment, the layer structures, excluding the color conversion layer 20 and the planarizing layer 21, are denoted by the same reference numerals as those in the first embodiment, and detailed explanation of them is not made herein, except for the characteristic components.

In FIG. 20, for ease of explanation, the respective layers, except for the light emitting layers 142, are not shown in the portions of the organic layer 14 formed outside the counter regions K and the portions of the organic layer 14 corresponding to the no-light emitting regions M23 in a plan view of the display device 10 (in a case where the thickness direction of the substrate 11A is the line-of-sight direction), as in FIG. 3 and others used in the description of the first embodiment. Also, regarding the portions of the organic layer 14 formed inside the counter regions K, mixing portions 52 and non-mixing portions 53 described later are shown, and the respective layers in each portion of the mixing portions 52 and the non-mixing portions 53 are not shown.

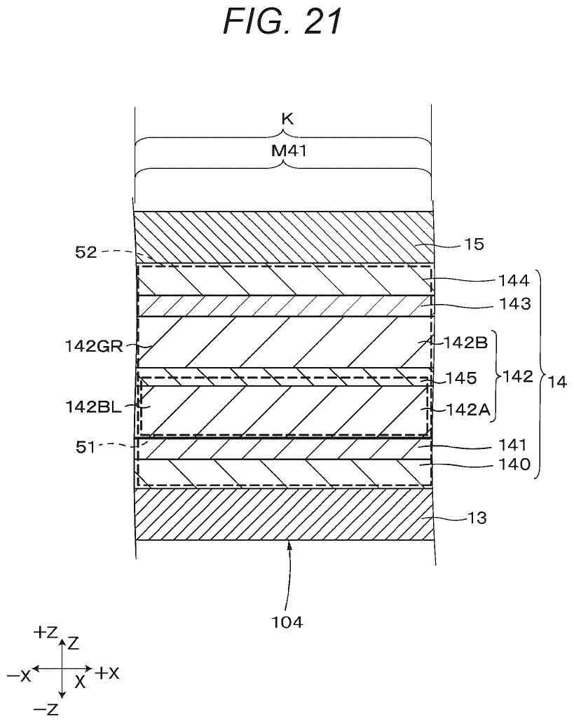

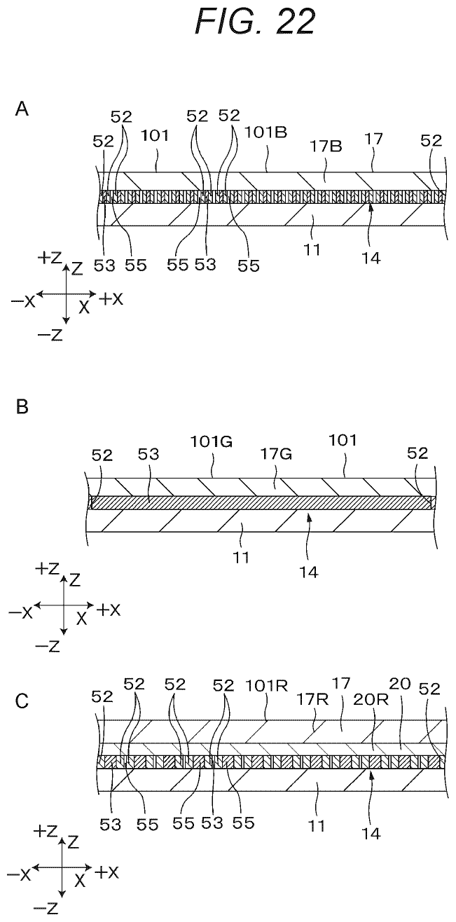

Further, in the sub-pixels 101 corresponding to the respective color types in FIGS. 17, 18, 19, and 20, the layout such as the number of the insulating structures 55 formed in a sub-pixel 101 is not described in a comprehensive manner, for ease of explanation. The same applies in FIGS. 22, 23, 24, and 25. FIGS. 18A, 18B, and 18C are plan views for explaining an example of the layout of mixing regions and non-mixing regions in an example of the sub-pixels 101 of the display device 10 according to the fourth embodiment.

In the display device 10 according to the fourth embodiment, the substrate 11A forming the drive substrate 11, and the respective layers constituting the organic layer 14 may be layers shared among a plurality of sub-pixels 101 corresponding to a plurality of color types, as illustrated in FIGS. 19 and 20. The same applies in the fifth and sixth embodiments described later.

### (Configuration of Sub-Pixels)

In the display device 10 according to the fourth embodiment, each pixel may be formed with a combination of a plurality of sub-pixels 101 corresponding to a plurality of color types. In the example in FIGS. 17 to 21, also as illustrated in Modification 3 of the first embodiment, the three colors of red, green, and blue are defined as the combination of the plurality of sub-pixels 101 that constitute one pixel and correspond to the plurality of color types on the same drive substrate 11, and the three types of a sub-pixel 101R (red sub-pixel), a sub-pixel 101G (green sub-pixel), and a sub-pixel 101B (blue sub-pixel) are provided as the sub-pixels 101. Furthermore, examples of layouts of the individual sub-pixels 101R, 101G, and 101B include a layout in which combinations of sub-pixels 101 formed in a rectangular shape are arranged in a matrix fashion. In the example in FIGS. 17 to 21, the sub-pixels 101R, 101G, and 101B are two-dimensionally provided in the display region 10A. However, the example in FIGS. 17 to 21 are merely an example.

### (Organic Layer)

The organic layer 14 has a structure in which a plurality of functional layers including a plurality of types of light emitting layers that differ in color type is stacked. The organic layer 14 in the display device 10 according to the fourth embodiment may use a structure similar to the layer structure described in the first embodiment, and has a configuration in which a hole injection layer 140, a hole transport layer 141, a first light emitting layer 142A, an intermediate layer 145, a second light emitting layer 142B, and an electron transport layer 143 are stacked in this order in the direction from the first electrodes 13 toward the second electrode 15 (from the side closer to the first electrodes 13) as illustrated in FIG. 21. In this case, the first light emitting layer 142A and the second light emitting layer 142B are light emitting layers 142 that differ from each other in color type.

### (First Light Emitting Layer and Second Light Emitting Layer)

The color types of the plurality of light emitting layers 142 (the first light emitting layer 142A and the second light emitting layer 142B) may be defined as appropriate, but are blue and green in the example illustrated in FIG. 20, FIG. 21, and others. Therefore, in this example, the first light emitting layer 142A is a blue light emitting layer 142BL having blue as its emission color. The second light emitting layer 142B is a green light emitting layer 142GR having green as its emission color.

### (Blue Light Emitting Layer)

The blue light emitting layer 142BL may be formed in a manner similar to the blue light emitting layer described in the first embodiment.

### (Green Light Emitting Layer)

In the green light emitting layer 142GR, when an electric field is applied, some of holes injected from the first electrode 13 through the hole injection layer 140 and the hole transport layer 141, and some of electrons injected from the second electrode 15 through the electron transport layer 143 are recombined to generate green light. The green light emitting layer 142GR contains at least one of a green light emitting material, a hole transport material, an electron transport material, or both-charges transport material, for example.

### (Mixing Layer)

The mixing layer 51 according to the fourth embodiment is a layer formed by combining a layer in which a component forming the hole transport layer 141 is mixed with the first light emitting layer 142A, and a layer in which a component forming the hole transport layer 141 is mixed with part of the intermediate layer 145. However, this example does not limit the mixing layer 51 to that in a case where a component forming the hole transport layer 141 reaches the intermediate layer 145.

Also, as for the mixing layer 51 in the sub-pixels 101, the mixing layer 51 is formed along the openings 12A in the example in FIGS. 18A, 18B, 18C, 19, and 20. As illustrated in FIGS. 18B, 18C, and 19, for example, the mixing layer 51 is further formed around the insulating structures 55 formed inside the openings 12A in a plan view of the display device 10, as in the first embodiment.

### (Emission Colors)

In the fourth embodiment, the emission color of mixing regions M41 and the emission color of non-mixing regions (non-mixing light emitting regions M42) are different in the light emitting regions (sub-pixel light emitting regions KS), as described also in the first embodiment. In a case where a sub-pixel 101 includes a mixing portion 52 and a non-mixing portion 53, the emission color to be generated from the organic layer 14 in the sub-pixel 101 is a mixed color of the emission color of the mixing regions M41 and the emission color of the non-mixing light emitting regions M42.

In a mixing region M41, as illustrated in FIG. 21, in a case where the light emitting element 104 is energized, collision between holes and electrons in the organic layer 14 is likely to occur in the second light emitting layer 142B, and light emission from the second light emitting layer 142B mainly occurs. In a non-mixing light emitting region M42, collision between holes and electrons occurs normally in the first light emitting layer 142A, and light emission from the first light emitting layer 142A mainly occurs. Such light emission can be achieved by adjusting the structures (thickness and the like) and compositions (materials and the like) of the intermediate layer 145, the hole injection layer 140, the hole transport layer 141, the electron transport layer 143, and the electron injection layer 144.

In the example in FIG. 19, the light emission in the non-mixing light emitting regions M42 is mainly blue light emitted by the blue light emitting layer 142BL provided as the first light emitting layer 142A (the emission color in the non-mixing light emitting regions M42 is blue), and the light emission in the mixing regions M41 is mainly green light emitted by the green light emitting layer 142GR provided as the second light emitting layer 142B (the emission color in the mixing regions M41 is green).

### (Color Conversion Layer)

In the display device 10 according to the fourth embodiment, as illustrated in FIGS. 17C and 20, sub-pixels 101 corresponding to at least one color type include the color conversion layer 20. The color conversion layer 20 is preferably provided on the protective layer 16, as illustrated in FIG. 20. In a case where the color conversion layer 20 is provided on the protective layer 16, even if irregularities are formed on the first surface side of the protective layer 16 by the insulating structures 55 or the like, the color conversion layer 20 is formed to fill the irregularities on the first surface side of the protective layer 16, so that the first surface can be easily planarized.

In the display device 10 according to the fourth embodiment, in the sub-pixels 101 including the color conversion layer 20, the color conversion layer 20 converts the color of light generated in the organic layer 14. The color conversion layer 20 is a layer corresponding to the color type of the sub-pixel 101. In the example of the display device 10 illustrated in FIG. 20, a sub-pixel 101R includes the color conversion layer 20, and a red-color conversion layer 20R is provided as the color conversion layer 20. The red-color conversion layer 20R causes light to be emitted from the red-color conversion layer 20R, with incident light having been converted into red light. In the example illustrated in FIGS. 17C and 20, light generated in the organic layer 14 of the sub-pixel 101R passes through the red-color conversion layer 20R, to be converted into red light.

The color conversion layer 20 is not limited to any particular layer, as long as it is a layer capable of converting a color of light. An example of the color conversion layer 20 can be a layer containing a color conversion material in resin or the like. Examples of the color conversion material include organic fluorescent dyes, organic fluorescent pigments, inorganic phosphors, quantum dots, perovskites, and the like.

The color conversion material is specifically determined in accordance with the color type of light to be emitted from the color conversion layer 20.

Examples of the organic fluorescent dyes include a rhodamine derivative, an indenoperylene derivative, and the like. Examples of the organic fluorescent pigments include Lumogen and the like. In the example in FIGS. 17C and 20, rhodamine or the like can be used. Examples of the inorganic phosphors include SrSEu, BaSEu, and the like. In the example in FIGS. 17C and 20, SrSEu or the like can be used.

Examples of the quantum dots include a structure that includes a core portion formed with a compound semiconductor, and a shell layer that covers the peripheral surface of the core portion and is formed with a semiconductor or the like. In the example in FIG. 17C and others, a quantum dot layer including red quantum dots that are quantum dots to be converted into red light may be provided as the color conversion layer 20. In a case where quantum dots are used as the color conversion material, the color conversion layer is a so-called quantum dot layer. Examples of the perovskites include those having a perovskite structure as the crystal structure, such as CsPbBr and CsPbCl.

### (Sub-Pixel Light Emitting Regions)

Among the sub-pixels 101, the regions in which the respective sub-pixels 101 are formed are counter regions K. Of the regions (counter regions K) in which the sub-pixels 101 are formed, the regions excluding no-light emitting regions M43 are the light emitting regions (corresponding to the sub-pixel light emitting regions KS) in the sub-pixels 101. In the example illustrated in FIG. 20 and others, in a plan view of sub-pixels 101G and 101R (which is a case where the thickness direction of the substrate 11A is the line-of-sight direction), the regions corresponding to the portions in which the insulating structures 55 are provided are the no-light emitting regions M43.

### (Mixing Regions and Non-Mixing Light Emitting Regions)

In the display device 10, as illustrated in FIGS. 18B, 18C, and 20, the mixing portions 52 are formed around the insulating structures 55 at least in a plan view of the sub-pixels 101G and 101R, and the mixing regions M41 are defined as regions that are observed in a case where the thickness direction of the organic layer 14 is the line-of-sight direction, and as regions in which the mixing layer 51 is formed (which is a region in which the mixing portions 52 are formed). In the fourth embodiment, the insulating layer 12 is formed between the sub-pixels 101, and the mixing portions 52 are also formed in the vicinities of the openings 12A. Therefore, the mixing regions M41 are also formed in the regions corresponding to the vicinities of the openings 12A.

In the example in FIGS. 17, 18, 19, and 20, the mixing regions M41 are formed along the openings 12A for the sub-pixels 101 of any color type. Further, in the sub-pixels 101G and the sub-pixels 101R, the mixing regions M41 are also formed around the insulating structures 55. Note that, as illustrated in the example in FIGS. 19A and 20, formation of the insulating structures 55 is avoided in the sub-pixels 101B.

### (Occupancy Rate Depending on Color Types of Sub-Pixels)

In the display device 10 according to the fourth embodiment, the mixing layer 51 is formed so that the entire area of the mixing regions M41 varies among the sub-pixels 101 of a plurality of types corresponding to the different color types among the sub-pixels 101. Therefore, in a case where sub-pixels 101 in which the mixing regions M41 are formed are a first sub-pixel and a second sub-pixel, the occupancy rate of the mixing regions M41 determined for the first sub-pixel and the occupancy rate of the mixing regions M41 determined for the second sub-pixel are different from each other. Here, the occupancy rate of the mixing regions M41 indicates the proportion of the mixing regions M41 in the light emitting region (sub-pixel light emitting region KS) of the sub-pixel 101, as described in the first embodiment. The occupancy rate of the mixing regions M41 can be determined in accordance with the layout of the insulating structures 55.

As illustrated in the example in FIGS. 17A to 17C, 18A to 18C, 19, and 20, the occupancy rate of the mixing regions M41 of each sub-pixel 101B is lower than the occupancy rate of the mixing regions M41 of the other sub-pixels 101R and 101G. In each sub-pixel 101B, the non-mixing light emitting region M42 substantially occupies the sub-pixel 101B, except for the outer peripheral edge of the region in which the sub-pixel 101B is formed (the peripheral edge of the opening 12A). In this case, in the sub-pixel 101B, the emission color of the organic layer 14 is normally blue.

Further, in a case where the sub-pixels 101R and 101G are the first sub-pixel and the second sub-pixel, the occupancy rate of the mixing regions M41 determined for the first sub-pixel and the occupancy rate of the mixing regions M41 determined for the second sub-pixel are different from each other. Specifically, in the example in FIG. 20, the occupancy rate of the mixing regions M41 of the sub-pixel 101R is lower than the occupancy of the mixing regions M41 of the sub-pixel 101G. Further, in the fourth embodiment, the occupancy rate of the mixing regions M41 for the sub-pixel 101R provided with the color conversion layer 20 is a value between the occupancy rate of the mixing regions M41 for the sub-pixel 101B, which is another sub-pixel 101, and the occupancy rate of the mixing regions M41 for the sub-pixel 101G. In the sub-pixel 101G, the occupancy rate of the mixing regions is higher than those in the other sub-pixels 101B and 101R, and the emission color of the organic layer 14 is substantially green. In the sub-pixel 101R, the emission color of the organic layer 14 is a substantially intermediate color (mixed color) between green and blue, compared with the emission colors of the organic layer 14 in the other sub-pixels 101B and 101G.

The sub-pixel 101R has the red-color conversion layer 20R as the color conversion layer 20. Normally, the color conversion efficiency in converting incident light into red light with the red-color conversion layer 20R is often higher in a case where the incident light is light corresponding to an intermediate color between blue and green than in a case where the light incident on the red-color conversion layer 20R is blue light or green light. From the viewpoint of such color conversion efficiency, the emission color of the organic layer 14 in the sub-pixel 101R is preferably a substantially intermediate color between green and blue. Therefore, the occupancy rate of the mixing regions M41 of the sub-pixel 101R is preferably set to a value between those of the sub-pixel 101B and the sub-pixel 101G.

The magnitudes of the occupancy rates of the mixing regions M41 in the sub-pixels 101R and 101G can be achieved by adjusting the layout of the insulating structures 55 in the sub-pixel 101G and the sub-pixel 101R. As for such layout adjustment, an example of the layout may be a layout in which the insulating structures 55 are formed so that the diameters of the individual insulating structures 55 provided in the sub-pixels 101G and 101G become substantially the same, and the number of the insulating structures 55 disposed in the sub-pixel 101G becomes larger than that in the sub-pixel 101R, as in the example in FIGS. 18B and 18C.

### (Planarizing Layer)

In the display device 10, as illustrated in FIG. 20, the planarizing layer 21 is preferably provided so as to cover the protective layer 16 in each sub-pixel 101 in which the formation of the color conversion layer 20 is avoided. The material of the planarizing layer 21 may be a resin or the like, for example. As the planarizing layer 21 is provided, the surface irregularities can be reduced by the combination of the color conversion layer 20 and the planarizing layer 21.

### (Color Filters)

In the display device 10 according to the fourth embodiment, color filters 17 are preferably provided as illustrated in FIG. 20. The color filters 17 may be similar to the color filters described in Modification 3 of the first embodiment. The color filters 17 may not be provided in at least some of the sub-pixels 101. For example, the color filters 17 for the sub-pixels 101R may not be provided. In this case, the portions from which the color filters 17 are omitted may be filled with resin.

Note that, in the fourth embodiment, an example in which the insulating structures 55 are provided has been described. However, the insulating structure described in the second embodiment may be adopted, instead of the insulating structures 55.

### [4-2 Functions and Effects]

In the display device 10 according to the fourth embodiment, even if the light emitting elements 104 are miniaturized, the organic layer 14 common to the plurality of sub-pixels 101 corresponding to the plurality of color types is used, the layout of the insulating structures 55 is adjusted in accordance with the color types of the sub-pixels 101, and the color conversion layer is provided for specific sub-pixels 101. With this arrangement, the color of light emission from the organic layer 14 of the light emitting elements 104 can be adjusted. Thus, the display device 10 can be easily manufactured, and the display device 10 can be easily made to achieve a high definition and a smaller size.

Also, in the display device 10 according to the fourth embodiment, the occupancy rate of the mixing regions M41 can be determined, with the color conversion efficiency depending on the color conversion layer 20 being taken into account. Thus, the efficiency of use of light generated from the organic layer 14 can be increased, and power consumption can be lowered.

### [4-3 Modifications]

### (Modification 1)

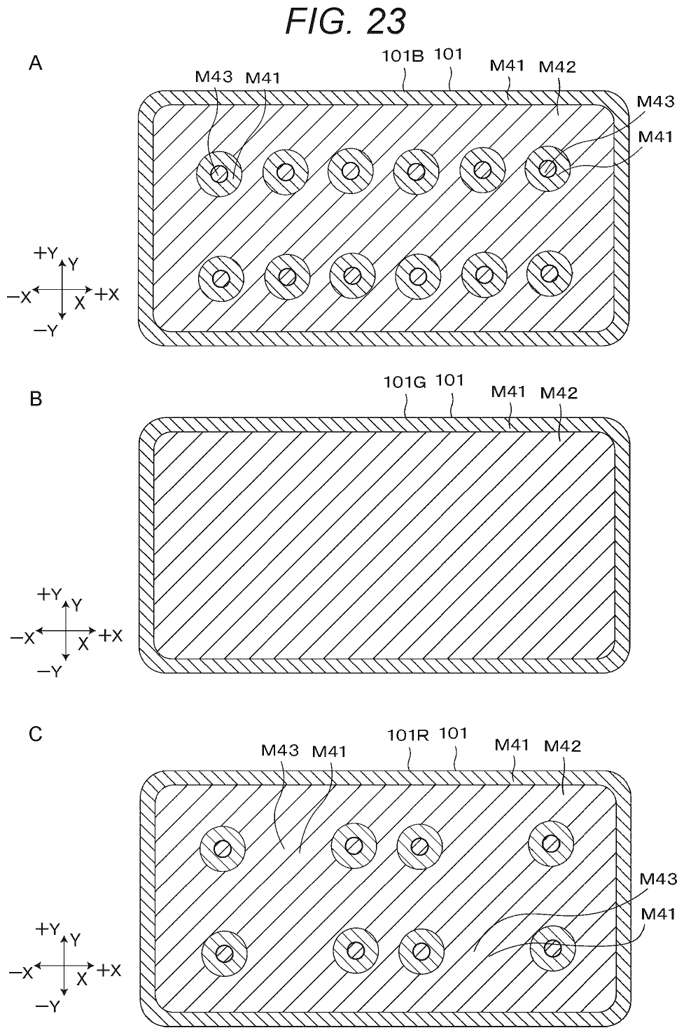

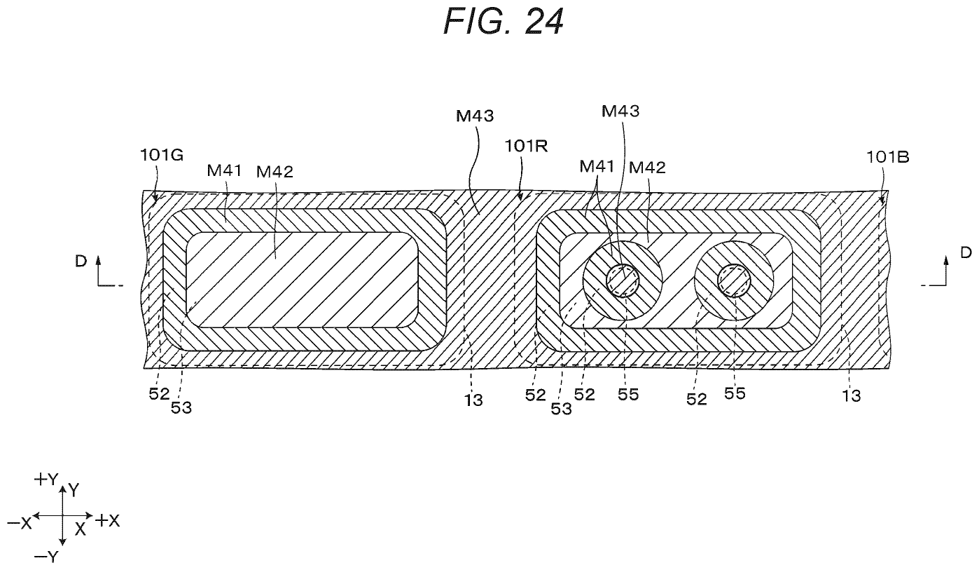

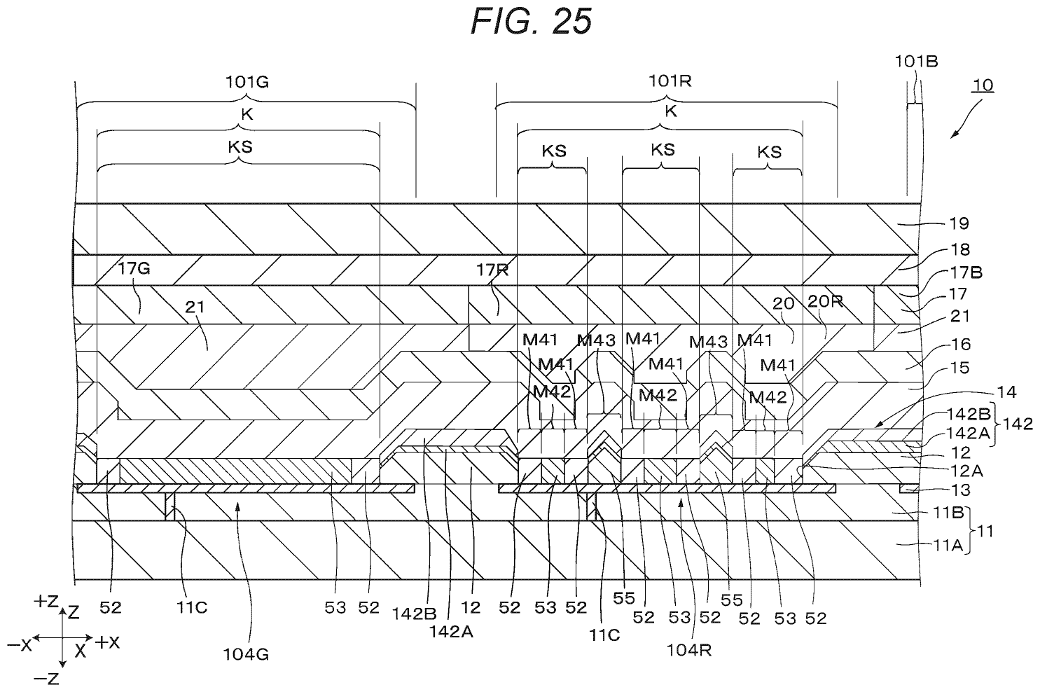

In the display device 10 according to the fourth embodiment, the organic layer 14 may be formed so that the emission color of the mixing portions 52 and the emission color of the non-mixing portions 53 become blue and green, respectively (which is the opposite of those in the example in FIG. 17), and the occupancy rate of the mixing regions M41 among the plurality of sub-pixels 101 corresponding to the plurality of color types may be determined in accordance with such an organic layer 14, as illustrated in FIGS. 22A to 22C, FIGS. 23A to 23C, FIG. 24, and FIG. 25, for example. Such a mode is referred to as Modification 1 of the fourth embodiment. FIGS. 22A to 23C are cross-sectional views for explaining sub-pixels 101 of a display device 10 according to Modification 1 of the fourth embodiment. FIGS. 23A, 23B, and 23C are plan views for explaining sub-pixels 101 of the display device 10 according to Modification 1 of the fourth embodiment. FIG. 24 is a plan view for explaining a plurality of sub-pixels 101 of the display device 10 according to Modification 1 of the fourth embodiment. FIG. 25 is a cross-sectional diagram schematically illustrating a state of a longitudinal cross-section taken along the line D-D defined in FIG. 24.

### (Mixing Layer)

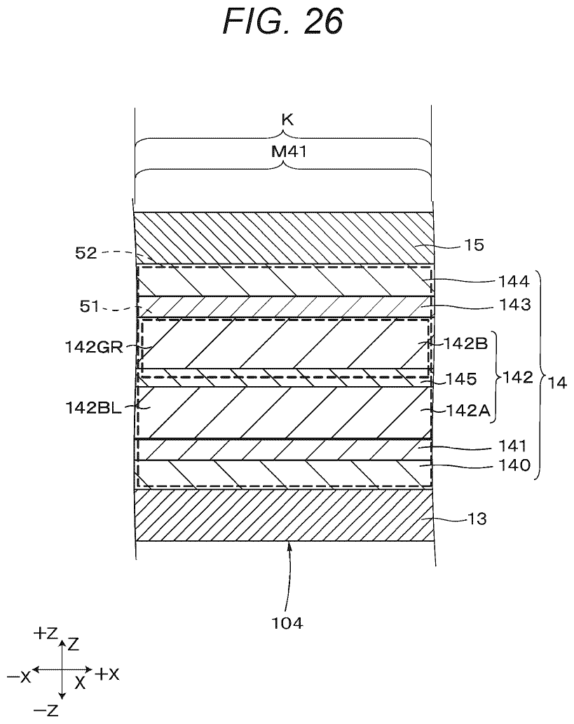

The mixing layer 51 according to the fourth embodiment is a layer formed by combining a layer in which a component forming the electron transport layer 143 is mixed with the second light emitting layer 142B, and a layer in which a component forming the electron transport layer 143 is mixed with part of the intermediate layer 145, as illustrated in FIG. 26. However, this example does not limit the mixing layer 51 to that in a case where a component forming the electron transport layer 143 reaches the intermediate layer 145.

### (Emission Colors)

In the mixing regions M1, in a case where the light emitting element 104 is energized, collision between holes and electrons in the organic layer 14 is likely to occur in the first light emitting layer 142A, and light emission from the first light emitting layer 142A mainly occurs. In the non-mixing light emitting regions M2, collision between holes and electrons occurs normally in the second light emitting layer 142B, and light emission from the second light emitting layer 142B mainly occurs. As mentioned in the description of the fourth embodiment, such light emission can be achieved by adjusting the structures (thickness and the like) and compositions (materials and the like) of the intermediate layer 145, the hole injection layer 140, the hole transport layer 141, the electron transport layer 143, and the electron injection layer 144.

In the example in FIGS. 22 to 26, the light emission in the non-mixing light emitting regions M42 is mainly blue light emitted by the green light emitting layer 142GR provided as the second light emitting layer 142B (the emission color in the non-mixing light emitting regions M42 is green), and the light emission in the mixing regions M41 is mainly blue light emitted by the blue light emitting layer 142BL provided as the first light emitting layer 142A (the emission color in the mixing regions M41 is blue).

### (Occupancy Rate Depending on Color Types of Sub-Pixels)

In the display device 10 according to Modification 1 of the fourth embodiment, the mixing regions M41 are formed along the openings 12A for the sub-pixels 101 of any color type in the example illustrated in FIGS. 22 to 26. Further, in the sub-pixels 101B and the sub-pixels 101R, the mixing regions M41 are also formed around the insulating structures 55. In the sub-pixels 101G, the formation of the insulating structures 55 is avoided.

In the example in FIGS. 23A to 23C, the occupancy rate of the mixing regions M41 of the sub-pixel 101G is lower than those of the other sub-pixels 101R and 101B. In each sub-pixel 101G, the non-mixing light emitting region M42 substantially occupies the sub-pixel 101G, except for the outer peripheral edge of the region in which the sub-pixel 101G is formed (the inner peripheral edge of the opening 12A), as illustrated in FIGS. 23B, 24, and 25. In this case, in each sub-pixel 101G, the emission color of the organic layer 14 is normally green.

In a case where sub-pixels 101R and 101B in which the mixing regions M41 are formed are a first sub-pixel and a second sub-pixel, the occupancy rate of the mixing regions M41 determined for the first sub-pixel and the occupancy rate of the mixing regions M41 determined for the second sub-pixel are different from each other. As illustrated in the example in FIGS. 22A to 22C and FIGS. 23A to 23C, the occupancy rate of the mixing regions M41 of the sub-pixel 101R is lower than the occupancy rate of the mixing regions M41 of the sub-pixel 101B. This can be achieved by adjusting the layout such as the numbers of insulating structures 55 disposed in the sub-pixel 101B and the sub-pixel 101R.

In the display device 10 according to Modification 1 of the fourth embodiment, the display device 10 can be more easily manufactured, and the display device 10 can be easily made to achieve a high definition and a smaller size, as described above in “Functions and Effects” of the fourth embodiment. Further, in Modification 1 of the fourth embodiment, the occupancy rate of the mixing regions M41 can also be determined, with the color conversion efficiency depending on the color conversion layer 20 being taken into account. Thus, the efficiency of use of light generated from the organic layer 14 can be increased, and power consumption can be lowered.

### (Modification 2)

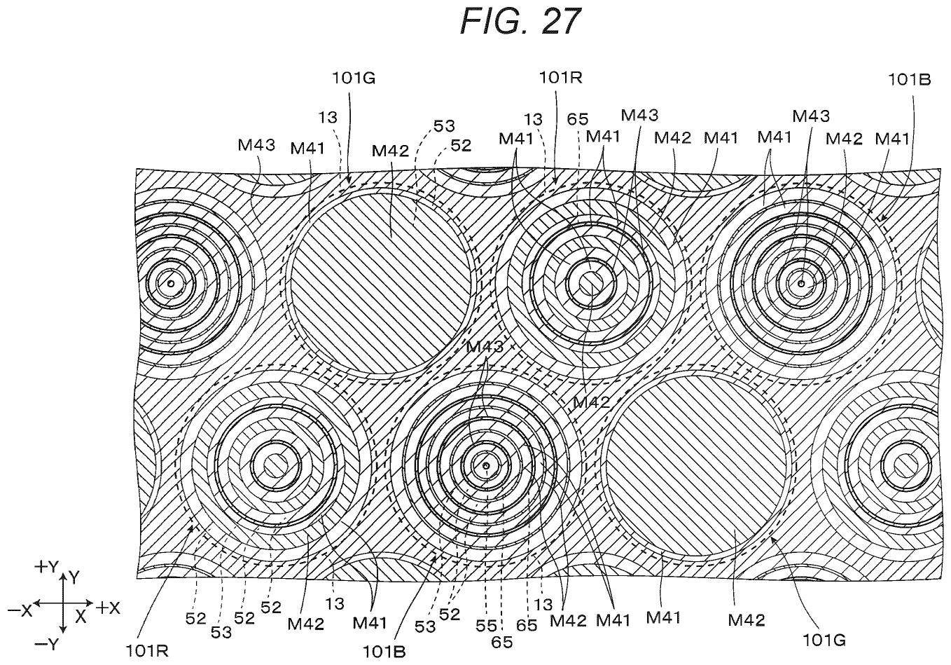

In the display device 10 according to the fourth embodiment, insulating structures 65 as illustrated in FIG. 27 may be used, instead of or together with the insulating structures 55. Such a mode is referred to as Modification 2 of the fourth embodiment. FIG. 27 is a plan view schematically illustrating an example of Modification 2 of the fourth embodiment.

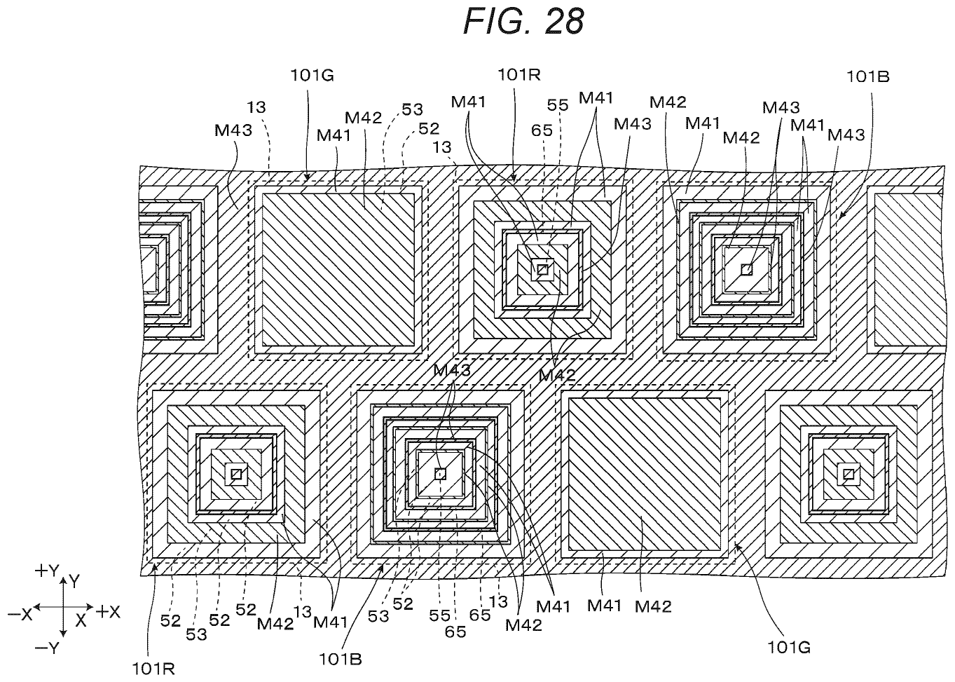

Note that FIG. 27 illustrates an example case where Modification 1 of the fourth embodiment is used as an example of Modification 2 of the fourth embodiment. This also applies in FIG. 28. FIG. 28 is a plan view for explaining another example of Modification 2 of the fourth embodiment. Also, FIGS. 27 and 28 each illustrate an example case where the sub-pixels 101 are arranged in a delta-like layout. A delta-like layout means that, for a combination of the sub-pixels 101R, 101G, and 101B constituting one pixel, the sub-pixels 101 are arranged so that the shape connecting the centers of the sub-pixels 101 is a triangular shape. In FIGS. 27 and 28, the color conversion layer 20 and the like are not shown, and the mixing regions M41, the non-mixing light emitting regions M42, the regions in which the insulating structures 55 and 65 are formed, and the regions in which the insulating layer 12 is formed are indicated by different kinds of hatching. In FIGS. 27 and 28, the first electrodes 13 are indicated by dashed lines for some of the sub-pixels 101.

In the sub-pixels 101B illustrated in FIG. 27, insulating structures 55 and 65 are provided. An insulating structure 55 (a columnar structure) is disposed at the center of each sub-pixel 101B, and insulating structures 65 are disposed at intervals around the insulating structure 55. Each insulating structure 65 is formed in an annular wall-like shape, and a plurality of insulating structures 65 is formed in each sub-pixel 101B. Here, the plurality of insulating structures 65 is concentrically disposed. In the example in FIG. 27, the insulating structures 65 formed in an annular shape is formed in a circular shape in plan view of the sub-pixels 101. Note that, in the example in FIG. 27, each sub-pixel 101 is also defined in a circular shape. In this case, the mixing layer 51 is easily formed along the inner periphery or the outer periphery of each insulating structure 65. Accordingly, the mixing portions 52 and the non-mixing portion 53 as illustrated in FIG. 28 are formed in an annular shape. Further, the mixing regions M41 and the non-mixing light emitting regions M42 are also easily formed concentrically.

In the sub-pixels 101R illustrated in FIG. 27, insulating structures 65 are provided. In each sub-pixel 101R, a plurality of insulating structures 65 is formed. In each sub-pixel 101R, a plurality of insulating structures 65 is concentrically disposed.

In the sub-pixels 101G illustrated in FIG. 27, formation of the insulating structures 65 is avoided inside the openings 12A.

Even in a case where the insulating structures 65 illustrated in the example in FIG. 27 are used, the occupancy rates of the mixing regions M41 of the sub-pixels 101 can be determined in accordance with the color types of the sub-pixels 101. For example, the occupancy rate of the mixing regions M41 of the sub-pixels 101R can be made lower than the occupancy rate of the mixing regions M41 of the sub-pixels 101B. In the example illustrated in FIG. 27, the number of the insulating structures 65 that are formed in an annular shape and are disposed in each sub-pixel 101R can be made smaller than the number of the adjacent insulating structures 65 that are formed in an annular shape and are disposed in each sub-pixel 101B.

In the display device 10 according to Modification 2 of the fourth embodiment, the insulating structures 65 may have a non-circular shape such as a rectangular shape, as illustrated in the example in FIG. 28. In this case, the insulating structures 65 may also be concentrically arranged in sub-pixels 101, as illustrated in FIG. 28.

### 5 Fifth Embodiment

### [5-1 Configuration of a Display Device]

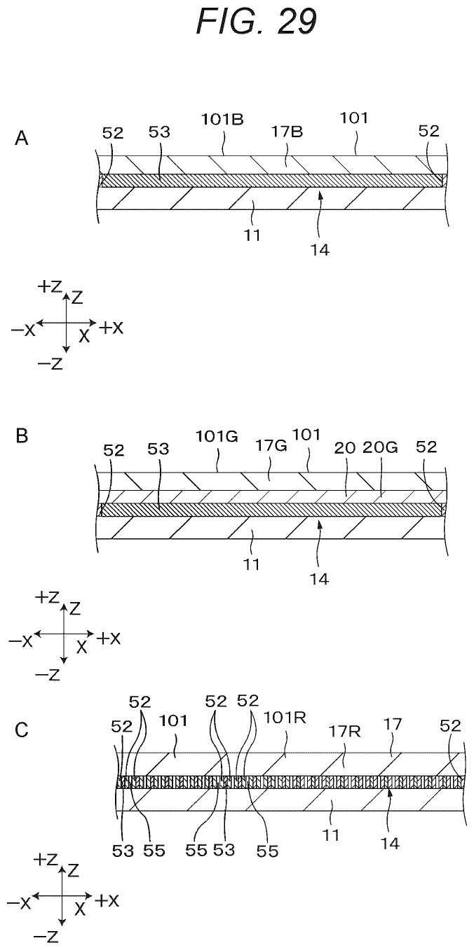

As illustrated in FIGS. 29 to 33, a display device 10 according to a fifth embodiment has a configuration in which a color conversion layer 20 is provided in each sub-pixel 101G among a plurality of sub-pixels 101 corresponding to a plurality of color types, a configuration in which an organic layer 14 is formed so that the emission color of mixing portions 52 and the emission color of non-mixing portions 53 become red and blue, respectively, and a configuration in which the occupancy rate of mixing regions M51 in the plurality of sub-pixels 101 corresponding to the plurality of color types is determined in accordance with the organic layer 14. Regarding the aspects other than these configurations, the display device 10 according to the fifth embodiment is formed in a manner similar to the display device 10 according to the fourth embodiment.

FIGS. 29A to 29C are cross-sectional views for explaining, for each color type, an example of sub-pixels 101 of the display device 10 according to the fifth embodiment. In FIG. 29A to 29C, for ease of explanation, the insulating layer 12, the first electrodes 13, the second electrode 15, the protective layer 16, the filling resin layer 18, and the counter substrate 19 are not shown. Further, the respective layers constituting the organic layer 14 and the components between adjacent sub-pixels 101 are not shown, and the organic layer 14 covering the insulating structures 55 is not shown.

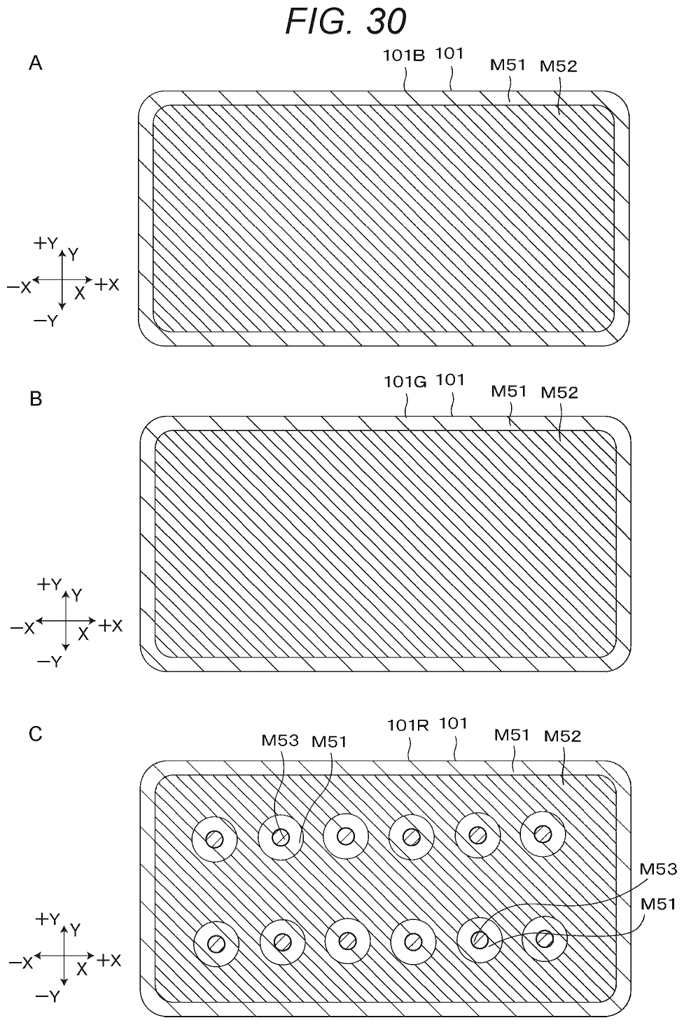

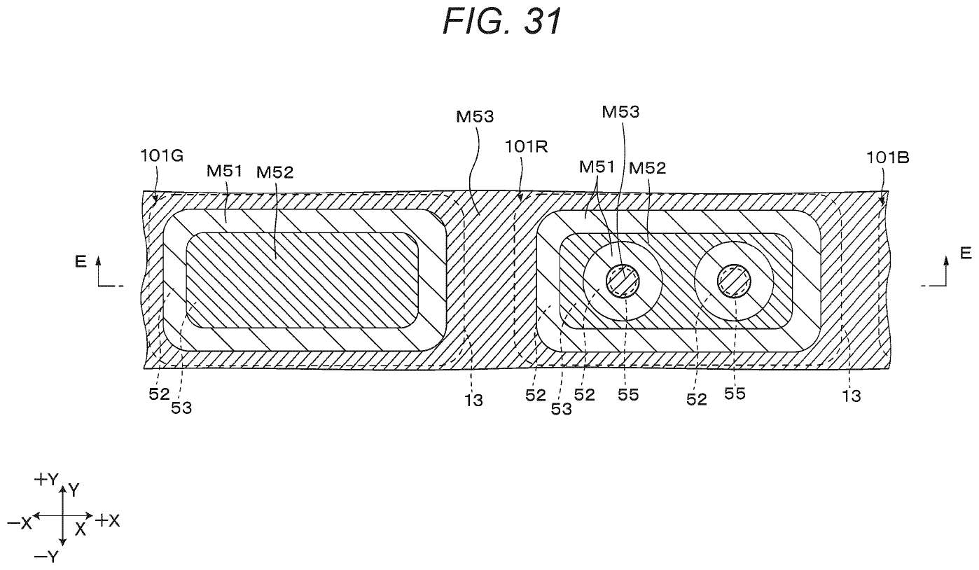

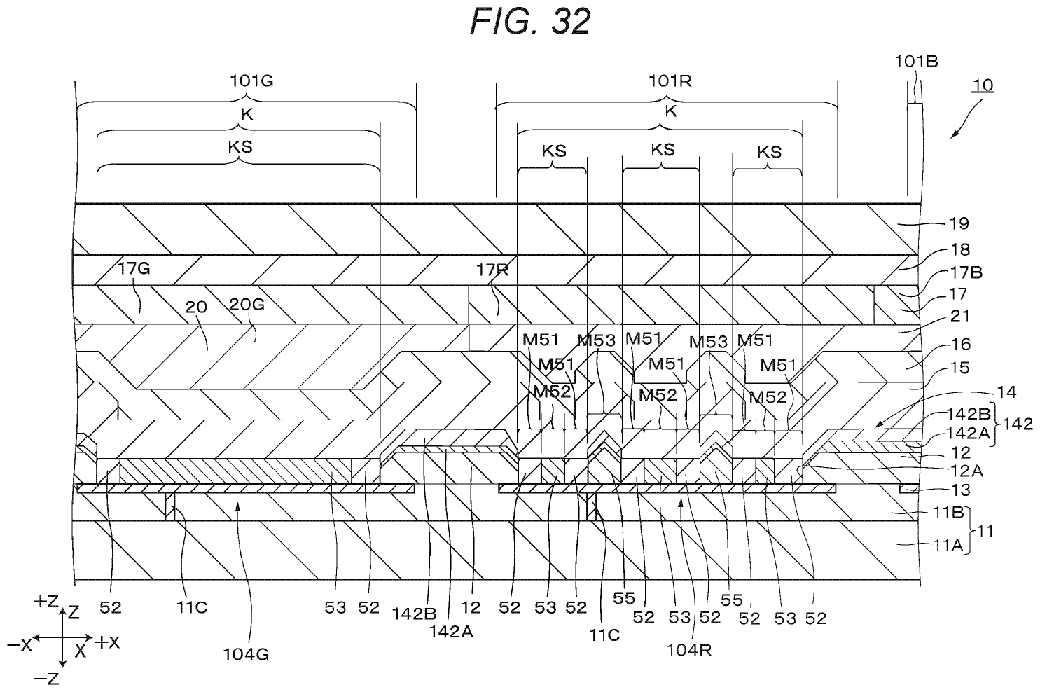

FIG. 31 is a plan view for explaining adjacent sub-pixels 101. FIG. 32 is a cross-sectional diagram schematically illustrating a longitudinal cross-section taken along the line E-E defined in FIG. 31. In the display device 10 according to the fifth embodiment, the respective structures of the insulating structures 55, the mixing portions 52, and the non-mixing portions 53 may be similar to those of the display device 10 according to the first embodiment. In the fifth embodiment, the insulating structures 55, the mixing portions 52, and the non-mixing portions 53 are denoted by the same reference numerals as those in the first embodiment in FIG. 31, FIG. 32, and others, and detailed explanation of them is not made herein.

Further, as illustrated in FIGS. 31 and 32, in the display device 10 according to the fifth embodiment, the layer structures excluding the color conversion layer 20, which are the structures of the respective layers such as the drive substrate 11 including the substrate 11A, the first electrodes 13, the respective layers constituting the organic layer 14 (excluding the light emitting layers 142), and the second electrode 15, for example, as well as the structure of the planarizing layer 21, may be similar to those of the display device 10 according to the fourth embodiment. In the fifth embodiment, the layer structures, excluding the color conversion layer 20, are denoted by the same reference numerals as those in the first embodiment, and detailed explanation of them is not made herein, except for the characteristic components.

In FIG. 32, for ease of explanation, the respective layers, except for the light emitting layers 142, are not shown in the portions of the organic layer 14 formed outside the counter regions K and the portions of the organic layer 14 corresponding to no-light emitting regions M53 in a plan view of the display device 10 (in a case where the thickness direction of the substrate 11A is the line-of-sight direction), as in FIG. 20 and others used in the description of the fourth embodiment. Also, regarding the portions of the organic layer 14 formed inside the counter regions K, mixing portions 52 and non-mixing portions 53 described later are shown, and the respective layers in each portion of the mixing portions 52 and the non-mixing portions 53 are not shown.

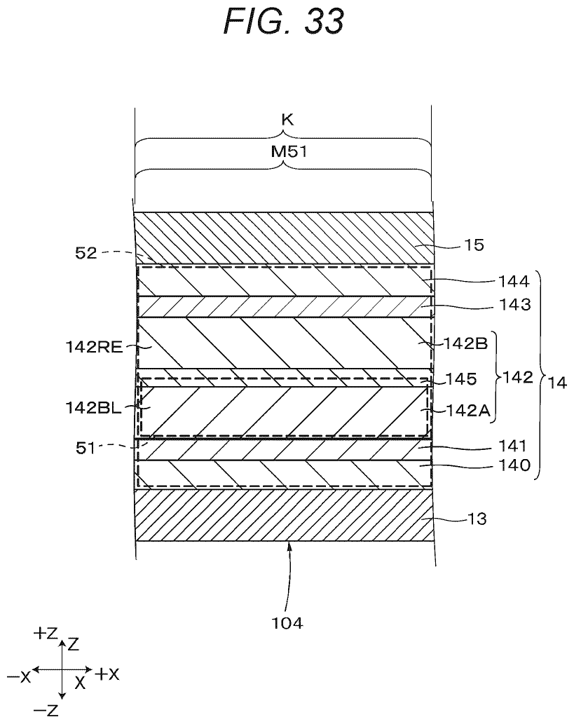

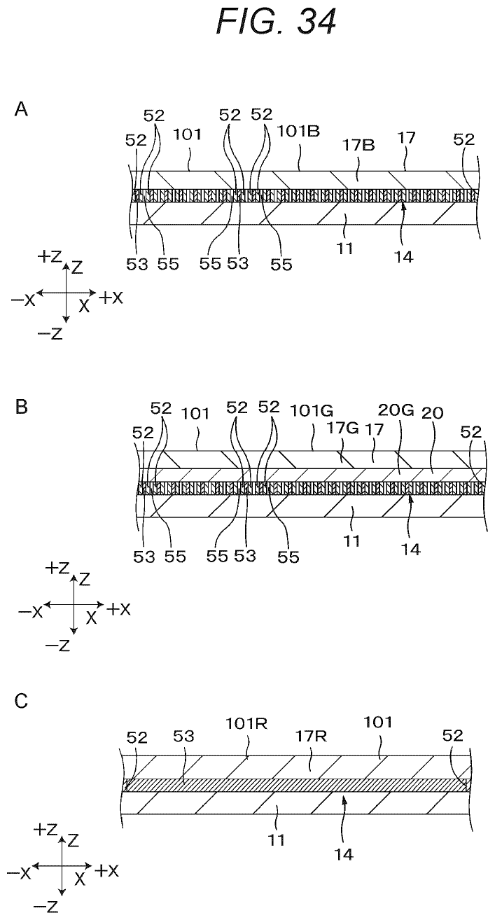

Further, in the sub-pixels 101 corresponding to the respective color types in FIGS. 29, 30, 31, and 32, the layout such as the number of the insulating structures 55 formed in a sub-pixel 101 is not described in a comprehensive manner, for ease of explanation. The same applies in FIGS. 34, 35, 36, and 37. FIGS. 30A, 30B, and 30C are plan views for explaining an example of the layout of mixing regions M51 and non-mixing light emitting regions M52 in an example of the sub-pixels 101 of the display device 10 according to the fifth embodiment.

In the display device 10 according to the fifth embodiment, a plurality of sub-pixels 101 corresponding to a plurality of color types is provided, as in the fourth embodiment. Also, the organic layer 14 may be similar to that of the fourth embodiment, except for the combination of color types of the light emitting layers 142.

### (First Light Emitting Layer and Second Light Emitting Layer)

The color types of a plurality of light emitting layers 142 (the first light emitting layer 142A and the second light emitting layer 142B) provided in the organic layer 14 are blue and red, as illustrated in the example in FIG. 33. Therefore, in this example, the first light emitting layer 142A is a blue light emitting layer 142BL having blue as its emission color. The second light emitting layer 142B is a red light emitting layer 142RE having red as its emission color.

### (Blue Light Emitting Layer)

The blue light emitting layer 142BL may be formed in a manner similar to the blue light emitting layer described in the first embodiment and the fourth embodiment.

### (Red Light Emitting Layer)

The red light emitting layer 142RE may be formed in a manner similar to the red light emitting layer described above in the third embodiment.

### (Emission Colors)

In the fifth embodiment, the emission color of mixing regions M51 and the emission color of non-mixing regions (non-mixing light emitting regions M52) are different, as described also in the fourth embodiment.

In the mixing regions M51, in a case where the light emitting element 104 is energized, collision between holes and electrons in the organic layer 14 is likely to occur in the first light emitting layer 142A, and light emission from the first light emitting layer 142A mainly occurs. In the non-mixing light emitting regions M52, collision between holes and electrons occurs normally in the second light emitting layer 142B, and light emission from the second light emitting layer 142B mainly occurs.

The light emission in the non-mixing light emitting regions M52 illustrated in the example in FIG. 33 is mainly blue light emitted by the blue light emitting layer 142BL provided as the first light emitting layer 142A (the emission color in the non-mixing light emitting regions M52 is blue), and the light emission in the mixing regions M51 is mainly red light emitted by the red light emitting layer 142RE provided as the second light emitting layer 142B (the emission color in the mixing regions M51 is red).

### (Color Conversion Layer)

In the display device 10 according to the fifth embodiment, sub-pixels 101 corresponding to at least one color type include a color conversion layer. The color conversion layer is preferably a layer that emits light in a predetermined color. The same applies in the fourth embodiment. In the display device 10 according to the fifth embodiment, the color conversion layer may be a layer that emits green light, for example. In the example of the display device 10 illustrated in FIGS. 29 to 33, the sub-pixel 101G includes a color conversion layer 20, and a green-color conversion layer 20G is provided as the color conversion layer 20. The green-color conversion layer 20G causes incident light to be emitted from the green-color conversion layer after converted into green light. In the example illustrated in FIG. 29B and others, light generated in the organic layer 14 of the sub-pixel 101R passes through the green-color conversion layer 20G, to be converted into green light. The green-color conversion layer 20G is preferably a layer that emits light in green. The material of the color conversion layer 20 may be the similar to the material of the color conversion layer 20 described in the fourth embodiment. However, unlike the red-color conversion layer 20R described in the fourth embodiment, the green-color conversion layer 20G is formed with a material capable of converting a color type of light into green.

### (Mixing Regions)

In the example in FIGS. 29A to 29C and FIGS. 30A to 30C, the mixing regions M51 are formed along the openings 12A for the sub-pixels 101 of any color type. Further, in the sub-pixels 101R, the mixing regions M51 are also formed around the insulating structures 55. In the sub-pixels 101B and the sub-pixels 101G, the formation of the insulating structures 55 is avoided.

### (Occupancy Rate Depending on Color Types of Sub-Pixels)

In the display device 10 according to the fifth embodiment, the occupancy rate of the mixing regions M51 for the sub-pixels 101R provided with the color conversion layer 20 is a value that does not fall between the occupancy rate of the mixing regions M51 for the sub-pixels 101B and the occupancy rate of the mixing regions M51 for the sub-pixels 101G, the sub-pixels 101B and the sub-pixels 101G being the other sub-pixels 101. In the example in FIGS. 29A to 29C and FIGS. 30A to 30C, the occupancy rate of the mixing regions M51 for the sub-pixel 101R is higher than the occupancy rate of the mixing regions M51 for the sub-pixel 101B and the occupancy rate of the mixing regions M51 for the sub-pixel 101G. Furthermore, the occupancy rate of the mixing regions M51 for the sub-pixel 101B and the occupancy rate of the mixing regions M51 for the sub-pixel 101G are preferably almost equal.

In the example in FIGS. 29A to 29C and FIGS. 30A to 30C, the occupancy rate of the mixing regions M51 of the sub-pixel 101R is higher than the occupancy rates of the mixing regions M51 of the other sub-pixels 101B and 101R, and the emission color of the organic layer 14 in the sub-pixel 101R is substantially red. In the sub-pixel 101B and the sub-pixel 101G, the emission color of the organic layer 14 is normally a color that is close to blue (alternatively, slightly reddish blue).

As described above, each sub-pixel 101G has the green-color conversion layer 20G as the color conversion layer 20. In general, even if red light (a light component in the red wavelength band) is included in the light incident on the green-color conversion layer 20G, the color conversion efficiency in converting the incident light into green light with the green-color conversion layer 20G is not significantly increased in many cases. From the viewpoint of such color conversion efficiency, it is preferable that the emission color of the organic layer 14 in the sub-pixels 101G is normally blue (mixing of light components in the red wavelength band is prevented), and it is preferable that the occupancy rate of the mixing regions M51 of the sub-pixels 101G is lower than the occupancy rate of the mixing regions M51 of the sub-pixels 101R, and is almost equal to the occupancy rate of the mixing regions M51 of the sub-pixels 101B.

Note that the structure of the insulating structure 60 described in the second embodiment, and the insulating structures 65 described in Modification 2 of the fourth embodiment can also be applied to the insulating structures of the fifth embodiment.

### [5-2 Functions and Effects]

With the display device 10 according to the fifth embodiment, effects similar to those of the fourth embodiment can be achieved. The display device 10 can be easily manufactured and be easily made to achieve a high definition and a smaller size, and power consumption can be lowered.

### [5-3 Modification]

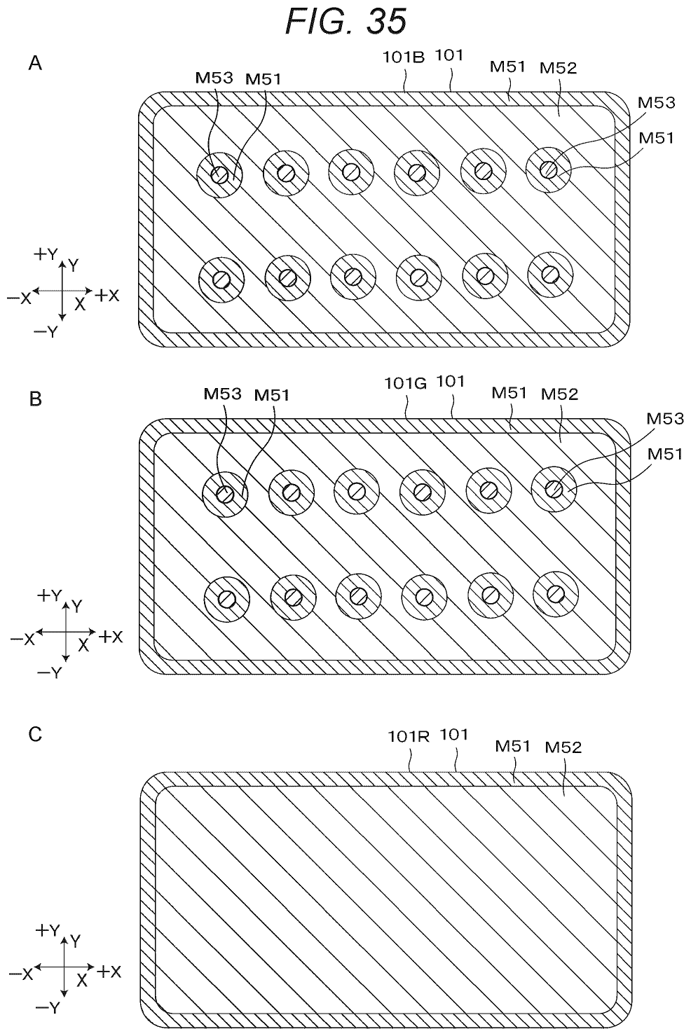

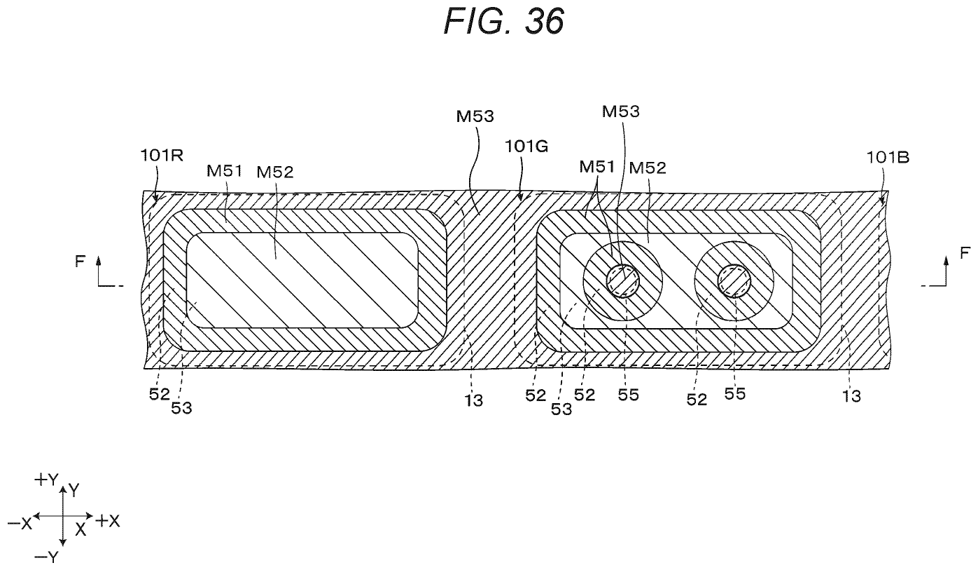

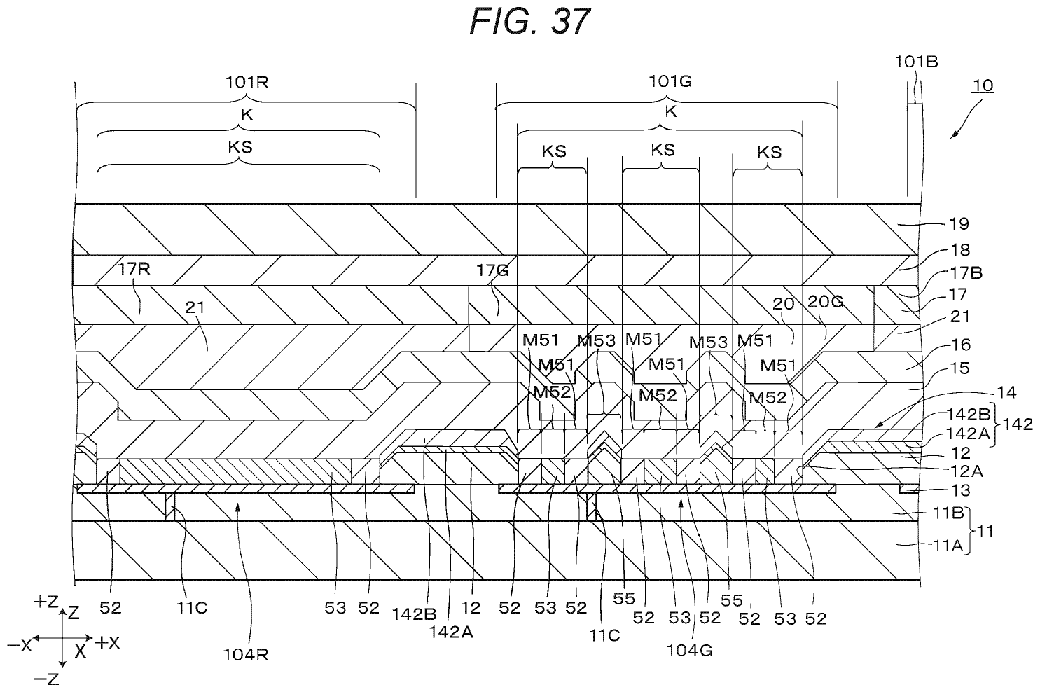

In the display device 10 according to the fifth embodiment, as illustrated in FIGS. 34 to 38, the organic layer 14 may be formed so that the emission color of the mixing portions 52 and the emission color of the non-mixing portions 53 become red and blue, respectively (that is, the emission color of the mixing portions 52 and the emission color of the non-mixing portions 53 are the opposite of those in the example in FIGS. 29 to 33). The occupancy rate of the mixing regions M51 among the plurality of sub-pixels 101 corresponding to the plurality of color types may be determined in accordance with such an organic layer 14, as illustrated in FIGS. 34A to 34C, FIGS. 35A to 35C, FIG. 36, and FIG. 37, for example. Such a mode is referred to as the modification of the fifth embodiment. FIGS. 34A to 34C are cross-sectional views for explaining sub-pixels 101 of a display device 10 according to the modification of the fifth embodiment. FIGS. 35A, 35B, and 35C are plan views for explaining sub-pixels 101 of the display device 10 according to the modification of the fifth embodiment. FIG. 36 is a plan view for explaining a plurality of sub-pixels 101 of the display device 10 according to the modification of the fifth embodiment. FIG. 37 is a cross-sectional diagram schematically illustrating a state of a longitudinal cross-section taken along the line F-F defined in FIG. 36.

### (Mixing Layer)

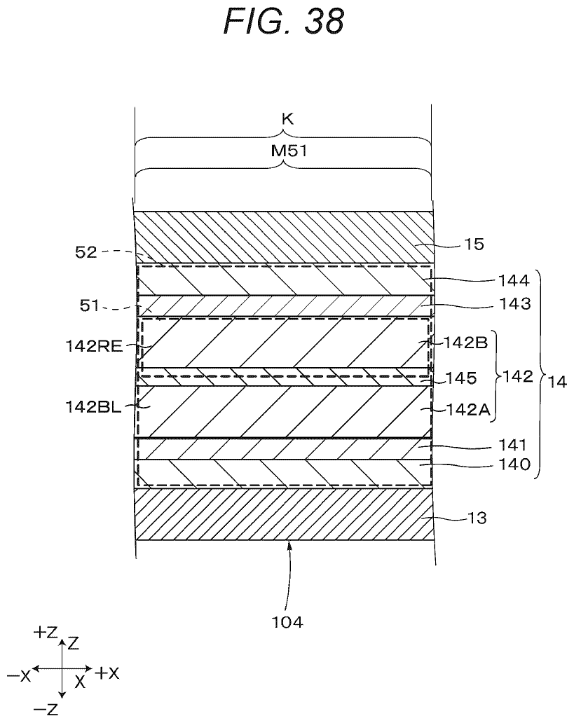

The mixing layer 51 according to the fifth embodiment is a layer formed by combining a layer in which a component forming the electron transport layer 143 is mixed with the second light emitting layer 142B, and a layer in which a component forming the electron transport layer 143 is mixed with part of the intermediate layer 145, as illustrated in FIG. 38. However, this example does not limit the mixing layer 51 to that in a case where a component forming the electron transport layer 143 reaches the intermediate layer 145.

### (Emission Colors)

In the mixing regions M1, in a case where the light emitting element 104 is energized, collision between holes and electrons in the organic layer 14 is likely to occur in the first light emitting layer 142A, and light emission from the first light emitting layer 142A mainly occurs. In the non-mixing light emitting regions M2, collision between holes and electrons occurs normally in the second light emitting layer 142B, and light emission from the second light emitting layer 142B mainly occurs. As mentioned in the description of the fourth embodiment, such light emission can be achieved by adjusting the structures (thickness and the like) and compositions (materials and the like) of the intermediate layer 145, the hole injection layer 140, the hole transport layer 141, the electron transport layer 143, and the electron injection layer 144.

In the example in FIGS. 22 to 26, the light emission in the non-mixing light emitting regions M42 is mainly red light emitted by the red light emitting layer 142RE provided as the second light emitting layer 142B (the emission color in the non-mixing light emitting regions M42 is red), and the light emission in the mixing regions M41 is mainly blue light emitted by the blue light emitting layer 142BL provided as the first light emitting layer 142A (the emission color in the mixing regions M41 is blue).

### (Mixing Regions)

In the example in FIGS. 34A to 34C and FIGS. 35A to 35C, the mixing regions M51 are also formed around the insulating structures 55 in the sub-pixel 101B and the sub-pixel 101G, as illustrated also in FIGS. 36 and 37. In the sub-pixel 101R, formation of the insulating structures 55 is avoided (formation of the mixing regions M51 around the insulating structures 55 is avoided).

### (Occupancy Rate Depending on Color Types of Sub-Pixels)

In the display device 10 according to the fifth embodiment, in the example in FIGS. 34A to 34C and FIGS. 35A to 35C, the occupancy rate of the mixing regions M51 for the sub-pixel 101R is lower than the occupancy rate of the mixing regions M51 for the sub-pixel 101B and the occupancy rate of the mixing regions M51 for the sub-pixel 101G, and the emission color of the organic layer 14 is substantially red. Furthermore, the occupancy rate of the mixing regions M51 for the sub-pixel 101B and the occupancy rate of the mixing regions M51 for the sub-pixel 101G are almost the same. In both of the sub-pixel 101B and the sub-pixel 101G, the emission color of the organic layer 14 is normally a color that is close to blue (alternatively, slightly reddish blue).

In the display device 10 according to the modification of the fifth embodiment, the display device 10 can be more easily manufactured, and the display device 10 can be easily made to achieve a high definition and a smaller size, as described above in “Functions and Effects” of the fifth embodiment. Further, in Modification 1 of the fourth embodiment, the occupancy rate of the mixing regions can also be determined, with the color conversion efficiency depending on the color conversion layer being taken into account. Thus, the efficiency of use of light generated from the organic layer 14 can be increased, and power consumption can be lowered.

### 6 Sixth Embodiment

A display device 10 according to a sixth embodiment has the same configuration as that of any of the first to fifth embodiments, except that lenses are provided on the first surface side of the protective layer 16. The components other than the lenses are similar to those of the first to fifth embodiments, and therefore, detailed explanation thereof is not made herein.

### (Lenses)

In the display device 10 according to the sixth embodiment, lenses (not shown) are provided on the first surface side (the upper side, or the +Z direction side) of the protective layer 16. The lenses are preferably on-chip lenses (OCLs). The material of the lenses may be a resin or the like, for example. The lenses are disposed in accordance with the positions corresponding to the respective sub-pixels 101.

### (Shape of the Lenses)

Each lens is preferably formed in a convex shape having a curved surface that is convexly curved in a direction away from the drive substrate 11 (the +Z direction), and is preferably a so-called convex lens.

In the display device 10 according to the sixth embodiment, color filters 17 may be provided. Note that, in the display device 10 provided with the color filters 17 in this case, the lenses may be provided on the first surface side (the upper side, or the +Z direction side) of the color filters 17, for example.

### 7 Example Cases Where a Display Device Has Resonator Structures

A case where resonator structures are formed in a display device 10 is now described, with the display device 10 according to the first embodiment being taken as an example. In the display device 10 according to the first embodiment, resonator structures may be further formed in at least some of the plurality of sub-pixels 101. Note that the resonator structures described in conjunction with the first embodiment may be applied in the second and third embodiments.

### (Resonator Structures)

Resonator structures are formed in the display device 10. The resonator structures are cavity structures, and are structures that cause resonation of light generated in the organic layer 14. In the display device 10, the resonator structures are formed in the light emitting elements 104 (light emitting elements 104R, 104B, and 104G), and each resonator structure includes the first electrode 13, the organic layer 14, and the second electrode 15. Causing resonation of emitted light from the organic layer 14 means causing resonation of light of a specific wavelength included in the emitted light.

In a resonator structure, of the emitted light from the organic layer 14, the component that is reflected and resonates between predetermined layers such as between the first electrode 13 and the second electrode 15 is emphasized, and the light emphasized is emitted toward the outside from the side of the display surface DP (first surface side).

The organic layer 14 generally uses light corresponding to the color type of the sub-pixel 101 as emitted light, and the resonator structure causes resonation of light of a specific wavelength included in the emitted light from the organic layer 14. At this point of time, light of a predetermined wavelength in the emitted light from the organic layer 14 is emphasized. The light of the predetermined wavelength being emphasized, light is then emitted toward the outside from the side of the second electrode 15 (which is the light emitting surface side) of the light emitting element 104. Note that the light of the predetermined wavelength is light corresponding to a predetermined color type, and indicates light corresponding to a color type determined in accordance with the sub-pixel 101. The display device 10 includes the light emitting elements 104R, 104G, and 104B corresponding to the sub-pixels 101R, 101G, and 101B. Furthermore, a resonator structure is formed for each of the light emitting elements 104R, 104G, and 104B. In the resonator structure in the sub-pixel 101R, the red light of the emitted light from the organic layer 14 resonates. Light is emitted toward the outside from the second electrode 15 of the light emitting element 104R, with the red light being emphasized. Accordingly, red light having excellent color purity can be emitted from the sub-pixel 101R. In the resonator structures in the sub-pixels 101G and 101B, the green light and the blue light of the emitted light from the organic layer 14 resonate, respectively. In the sub-pixels 101G and 101B, light is emitted toward the outside from the second electrodes 15 of the light emitting elements 104G and 104B, with the green light and the blue light being emphasized. Accordingly, green light and blue light having excellent color purity can be emitted from the sub-pixels 101G and 101B, respectively.

As the resonator structures are formed in the display device 10 in this manner, the color purity of the sub-pixels 101 can be enhanced.

First to seventh examples will be sequentially described below as example cases where the display device 10 has resonator structures, and the explanation will be continued.

### Resonator Structure: First Example

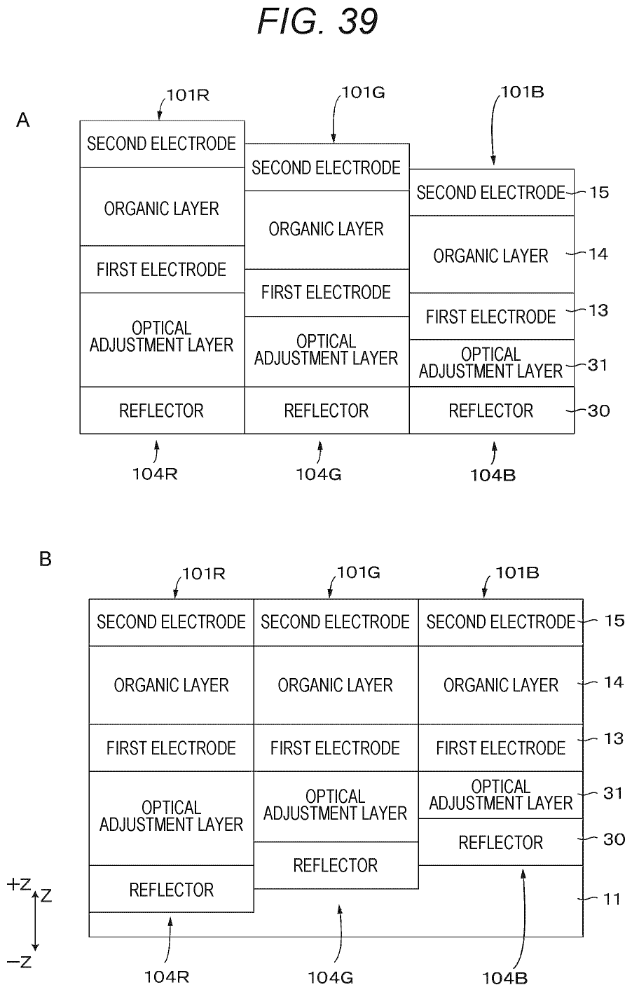

FIG. 39A is a schematic cross-sectional view for explaining a first example of a case where the display device 10 has resonator structures.

In the first example, the thickness of the first electrode 13 and the thickness of the second electrode 15 are uniform among the sub-pixels 101R, 101G, and 101B.

In each of the sub-pixels 101R, 101G, and 101B (light emitting elements 104R, 104G, and 104B), an optical adjustment layer 31 is provided on the lower side (second surface side) of the first electrode 13, a reflector 30 is further disposed on the second surface side of the optical adjustment layer 31, and the optical adjustment layer 31 is formed between the reflector 30 and the first electrode 13. The resonator structure that causes resonation of light generated by the organic layer 14 is formed between the reflector 30 and the second electrode 15.

The thickness of the reflector 30 is the same among the sub-pixels 101R, 101G, and 101B. The thickness of the optical adjustment layer 31 varies among the sub-pixels 101R, 101G, and 101B. As the optical adjustment layer 31 has a thickness that varies among the sub-pixels 101R, 101G, and 101B, it is possible to set optical distances for causing resonance suitable for the sub-pixels 101R, 101G, and 101B.

In the example in FIG. 39A, the positions of the first surfaces of the reflectors 30 provided in the sub-pixels 101R, 101G, and 101B are designed so as to be aligned in the vertical direction. In the sub-pixels 101R, 101G, and 101B, the positions of the first surfaces of the second electrodes 15 vary with the differences in the thickness among the optical adjustment layers 31.

The reflectors 30 can be formed with a metal such as aluminum (Al), silver (Ag), or copper (Cu), or an alloy containing these metals as principal components, for example.

The optical adjustment layers 31 can be formed with an inorganic insulating material such as silicon nitride (SiNx), silicon oxide (SiOx), or silicon oxynitride (SiOxNy), or an organic resin material such as an acrylic resin or a polyimide resin. Each optical adjustment layer 31 may be a single layer, or may be a film stack formed with a plurality of materials.

Each second electrode 15 is preferably a layer that functions as a semi-transmissive reflective film. The second electrodes 15 can be formed with magnesium (Mg), silver (Ag), a magnesium-silver alloy (MgAg) containing these materials as the principal components, an alloy containing an alkali metal or an alkaline earth metal, or the like. The configurations of the first electrodes 13 and the organic layers 14 are similar to those described above, and therefore, explanation of them is not made herein.

### Resonator Structure: Second Example

FIG. 39B is a schematic cross-sectional view for explaining a second example of a case where the display device 10 has resonator structures. The second example has a layer structure similar to that of the first example, except that the positions of the second electrodes 15 and the reflectors 30 are different from those in the first example.

In the sub-pixels 101R, 101G, and 101B (light emitting elements 104R, 104G, and 104B), the upper surfaces of the second electrodes 15 are arranged so that their positions in the vertical direction are aligned. The reflectors 30 provided in the sub-pixels 101R, 101G, and 101B are at different positions in the vertical direction, depending on the differences in thickness among the optical adjustment layers 31.

### Resonator Structure: Third Example

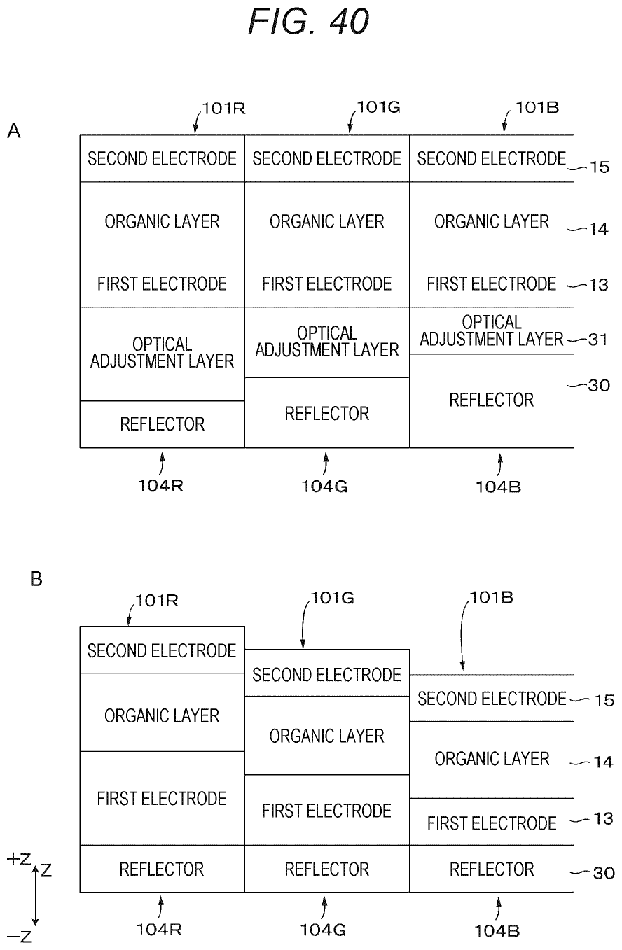

FIG. 40A is a schematic cross-sectional view for explaining a third example of a case where the display device 10 has resonator structures. The third example has a layer structure similar to that of the first example, except that the thicknesses of the reflectors 30 vary among the sub-pixels 101R, 101G, and 101B (light emitting elements 104R, 104G, and 104B).

In the sub-pixels 101R, 101G, and 101B, the upper surfaces of the second electrodes 15 are arranged so that their positions in the vertical direction are aligned. The positions of the first surfaces of the reflectors 30 provided in the sub-pixels 101R, 101G, and 101B vary in the vertical direction, depending on the differences in thickness among the optical adjustment layers 31. However, the positions of the second surfaces of the reflectors 30 are aligned among the sub-pixels 101R, 101G, and 101B.

### Resonator Structure: Fourth Example

FIG. 40B is a schematic cross-sectional view for explaining a fourth example of a case where the display device 10 has resonator structures. The fourth example is similar to the first example, except that the optical adjustment layers 31 are not included, and the thicknesses of the first electrodes 13 vary among the sub-pixels 101R, 101G, and 101B (light emitting elements 104R, 104G, and 104B).

Regarding the thicknesses of the first electrodes 13, the respective thicknesses of the first electrodes 13 are designed so as to set optical distances for causing optical resonance suitable for the sub-pixels 101R, 101G, and 101B.

### Resonator Structure: Fifth Example

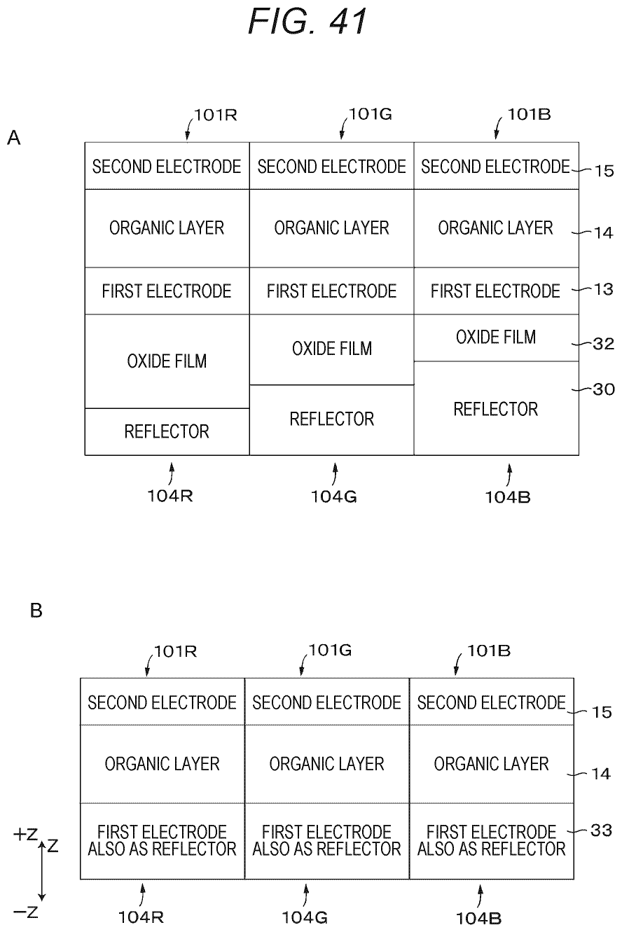

FIG. 41A is a schematic cross-sectional view for explaining a fifth example of a case where the display device 10 has resonator structures. The fifth example is similar to the first example, except that the optical adjustment layers 31 are not included, and oxide films 32 are formed on the first surface side (the side of the surfaces facing the first electrodes 13) of the reflectors 30.

The thicknesses of the oxide films 32 vary among the sub-pixels 101R, 101G, and 101B (light emitting elements 104R, 104G, and 104B).

Regarding the thicknesses of the oxide films 32, the respective thicknesses of the oxide films 32 are designed so as to set optical distances for causing optical resonance suitable for the sub-pixels 101R, 101G, and 101B.

The oxide films 32 are films obtained by oxidizing the surfaces of the reflectors 30, and are formed with aluminum oxide, tantalum oxide, titanium oxide, magnesium oxide, zirconium oxide, or the like, for example. The oxide films 32 function as insulating films for adjusting the optical path lengths (optical distances) between the reflectors 30 and the second electrodes 15.

The oxide films 32 having thicknesses suitable for the sub-pixels 101R, 101G, and 101B can be formed in the following manner, for example.

First, a substrate on which the reflectors 30 are formed is immersed in a container filled with an electrolytic solution, and electrodes are disposed so as to face the reflectors 30.

With the electrodes being used as references, positive voltages are then applied to the reflectors 30, to anodize the reflectors 30. Voltages corresponding to the thicknesses of the oxide films 32 to be obtained are applied to the reflectors 30 of the sub-pixels 101R, 101G, and 101B. As a result, the oxide films 32 having different thicknesses (the oxide films 32 having thicknesses suitable for the sub-pixels 101R, 101G, and 101B) can be collectively formed on the reflectors 30 of the sub-pixels 101R, 101G, and 101B.

### Resonator Structure: Sixth Example

FIG. 41B is a schematic cross-sectional view for explaining a sixth example of a case where the display device 10 has resonator structures.

In the sixth example, each resonator structure of the display device 10 is formed with a structure in which the first electrode 13, the organic layer 14, and the second electrode 15 are stacked. In the sixth example, each first electrode 13 is a first electrode (also serving as a reflector) 33 that is designed to function as both an electrode and a reflector. The first electrodes (also serving as reflectors) 33 are formed with a material having an optical constant selected in accordance with the types of the light emitting elements 104R, 104G, and 104B. Since the phase shift by the first electrodes (also serving as reflectors) 33 vary, it is possible to set an optical distance for generating optimum resonance for the wavelength of light corresponding to the color to be displayed.

The first electrodes (also serving as reflectors) 33 can be formed with a single-component metal such as aluminum (Al), silver (Ag), gold (Au), or copper (Cu), or an alloy containing these metals as the principal components. For example, the first electrode (also serving as a reflector) 33R of the sub-pixel 101R may be formed with copper (Cu), and the first electrode (also serving as a reflector) 33G of the sub-pixel 101G and the first electrode (also serving as a reflector) 33B of the sub-pixel 101B may be formed with aluminum.

The second electrodes 15 and the organic layers 14 are similar to those of the first example, and therefore, explanation of them is not made herein.

### Resonator Structure: Seventh Example

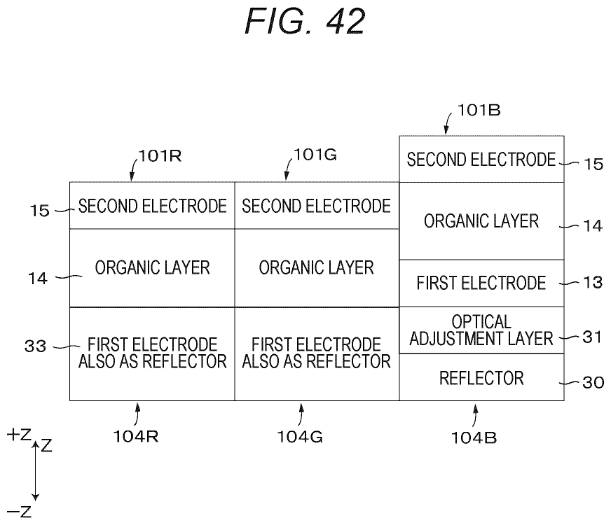

FIG. 42 is a schematic cross-sectional view for explaining a seventh example of a case where the display device 10 has resonator structures.

In the seventh example, the resonator structures illustrated in the sixth example are provided for the sub-pixels 101R and 101G (light emitting elements 104R and 104G), and the resonator structure illustrated in the first example is provided for the sub-pixel 101B (light emitting element 104B).

[8 Examples of Positional Relationship in Cases where the Display Device Includes Wavelength Selection Units]

Regarding the positional relationship in a case where wavelength selection units are formed in a display device 10, the mutual positional relationship among the light emitting units, the lens members, and the wavelength selection units is now described, with a display device 10 obtained by combining Modification 15 and Modification 14 of the first embodiment being taken as an example. The display device 10 according to the sixth embodiment includes color filters as wavelength selection units.

### (Color Filters, and Lenses)

In the display device 10 according to the sixth embodiment, wavelength selection units and lens members may be provided for the respective sub-pixels 101. In the example described in the sixth embodiment, the wavelength selection units are the color filters 17. For example, as the color filters 17, a red-color filter 17R, a green-color filter 17G, and a blue-color filter 17B are provided for the sub-pixels 101R, 101G, and 101B, respectively. At this point of time, light absorbing layers are preferably provided between the adjacent color filters 17. Examples of the light absorbing layers include black matrix portions. Further, in the example described in the sixth embodiment, lenses are provided as the lens members.

### (Relationship Among Normal Lines Extending Through the Centers of Light Emitting Units, Lens Members, and Wavelength Selection Units)

In the description below, the relationship among a normal line LN extending through the center of a light emitting unit, a normal line LN′ extending through the center of a lens member, and a normal line LN″ extending through the center of a wavelength selection unit is described. Here, the light emitting unit is a portion corresponding to a counter region K, for example. The lens member is a lens, for example. The wavelength selection unit is a red-color filter 17R, a green-color filter 17G, or a blue-color filter 17B, for example.

Note that the size of the wavelength selection units may be changed as appropriate in accordance with light emitted from the light emitting units, or, in a case where the light absorbing units (black matrix portions, for example) are provided between the wavelength selection units of adjacent light emitting units, the size of the light absorbing units may be changed as appropriate in accordance with light emitted from the light emitting units. Also, the size of each wavelength selection unit may be changed as appropriate in accordance with the distance (offset amount) d₀ between the normal line extending through the center of the light emitting unit and the normal line extending through the center of the wavelength selection unit. The planar shape of each wavelength selection unit may be the same as, similar to, or different from the planar shape of each lens member.

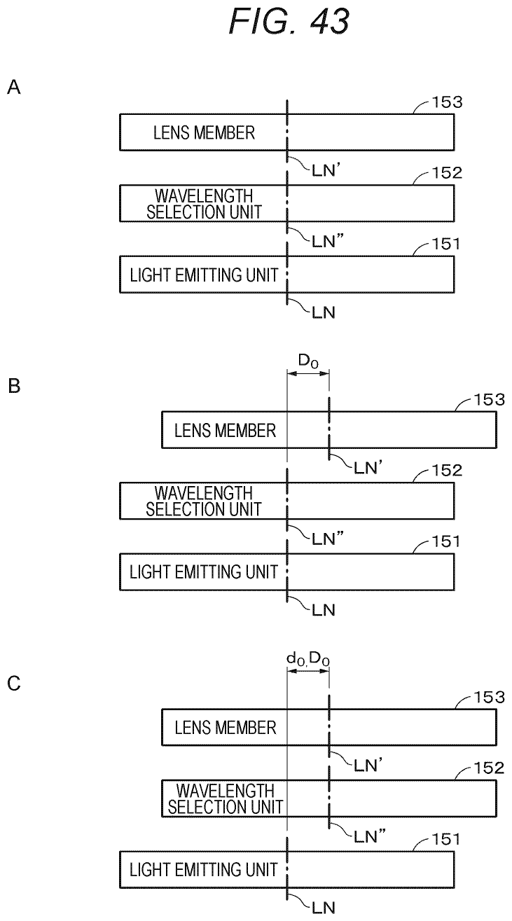

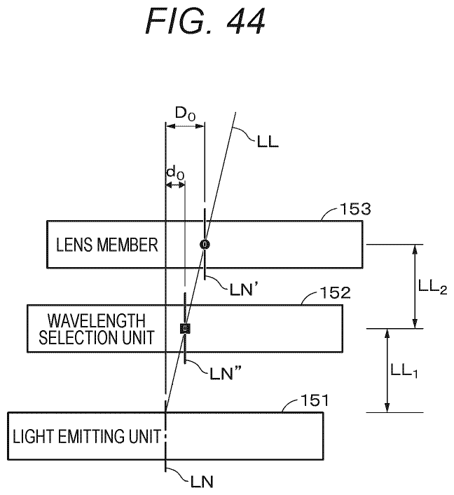

In the description below, referring to FIGS. 43A, 43B, 43C, and 44, the relationship among the normal lines extending through the center of the respective members in a case where a light emitting unit 151 (corresponding to the counter region K in the example in FIG. 2), a wavelength selection unit 152, and a lens member 153 are arranged in this order will be described.

As illustrated in FIG. 43A, the normal line LN extending through the center of the light emitting unit 151, the normal line LN″ extending through the center of the wavelength selection unit 152, and the normal line LN′ extending through the center of the lens member 153 may coincide with one another. That is, D₀=0 and d₀=0 may be satisfied. Here, Do represents the distance (offset amount) between the normal line LN extending through the center of the light emitting unit 151 and the normal line LN′ extending through the center of the lens member 153, and d₀ represents the distance (offset amount) between the normal line LN extending through the center of the light emitting unit 151 and the normal line LN″ extending through the center of the wavelength selection unit 152.

As illustrated in a configuration in FIG. 43B, the normal line LN extending through the center of the light emitting unit 151 and the normal line LN″ extending through the center of the wavelength selection unit 152 may coincide with each other, but the normal line LN extending through the center of the light emitting unit 151 and the normal line LN″ extending through the center of the wavelength selection unit 152 may not coincide with the normal line LN′ extending through the center of the lens member 153. That is, D₀>0 and d₀=0 may be satisfied.

As illustrated in a configuration in FIG. 43C, the normal line LN extending through the center of the light emitting unit 151 may not coincide with the normal line LN″ extending through the center of the wavelength selection unit 152 and the normal line LN′ extending through the center of the lens member 153, and the normal line LN″ extending through the center of the wavelength selection unit 152 may coincide with the normal line LN′ extending through the center of the lens member 153. That is, D₀>0, d₀>0, and D₀=d₀ may be satisfied.

As illustrated in a configuration in FIG. 44, the normal line LN extending through the center of the light emitting unit 151, the normal line LN″ extending through the center of the wavelength selection unit 152, and the normal line LN′ extending through the center of the lens member 153 may not coincide with one another. That is, D₀>0, d₀>0, and D₀≠d₀ may be satisfied. Here, the center of the wavelength selection unit 152 (the position indicated by a black square in FIG. 44) is preferably located on the straight line LL connecting the center of the light emitting unit 151 and the center of the lens member 153 (the position indicated by a black circle in FIG. 44). Specifically, where the distance in the thickness direction (the vertical direction in FIG. 44) between the center of the light emitting unit 151 and the center of the wavelength selection unit 152 is represented by LL₁, and the distance in the thickness direction between the center of the wavelength selection unit 152 and the center of the lens member 153 is represented by LL₂,
the following is preferably satisfied,

$${D}_{0} > {d}_{0} > 0$$

and, with manufacturing variations being taken into consideration, the following is preferably satisfied,

$${d}_{0} : {D}_{0} = {LL}_{1} : ( {LL}_{1} + {LL}_{2} )$$

Here, the thickness direction indicates the thickness direction of the light emitting unit 151, the wavelength selection unit 152, and the lens member 153.

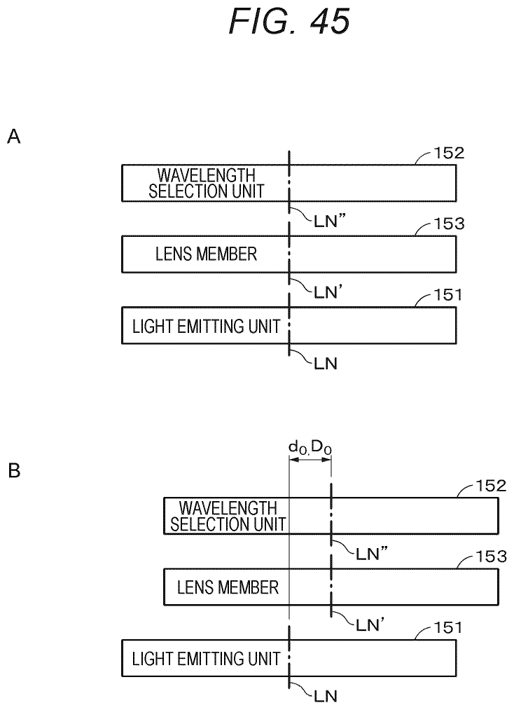

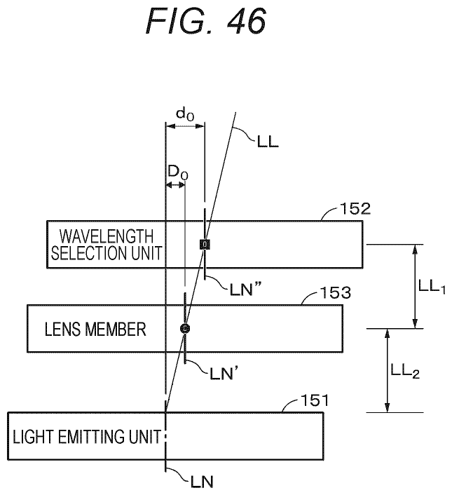

In the description below, referring to FIGS. 45A, 45B, and 46, the relationship among the normal lines extending through the center of the respective members in a case where the light emitting unit 151, the lens member 153, and the wavelength selection unit 152 are arranged in this order will be described.

As illustrated in a configuration in FIG. 45A, the normal line LN extending through the center of the light emitting unit 151, the normal line LN″ extending through the center of the wavelength selection unit 152, and the normal line LN′ extending through the center of the lens member 153 may coincide with one another. That is, D₀>0 and d₀=0 may be satisfied.

As illustrated in a configuration in FIG. 45B, the normal line LN extending through the center of the light emitting unit 151 may not coincide with the normal line LN″ extending through the center of the wavelength selection unit 152 and the normal line LN′ extending through the center of the lens member 153, and the normal line LN″ extending through the center of the wavelength selection unit 152 may coincide with the normal line LN′ extending through the center of the lens member 153. That is, D₀>0, d₀>0, and D₀=d₀ may be satisfied.

As illustrated in a configuration in FIG. 46, the normal line LN extending through the center of the light emitting unit 151, the normal line LN″ extending through the center of the wavelength selection unit 152, and the normal line LN′ extending through the center of the lens member 153 may not coincide with one another. Here, the center of the lens member 153 (the position indicated by a black circle in FIG. 46) is preferably located on the straight line LL connecting the center of the light emitting unit 151 and the center of the wavelength selection unit 152 (the position indicated by a black square in FIG. 46). Specifically, where the distance in the thickness direction (the vertical direction in FIG. 46) between the center of the light emitting unit 151 and the center of the lens member 153 is represented by LL₂, and the distance in the thickness direction between the center of the lens member 153 and the center of the wavelength selection unit 152 is represented by LL₁,
the following expression is preferably satisfied,

$${d}_{0} > {D}_{0} > 0$$

and, with manufacturing variations being taken into consideration, the following expression is preferably satisfied,

$${D}_{0} : {d}_{0} = {LL}_{2} : ( {LL}_{1} + {LL}_{2} )$$

Here, the thickness direction indicates the thickness direction of the light emitting unit 151, the wavelength selection unit 152, and the lens member 153.

### 9 Example Applications

(Electronic Apparatuses) A display device 10 according to the present disclosure may be included in various electronic apparatuses. For example, a display element (display device 10) according to one of the embodiments (any one of the first to sixth embodiments) described above may be included in various electronic apparatuses. Especially, a display element according to one of the above embodiments is preferably included in an electronic viewfinder of a video camera or a single-lens reflex camera, a head mounted display, or the like in which high resolution is required, used for enlarging near the eyes.

### Specific Example 1

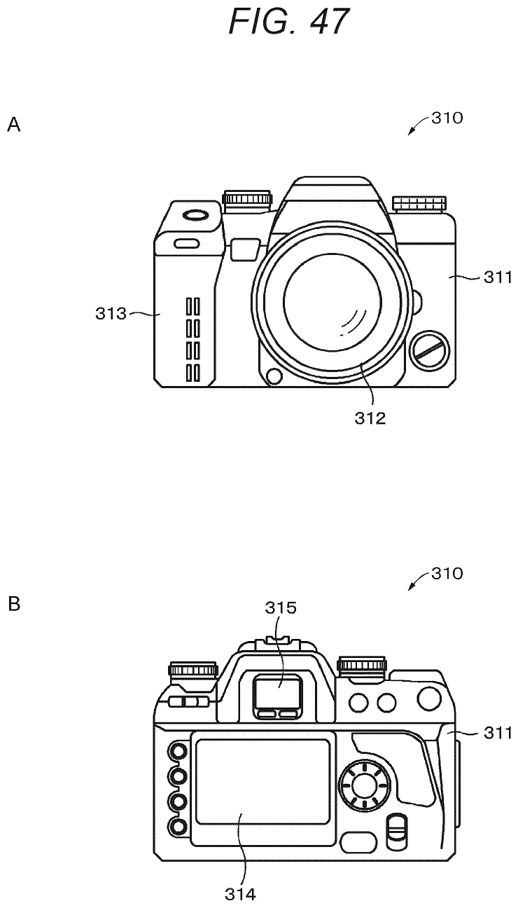

FIG. 47A is a front view illustrating an example of an external appearance of a digital still camera 310. FIG. 47B is a rear view illustrating an example of an external appearance of the digital still camera 310. The digital still camera 310 is of a lens interchangeable single-lens reflex type, and includes an interchangeable imaging lens unit (interchangeable lens) 312 substantially at the center on the front surface of a camera main body (camera body) 311, and a grip 313 to be held by the photographer on the front left side.

A monitor 314 is provided at a position shifted to the left side from the center of the rear surface of the camera main body 311. An electronic viewfinder (eyepiece window) 315 is provided above the monitor 314. By looking through the electronic viewfinder 315, the photographer can visually recognize an optical image of the subject guided from the imaging lens unit 312, and determine a picture composition. As the electronic viewfinder 315, a display device 10 according to any one of the above embodiments and modifications thereof can be used.

### Specific Example 2

FIG. 48 is a perspective view illustrating an example of an external appearance of a head-mounted display 320. The head-mounted display 320 includes ear hooking portions 322 to be worn on the head of the user on both sides of a display unit 321 in the shape of eyeglasses, for example. As the display unit 321, a display device 10 according to any one of the above embodiments and modifications thereof can be used.

### Specific Example 3

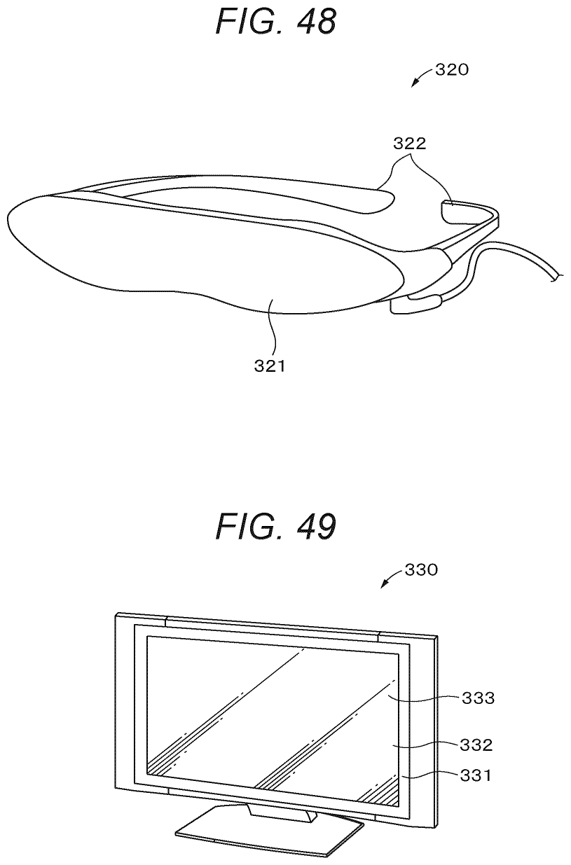

FIG. 49 is a perspective view illustrating an example of an external appearance of a television device 330. The television device 330 includes a video display screen unit 331 including a front panel 332 and a filter glass 333, and the video display screen unit 331 is formed with a display device 10 according to any one of the above embodiments and modifications thereof, for example.

### Specific Example 4

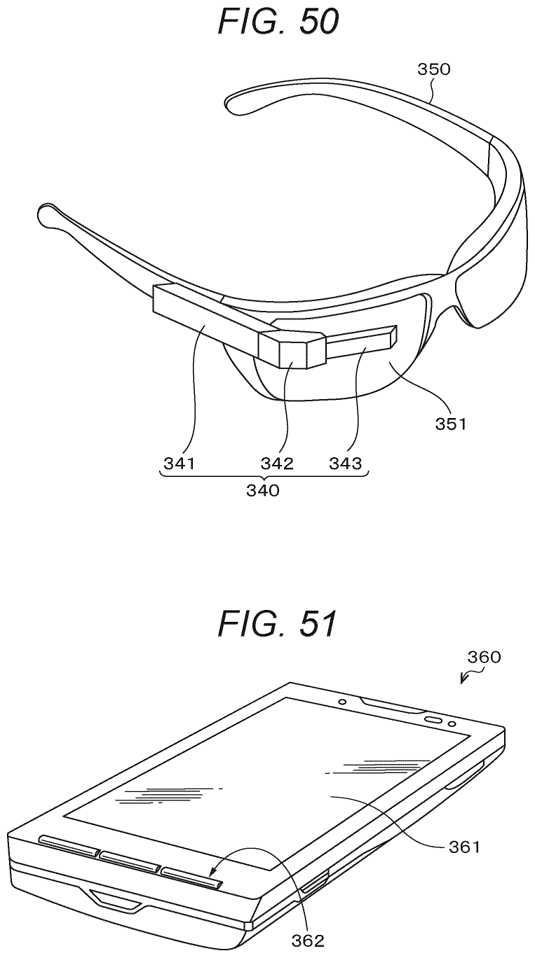

FIG. 50 illustrates an example of an external appearance of a see-through head-mounted display 340. The see-through head-mounted display 340 includes a main body 341, an arm 342, and a lens barrel 343.

The main body 341 is connected to the arm 342 and eyeglasses 350. Specifically, an end portion of the main body 341 in the long side direction is coupled to the arm 342, and one side of a side surface of the main body 341 is coupled to the eyeglasses 350 via a connecting member. Note that the main body 341 may be directly mounted on the head of the human body.

The main body 341 incorporates a control board for controlling operation of the see-through head-mounted display 340, and a display unit. The arm 342 connects the main body 341 and the lens barrel 343, and supports the lens barrel 343. Specifically, the arm 342 is coupled to an end portion of the main body 341 and an end portion of the lens barrel 343, and secures the lens barrel 343. Furthermore, the arm 342 incorporates a signal line for communicating data related to an image to be provided from the main body 341 to the lens barrel 343.

The lens barrel 343 projects image light provided from the main body 341 via the arm 342 toward the eyes of the user wearing the see-through head-mounted display 340 through an eyeglass 351. In this see-through head-mounted display 340, the display unit of the main body 341 includes one of the above display devices 10 and the like.

### Specific Example 5

FIG. 51 is a perspective view illustrating an example of an external appearance of a smartphone 360. As illustrated in FIG. 51, the smartphone 360 includes a display unit 361 that displays information about pixels or the like, an operating unit 362 that includes buttons and the like for receiving an operation input by the user. A display device 10 according to one of the above embodiments and modifications can be adopted as the display unit 361.

### Specific Example 6

Any of the display devices 10 and the like described above may be included in a vehicle or in various kinds of displays.

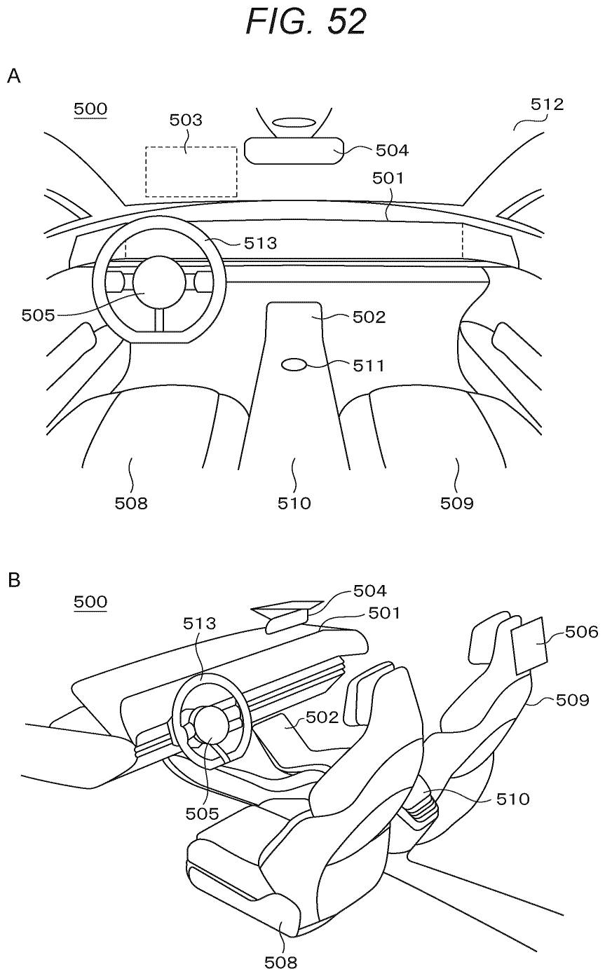

FIGS. 52A and 52B are diagrams illustrating an example of an internal configuration of a vehicle 500 provided with various displays. Specifically, FIG. 52A is a diagram illustrating an example of an internal state of the vehicle 500 as viewed from the rear side to the front side of the vehicle 500. FIG. 52B is a diagram illustrating an example of an internal state of the vehicle 500 as viewed obliquely from the rear side to the front side of the vehicle 500.

The vehicle 500 includes a center display 501, a console display 502, a head-up display 503, a digital rearview mirror 504, a steering wheel display 505, and a rear entertainment display 506. At least one of these displays includes any one of the above display devices 10 and the like. For example, all of these displays may include one of the above display devices 10 and the like.

The center display 501 is disposed on the dashboard at a location facing a driver's seat 508 and a passenger seat 509. FIGS. 52A and 52B illustrate an example of the center display 501 having a horizontally long shape extending from the side of the driver's seat 508 to the side of the passenger seat 509, but any screen size and installation location for the center display 501 may be adopted. The center display 501 can display information sensed by various sensors. As a specific example, the center display 501 can display an image captured by an image sensor, an image of the distance to an obstacle in front of or on a side of the vehicle 500, the distance being measured by a ToF sensor, a passenger's body temperature detected by an infrared sensor, and the like. The center display 501 can be used to display at least one piece of safety-related information, operation-related information, lifelogs, health-related information, authentication/identification-related information, or entertainment-related information, for example.

The safety-related information is information about doze sensing, looking-away sensing, sensing of mischief of a child riding together, presence or absence of wearing of a seat belt, sensing of leaving of an occupant, and the like, and is information sensed by a sensor disposed to overlap with the back surface side of the center display 501, for example. The operation-related information senses a gesture related to an operation performed by an occupant, using a sensor. Gestures to be sensed may include an operation of various kinds of equipment in the vehicle 500. For example, operations of air conditioning equipment, a navigation device, an audiovisual (AV) device, an illuminating device, and the like are detected. The lifelogs include lifelogs of all the occupants. For example, the lifelogs include an action record of each occupant in the vehicle. By acquiring and storing the lifelogs, it is possible to check the state of each occupant at the time of an accident. The health-related information senses the body temperature of an occupant, using a sensor such as a temperature sensor, and estimates the health condition of the occupant on the basis of the sensed body temperature. Alternatively, the face of the occupant may be imaged with an image sensor, and the health condition of the occupant may be estimated from the imaged facial expression. Further, a conversation may be made with an occupant in automatic voice, and the health condition of the occupant may be estimated on the basis of the contents of a response from the occupant. The authentication/identification-related information includes a keyless entry function of performing face authentication using a sensor, and a function of automatically adjusting a seat height and position through face identification. The entertainment-related information includes a function of detecting, with a sensor, operation information about an AV device being used by an occupant, and a function of recognizing the face of the occupant with sensor and providing content suitable for the occupant through the AV device.

The console display 502 can be used to display lifelog information, for example. The console display 502 is disposed near a shift lever 511 of a center console 510 between the driver's seat 508 and the passenger seat 509. The console display 502 can also display information detected by various sensors. Furthermore, the console display 502 may display an image of the surroundings of the vehicle captured with an image sensor, or may display an image of the distance to an obstacle present in the surroundings of the vehicle.

The head-up display 503 is virtually displayed behind a windshield 512 in front of the driver's seat 508. The head-up display 503 can be used to display at least one piece of the safety-related information, the operation-related information, the lifelogs, the health-related information, the authentication/identification-related information, or the entertainment-related information, for example. Being virtually disposed in front of the driver's seat 508 in many cases, the head-up display 503 is suitable for displaying information directly related to operations of the vehicle 500, such as the speed, the remaining amount of fuel (battery), and the like of the vehicle 500.

The digital rearview mirror 504 can not only display the rear of the vehicle 500 but also display the state of an occupant in the rear seat, and thus, can be used to display the lifelog information by disposing a sensor on the back surface side of the digital rearview mirror 504 in an overlapping manner, for example.

The steering wheel display 505 is disposed near the center of a steering wheel 513 of the vehicle 500. The steering wheel display 505 can be used to display at least one piece of the safety-related information, the operation-related information, the lifelogs, the health-related information, the authentication/identification-related information, or the entertainment-related information, for example. In particular, being located close to the driver's hands, the steering wheel display 505 is suitable for displaying the lifelog information such as the body temperature of the driver, or for displaying information regarding operations of the AV device, the air conditioning equipment, or the like.

The rear entertainment display 506 is attached to the back side of the driver's seat 508 or the passenger seat 509, and is for an occupant in the rear seat to enjoy viewing/listening. The rear entertainment display 506 can be used to display at least one piece of the safety-related information, the operation-related information, the lifelogs, the health-related information, the authentication/identification-related information, or the entertainment-related information, for example. In particular, as the rear entertainment display 506 is located in front of an occupant in the rear seat, information related to the occupant in the rear seat is displayed. For example, information regarding an operation of the AV device or the air conditioning equipment may be displayed, or a result of measurement of the body temperature or the like of an occupant in the rear seat with a temperature sensor may be displayed.

A sensor may be disposed on the back surface side of a display device 10 or the like in an overlapping manner, so that the distance to an object present in the surroundings can be measured in the configuration. Optical distance measurement methods are roughly classified into a passive type and an active type. By a method of the passive type, distance measurement is performed by receiving light from an object, without projecting light from a sensor to the object. Methods of the passive type include a lens focus method, a stereo method, and a monocular vision method. Methods of the active type include distance measurement that is performed by projecting light onto an object, and receiving reflected light from the object with a sensor to measure the distance. Methods of the active type include an optical radar method, an active stereo method, an illuminance difference stereo method, a moire topography method, and an interference method. Any of the display devices 10 and the like described above can be used in distance measurement by any of these methods. With a sensor disposed on the back surface side of the above display device 10 or the like in an overlapping manner, distance measurement of the passive type or the active type described above can be performed.

### 10 Illuminating Device

The light emitting device according to the present disclosure has been described in detail in the first to third embodiments and the modifications described above, taking as an example a case where the light emitting device is a display device. The light emitting device according to the present disclosure is not necessarily a display device, and may be used as an illuminating device. In a case where the light emitting device according to the present disclosure is used as an illuminating device, any of the configurations described in the first to sixth embodiments and the modifications described above can also be adopted.

### 11 Display Object

A light emitting device according to the present disclosure may be used as a display object. The display object may be a neon sign provided with a light emitter, an advertisement capable of light emission display, or the like. In a case where a light emitting device according to the present disclosure is used as an illuminating device, any of the configurations described above in the first to sixth embodiments and the modifications can also be adopted.

Next, specific examples are used in the description that further continues.

### EXAMPLES

### Example 1

For a display device, sub-pixels (blue sub-pixels) having blue as the emission color and sub-pixels (yellow sub-pixels) having yellow as the emission color were selected as a plurality of sub-pixels of different color types, as described in Modification 2 of the first embodiment. A display device having the layer configuration illustrated in FIGS. 3, 4, and 5 was selected as the display device.

An insulating layer and first electrodes were formed on the first surface side of a substrate. Openings (opening width: 800 μm, shape: rectangular) are formed in the insulating layer, and the first electrodes have surfaces exposed through the openings of the insulating layer. The first electrodes are anodes.

A plurality of insulating structures was disposed on the exposed surfaces of the first electrodes corresponding to the blue sub-pixels. The material of the insulating structures is SiO₂, the height and the diameter of the insulating structures are both 20 nm, and the diameter of each insulating structure is the diameter of the cylindrical portion. The plurality of insulating structures was arranged in a lattice-like form with a pitch of 2 μm.

Any insulating structure was not disposed on the exposed surfaces of the first electrodes corresponding to the yellow sub-pixels.

Next, an oxygen plasma treatment was performed, and a hole injection layer, a hole transport layer, a blue light emitting layer (fluorescent light emitting layer) as a first light emitting layer, an intermediate layer, a yellow light emitting layer (phosphorescent light emitting layer) as a second light emitting layer, an electron transport layer, and an electron injection layer (doped with lithium) were further formed in this order by a vacuum vapor deposition method. Second electrode were then formed. As the second electrodes, IZO films formed by a DC sputtering method were adopted. A protective layer was formed on the first surface side of the second electrodes. As the protective layer, a SiN film formed by a plasma CVD method was adopted. A glass substrate was used as a counter substrate, and the counter substrate was bonded onto the protective layer via a resin (a filling resin layer). The stack structure obtained by the steps up to the bonding of the counter substrate was heated with a hot plate (this treatment is called the heating treatment). The heating treatment was performed under heating conditions of 110 degrees Celsius and 10 minutes. Thus, a display device was obtained.

### (Light Emission Test)

A light emission test on the display device was performed as follows. The display device was caused to emit light at a current density of 10 mA/cm². It was confirmed that blue (whitish blue) light emission was obtained from the blue sub-pixels, and yellow (whitish yellow) light emission was obtained from the yellow sub-pixels. Thus, it was confirmed that installation of the insulating structures could change the emission color.

### (Cross-Sectional Structures)

A cross-sectional structure of a portion corresponding to a blue sub-pixel and a cross-sectional structure of a portion corresponding to a yellow sub-pixel in the display device were observed. In the blue sub-pixel, a portion having blue as the emission color, and a portion having whitish yellow as the emission color were observed. The portion having blue as the emission Color was observed in a region of 0.5 μm around a large number of structures. In this region, it was confirmed that a component forming the electron transfer layer was mixed in the second light emitting layer, which means that formation of a mixing region was confirmed. Formation of any mixing region was not confirmed in the portion having whitish yellow as the emission color. Accordingly, it was confirmed that a mixing layer was formed in the light emitting elements in the sub-pixels by installation of the insulating structures, which means that mixing regions can be formed in the regions of the sub-pixels.

It was confirmed that the yellow sub-pixels were normally formed with whitish yellow portions. Note that, in each of the blue sub-pixels and the yellow sub-pixels, a portion having blue as the emission color was observed in an annular region having a width of about 0.5 μm along the outer peripheral edge thereof.

### Example 2

A display device was selected, and, in the selected display device, three types of sub-pixels, which are red sub-pixels, green sub-pixels, and blue sub-pixels, were provided as a plurality of sub-pixels having different color types, as described in Modification 3 of the first embodiment, and as illustrated in FIGS. 8 and 9. Also, a display device having the layer configuration illustrated in FIGS. 3, 4, and 5 was selected as the display device, as in Example 1.

An insulating layer and first electrodes were formed on the first surface side of the substrate by a method and under conditions similar to those used in Example 1, except that the width of openings was 10 μm.

A plurality of insulating structures was disposed on the exposed surfaces of the first electrodes corresponding to the blue sub-pixels by a method and under conditions similar to those used in Example 1. Any insulating structure was not installed on the exposed surfaces of the first electrodes corresponding to the green sub-pixels and the red sub-pixels.

After the formation of the insulating structures, an organic layer, second electrodes, and a protective layer were provided by a method and under conditions similar to those used in Example 1. A smoothing layer was formed with an overcoat material on the protective layer, and blue-color filters, green-color filters, and red-color filters were provided as color filters so as to cover the regions corresponding to the blue sub-pixels, the green sub-pixels, and the red sub-pixels, respectively. The color filters were formed by a photolithography method or the like. A counter substrate was bonded to the color filters on the first surface side, with a filling resin layer being interposed in between. Next, a heating treatment was performed by a method and under conditions similar to those used in Example 1. Thus, a display device was obtained.

### (Light Emission Test)

The display device obtained in Example 2 was subjected to a light emission test in a manner similar to the light emission test described in Example 1. For each of the blue sub-pixels, the green sub-pixels, and the red sub-pixels, light emission corresponding to the color type of each sub-pixel was observed. Thus, it was confirmed that the display device obtained in Example 2 can perform full-color display.

### Example 3

A display device including a plurality of pixels as described in the first embodiment was selected. Also, a display device having the layer configuration illustrated in FIGS. 3, 4, and 5 was selected as the display device, as in Example 1.

An insulating layer and first electrodes were formed on the first surface side of a substrate. Openings (opening width: 12 μm, shape: rectangular) are formed in the insulating layer, and the first electrodes have surfaces exposed through the openings of the insulating layer. The first electrodes are anodes.

A plurality of insulating structures was disposed on the exposed surfaces of the first electrodes corresponding to the respective sub-pixels. The material of the insulating structures is SiO₂, the height of the insulating structures is 20 nm, the diameter of the insulating structures is 100 nm, and the shape of the insulating structures is a cylindrical shape. However, several different numerical values were determined as the numbers of insulating structures that were provided. A plurality of insulating structures was provided in each pixel 100 in accordance with the numerical value determined for the pixel 100.

Next, an organic layer, a second electrode, a protective layer, a filling resin layer, and a counter substrate were provided by a method and under conditions similar to those used in Example 1. A heating treatment was then performed by a method and under conditions similar to those used in Example 1. Thus, a display device was obtained.

### (Light Emission Test)

The display device obtained in Example 3 was subjected to a light emission test in a manner similar to the light emission test described in Example 1. As for the emission colors of the pixels, it was confirmed that the blue color was stronger in the emission color of a pixel in which the number of insulating structures was larger. Also, it was confirmed that the yellow color was stronger in the emission color of a pixel having a smaller number of insulating structures. It was confirmed that the emission color of a pixel can be changed in accordance with the density of insulating structures, as the density of insulating structures is changed when the number of the insulating structures in the pixel is changed.

### Example 4

A display device that has insulating structures as described in the second embodiment, and includes a plurality of pixels was selected. Also, a display device having a layer configuration as illustrated in FIGS. 13, 4, and 5 was selected.

An insulating layer and first electrodes were formed on the first surface side of a substrate. Openings (opening width: 18 μm, shape: rectangular) are formed in the insulating layer, and the first electrodes have surfaces exposed through the openings of the insulating layer. The first electrodes are anodes.

The insulating structures were disposed on the exposed surfaces of the first electrodes corresponding to the respective pixels. The insulating structures were formed with the same material as the insulating layer, and the insulating structures were formed in a lattice-like form and a wall-like form. The insulating structures included first structures, second structures, and third structures, and were designed so as to divide the counter region (the exposed surfaces of the first electrodes) into rectangular regions. Note that the regions that have been divided are referred to as the divided regions as described above.

However, as for the layout of the provided insulating structures, several types of layouts in which the sizes of the divided regions are different were determined. As the layouts of the insulating structures, a layout (first layout) in which the size (width) of the divided regions was 9 μm, a layout (second layout) in which the size of the divided regions was 4 μm, and a layout (third layout) in which the size of the divided regions was 2 μm were determined. The number of divisions of the counter region divided by the insulating structures becomes larger as the size of the divided regions becomes smaller.

In each pixel, the insulating structure was provided on the first electrode, in accordance with a predetermined layout. The insulating structures were provided in the first layout for some of the pixels, and the insulating structures were provided in the second layout for some other ones of the pixels. Of the pixels, those not having the insulating structures provided in the first layout or the second layout have the insulating structures provided in the third layout.

Next, an organic layer, a second electrode, a protective layer, a filling resin layer, and a counter substrate were provided by a method and under conditions similar to those used in Example 1. A heating treatment was then performed by a method and under conditions similar to those used in Example 1. Thus, a display device was obtained.

### (Light Emission Test)

The display device obtained in Example 3 was subjected to a light emission test in a manner similar to the light emission test described in Example 1. As for the emission colors of the pixels, it was confirmed that the blue color was stronger in a pixel having the insulating structures in the second layout than in a pixel having the insulating structures in the first layout. Also, as for the emission colors of pixels, it was confirmed that the blue color was stronger in a pixel having the insulating structures in the third layout than in a pixel having the insulating structures in the second layout. Accordingly, it was confirmed that the emission color of a pixel can be changed in accordance with the number of divisions of the counter region divided by the insulating structures in the pixel, or the size of the divided regions.

### Example 5

A display device that had red sub-pixels and pink sub-pixels as a plurality of sub-pixels of different color types as described in a modification of the third embodiment was selected as the display device. Also, a display device having the layer configuration illustrated in FIG. 3 was selected as the display device, as in Example 1. However, as for the configuration of the organic layer, an organic layer having the layer configuration illustrated in FIGS. 14 and 15 was selected, which differs from Example 1.

An insulating layer and first electrodes were formed on the first surface side of a substrate. Openings (opening width: 800 μm, shape: rectangular) are formed in the insulating layer, and the first electrodes have surfaces exposed through the openings of the insulating layer. The first electrodes are anodes.

A plurality of insulating structures was disposed on the exposed surfaces of the first electrodes corresponding to the red sub-pixels by a method and under conditions similar to those used in Example 1.

Any insulating structure was not disposed on the exposed surfaces of the first electrodes corresponding to the pink sub-pixels.

Next, an oxygen plasma treatment was performed, and a hole injection layer, a hole transport layer, a red light emitting layer (fluorescent light emitting layer) as a first light emitting layer, an intermediate layer, a blue light emitting layer (fluorescent light emitting layer) as a second light emitting layer, an electron transport layer, and an electron injection layer (doped with lithium) were further formed in this order by a vacuum vapor deposition method. Next, a second electrode, a protective layer, a filling resin layer, and a counter substrate were provided by a method and under conditions similar to those used in Example 1. Further, a heating treatment was performed by a method and under conditions similar to those used in Example 1. Thus, a display device was obtained.

### (Light Emission Test)

With the display device of Example 5, a light emission test was conducted in a manner and under conditions similar to those used in Example 1. The display device was caused to emit light at a current density of 10 mA/cm². It was confirmed that red (pinkish red) light emission was obtained from the red sub-pixels, and pink (reddish yellow) light emission was obtained from the pink sub-pixels. Thus, it was confirmed that installation of the insulating structures could change the emission color.

### (Cross-Sectional Structures)

A cross-sectional structure of a portion corresponding to a red sub-pixel and a cross-sectional structure of a portion corresponding to a pink sub-pixel in the display device were observed. In the red sub-pixel, a portion having red as the emission color and a portion having pink as the emission color were confirmed. The portion having red as the emission color was observed in a region of 0.5 μm around a large number of insulating structures. In this region, it was confirmed that a component forming the red light emitting layer as the first light emitting layer was mixed in the intermediate layer, which means that formation of a mixing region was confirmed. Formation of any mixing region was not confirmed in the portion having pink as the emission color. Accordingly, it was confirmed that a mixing layer was formed in the light emitting elements in the sub-pixels by installation of the insulating structures, which means that mixing regions can be formed in the regions of the sub-pixels.

It was confirmed that the pink sub-pixels were normally formed with pink portions. Note that, in each of the red sub-pixels and the pink sub-pixels, a portion having red as the emission color was observed in an annular region having a width of about 0.5 μm along the outer peripheral edge of the sub-pixel.

In the mixing regions, a component (organic material) forming the first light emitting layer is mixed with a component (organic material) forming the intermediate layer. Therefore, it is considered that the carrier transporting properties are changed, and the light emitting regions in the thickness direction of the light emitting elements are changed, to cause the red light emitting layer to emit strong light. It is considered that, in the portions where mixing of organic materials does not occur, strong blue light is emitted while red light emission is very weak, and therefore, blue light is dominantly emitted.

The display elements according to the first to sixth embodiments of the present disclosure and the modifications of the embodiments, the example applications, and Examples 1 to 5 have been specifically described so far. However, the present disclosure is not limited to the display elements according to the first to sixth embodiments and the modifications of the embodiments, the example applications, and Examples 1 to 5 described above, and various modifications based on the technical idea of the present disclosure can be made.

For example, the configurations, methods, steps, shapes, materials, numerical values, and the like given in the display elements according to the first to sixth embodiments and the modifications thereof, the example applications, and Examples 1 to 5 are merely examples, and different configurations, methods, steps, shapes, materials, numerical values, and the like may be used as necessary.

The configurations, methods, steps, shapes, materials, numerical values, and the like of the display elements according to the first to sixth embodiments and the modifications thereof, the example applications, and Examples 1 to 5 can be combined with one another without departing from the gist of the present disclosure.

The materials mentioned as examples in the display elements according to the first to sixth embodiments and the modifications thereof, the example applications, and Examples 1 to 5 can be used independently of one another or in combination of two or more, unless otherwise specified.

Further, the present disclosure can also adopt the following configurations.

(1)

A light emitting device including:
a substrate; and
a first electrode, an organic layer, and a second electrode that are sequentially stacked on the substrate, in which
the organic layer includes a plurality of functional layers including a plurality of types of light emitting layers of different color types, and,
in a case where a thickness direction of the substrate is set as a line-of-sight direction, a mixing layer is formed in at least a portion of the organic layer, the portion extending in a plane direction of the organic layer, the mixing layer being defined in accordance with the following conditions:
in a case where a first position and a second position in the organic layer are selected as two positions different in the plane direction of the organic layer, and components of the organic layer at the first position and the second position are compared in a thickness direction of the organic layer, a layer in which components of the plurality of different functional layers forming the organic layer are mixed, and which is recognized only at one of the first position or the second position is determined as the mixing layer.

(2)

The light emitting device according to (1), in which
the organic layer includes a first light emitting layer and a second light emitting layer as a plurality of types of the light emitting layers, and includes, as the plurality of functional layers, a hole injection layer, a hole transport layer, the first light emitting layer, an intermediate layer, the second light emitting layer, an electron transport layer, and an electron injection layer in order from a side closer to the first electrode, and
the mixing layer includes a layer in which a component forming at least part of the second light emitting layer and a component forming at least part of the electron transport layer are mixed.

(3)

The light emitting device according to (2), in which
the first light emitting layer is a fluorescent light emitting layer,
the second light emitting layer is a phosphorescent light emitting layer, and,
in the intermediate layer, an energy level at T1 level of the intermediate layer is higher than an energy level at T1 level of the second light emitting layer, and an energy level at S1 level of the intermediate layer is higher than an energy level at S1 level of the first light emitting layer.

(4)

The light emitting device according to (2) or (3), in which
the first light emitting layer has blue as an emission color, and
the second light emitting layer has yellow as an emission color.

(5)

The light emitting device according to (2) or (3), in which
the first light emitting layer has blue as an emission color, and
the second light emitting layer has a stack structure that includes a green phosphorescent light emitting layer having green as an emission color, and a red phosphorescent light emitting layer having red as an emission color.

(6)

The light emitting device according to (1), in which
the organic layer includes a first light emitting layer and a second light emitting layer as a plurality of types of the light emitting layers, and includes, as the plurality of functional layers, a hole injection layer, a hole transport layer, the first light emitting layer, an intermediate layer, the second light emitting layer, an electron transport layer, and an electron injection layer in order from a side closer to the first electrode, and
the mixing layer includes a layer in which a component forming at least part of the first light emitting layer and a component forming at least part of the intermediate layer are mixed.

(7)

The light emitting device according to (6), in which
the first light emitting layer and the second light emitting layer are fluorescent light emitting layers having different emission colors from each other, and,
in the intermediate layer, an energy level at S1 level of the intermediate layer is higher than an energy level at S1 level of the second light emitting layer.

(8)

The light emitting device according to (6) or (7), in which
the first light emitting layer has red as an emission color, and
the second light emitting layer has blue as an emission color.

(9)

The light emitting device according to (6) or (7), in which
the first light emitting layer has red as an emission color, and
the second light emitting layer has a stack structure that includes a green fluorescent light emitting layer having green as an emission color, and a blue fluorescent light emitting layer having blue as an emission color.

(10)

The light emitting device according to any one of (1) to (9), in which
an insulating structure is provided between the first electrode and the organic layer, and
the insulating structure is formed in a columnar shape.

(11)

The light emitting device according to any one of (1) to (9), in which
an insulating structure is provided between the first electrode and the organic layer, and
the insulating structure is formed in a shape extending in a plane direction of the first electrode.

(12)

The light emitting device according to (11), further including
a counter region for the first electrode and the organic layer, in which
the insulating structure is formed in a shape extending in a plurality of directions intersecting each other in a plane direction of the first electrode, and is formed to divide the counter region in a plan view of the substrate.

(13)

The light emitting device according to (11) or (12), further including
an insulating layer covering a periphery of the first electrode, in which
an end portion of the insulating structure in a longitudinal direction of the insulating structure is joined to the insulating layer.

(14)

The light emitting device according to any one of (1) to (13), further including
a plurality of sub-pixels corresponding to a plurality of color types, in which
each of the sub-pixels includes the substrate, the first electrode, the organic layer, and the second electrode, and
the mixing layer is formed in the sub-pixel corresponding to at least one color type.

(15)

The light emitting device according to (14), in which
each of the sub-pixels has a light emitting region, and,
in a case where a region in which the mixing layer is formed in the light emitting region is defined as a mixing region, and a proportion of the mixing region in the light emitting region is defined as an occupancy rate of the mixing region,
the sub-pixel corresponding to at least one color type has a first occupancy rate as the occupancy rate, and
the sub-pixel corresponding to at least another color type has a second occupancy rate as the occupancy rate, the second occupancy rate being different from the first occupancy rate.

(16)

The light emitting device according to (15), in which
an insulating structure is provided between the first electrode and the organic layer at least in the sub-pixel having the first occupancy rate,
the insulating structure is formed in a columnar shape, and
a number and a pitch of the insulating structures are determined in accordance with the first occupancy rate.

(17)

The light emitting device according to (15), in which
an insulating structure is provided between the first electrode and the organic layer at least in the sub-pixel having the first occupancy rate,
a counter region for the first electrode and the organic layer is provided,
the insulating structure is formed in a shape extending in a plurality of directions intersecting each other in a plane direction of the first electrode, and is formed to divide the counter region in a plan view of the substrate, and
a number of divisions of the counter region is determined in accordance with the first occupancy rate.

(18)

The light emitting device according to any one of (1) to (17), in which
an insulating structure is provided between the first electrode and the organic layer, and
the insulating structure has a structure in which a silicon nitride layer and a silicon oxide layer are stacked.

(19)

The light emitting device according to any one of (1) to (18), further including
an insulating layer covering a periphery of the first electrode, in which
an insulating structure is provided between the first electrode and the organic layer, and
the insulating structure includes the same material as the insulating layer.

(20)

The light emitting device according to any one of (1) to (19), in which,
in a case where a region in which a mixing portion is formed is set as the mixing region,
the mixing region is formed in an annular shape, and
a width of the mixing region is 0.5 μm or greater.

(21)

The light emitting device according to any one of (1) to (20), in which
an insulating structure is provided between the first electrode and the organic layer, and
a height of the insulating structure exceeds 15 nm.

(22)

The light emitting device according to (1), further including
a plurality of sub-pixels corresponding to a plurality of color types, in which
each of the sub-pixels includes the substrate, the first electrode, the organic layer, and the second electrode, and has a light emitting region, and
the mixing layer is formed in the sub-pixel corresponding to at least one color type, and,
in the light emitting region of the sub-pixel including the mixing layer, in a case where a region in which the mixing layer is formed is set as a mixing region, and a region excluding the mixing region is set as a non-mixing region, an emission color of the mixing region and an emission color of the non-mixing region are different.

(23)

The light emitting device according to (22), in which
at least one type of the plurality of sub-pixels includes a color conversion layer that converts a color of light generated in the organic layer.

(24)

The light emitting device according to (23), in which,
in a case where the sub-pixel including the color conversion layer among the plurality of sub-pixels is set as a first sub-pixel, and the sub-pixels other than the first sub-pixel are set as second sub-pixels,
the mixing layer is formed in the first sub-pixel and at least one of the second sub-pixels, and,
in a case where a proportion of the mixing region in the light emitting region is defined as an occupancy rate of the mixing region, the occupancy rate determined for the first sub-pixel and the occupancy rate determined for the at least one of the second sub-pixels in which the mixing layer is formed are different from each other.

(25)

The light emitting device according to (24), in which
the organic layer has a structure in which the plurality of functional layers including a plurality of types of the light emitting layers having different color types is stacked,
the plurality of types of the light emitting layers is common to a plurality of types of the sub-pixels, color types of the light emitting layers are blue and green, and
the color conversion layer is a layer that emits green light.

(26)

The light emitting device according to (25), in which
at least one type of a plurality of the sub-pixels is a red sub-pixel having red as an emission color, and
the red sub-pixel is the first sub-pixel, and includes a red-color conversion layer as the color conversion layer, the red-color conversion layer converting a color of light generated in the organic layer into red.

(27)

The light emitting device according to (22), in which
the organic layer has a structure in which the plurality of functional layers including a plurality of types of the light emitting layers having different color types is stacked,
the plurality of types of the light emitting layers is common to a plurality of types of the sub-pixels,
color types of the light emitting layers are blue and red, and
the color conversion layer is a layer that emits green light.

(28)

The light emitting device according to (27), in which
at least one type of a plurality of the sub-pixels is a green sub-pixel having green as an emission color, and
the green sub-pixel includes a green-color conversion layer that converts a color of light generated in the organic layer into green.

(29)

The light emitting device according to (27) or (28), in which
a blue sub-pixel having blue as an emission color and a red sub-pixel having red an emission color are provided as a plurality of the sub-pixels,
the color conversion layer is a layer that emits green light, and
a color of light generated in the mixing region is stronger in blue than a color of light generated in the non-mixing region,
the color of the light generated in the non-mixing region is stronger in red than the color of the light generated in the mixing region, and,
in a case where a proportion of the mixing region in the light emitting region is set as an occupancy rate of the mixing region, the occupancy rate in the blue sub-pixel is higher than the occupancy rate in the red sub-pixel.

(30)

The light emitting device according to any one of (27) to (29), in which
a blue sub-pixel having blue as an emission color and a red sub-pixel having red an emission color are provided as a plurality of the sub-pixels,
the color conversion layer is a layer that emits green light, and
a color of light generated in the mixing region is stronger in red than a color of light generated in the non-mixing region,
the color of the light generated in the non-mixing region is stronger in blue than the color of the light generated in the mixing region, and,
in a case where a proportion of the mixing region in the light emitting region is set as an occupancy rate of the mixing region, the occupancy rate in the red sub-pixel is higher than the occupancy rate in the blue sub-pixel.

(31)

An electronic apparatus including
the display element according to any one of (1) to (30).

### REFERENCE SIGNS LIST

10 Display device
10A Display region
10B Outer region
11 Drive substrate
12 Insulating layer
12A Opening
13 First electrode
14 Organic layer
15 Second electrode
16 Protective layer
17 Color filter
18 Filling resin layer
19 Counter substrate
51 Mixing layer
52 Mixing portion
53 Non-mixing portion
53A First portion
55 Insulating structure
100 Pixel
104 Light emitting element
140 Hole injection layer
141 Hole transport layer
142 Light emitting layer
142A First light emitting layer
142B Second light emitting layer
143 Electron transport layer
144 Electron injection layer
145 Intermediate layer
M1 Mixing region
M2 Non-mixing light emitting region
M3 No-light emitting region

1. A light emitting device comprising:
a substrate; and
a first electrode, an organic layer, and a second electrode that are sequentially stacked on the substrate, wherein
the organic layer includes a plurality of functional layers including a plurality of types of light emitting layers of different color types, and,
in a case where a thickness direction of the substrate is set as a line-of-sight direction, a mixing layer is formed in at least a portion of the organic layer, the portion extending in a plane direction of the organic layer, the mixing layer being defined in accordance with the following conditions:
in a case where a first position and a second position in the organic layer are selected as two positions different in the plane direction of the organic layer, and components of the organic layer at the first position and the second position are compared in a thickness direction of the organic layer, a layer in which components of the plurality of different functional layers forming the organic layer are mixed, and which is recognized only at one of the first position or the second position is determined as the mixing layer.

2. The light emitting device according to claim 1, wherein
the organic layer includes a first light emitting layer and a second light emitting layer as a plurality of types of the light emitting layers, and includes, as the plurality of functional layers, a hole injection layer, a hole transport layer, the first light emitting layer, an intermediate layer, the second light emitting layer, an electron transport layer, and an electron injection layer in order from a side closer to the first electrode, and
the mixing layer includes a layer in which a component forming at least part of the second light emitting layer and a component forming at least part of the electron transport layer are mixed.

3. The light emitting device according to claim 2, wherein
the first light emitting layer includes a fluorescent light emitting layer,
the second light emitting layer includes a phosphorescent light emitting layer, and,
in the intermediate layer, an energy level at T1 level of the intermediate layer is higher than an energy level at T1 level of the second light emitting layer, and an energy level at S1 level of the intermediate layer is higher than an energy level at S1 level of the first light emitting layer.

4. The light emitting device according to claim 2, wherein
the first light emitting layer has blue as an emission color, and
the second light emitting layer has yellow as an emission color.

5. The light emitting device according to claim 2, wherein
the first light emitting layer has blue as an emission color, and
the second light emitting layer has a stack structure that includes a green phosphorescent light emitting layer having green as an emission color, and a red phosphorescent light emitting layer having red as an emission color.

6. The light emitting device according to claim 1, wherein
the organic layer includes a first light emitting layer and a second light emitting layer as a plurality of types of the light emitting layers, and includes, as the plurality of functional layers, a hole injection layer, a hole transport layer, the first light emitting layer, an intermediate layer, the second light emitting layer, an electron transport layer, and an electron injection layer in order from a side closer to the first electrode, and
the mixing layer includes a layer in which a component forming at least part of the first light emitting layer and a component forming at least part of the intermediate layer are mixed.

7. The light emitting device according to claim 6, wherein
the first light emitting layer and the second light emitting layer are fluorescent light emitting layers having different emission colors from each other, and,
in the intermediate layer, an energy level at S1 level of the intermediate layer is higher than an energy level at S1 level of the second light emitting layer.

8. The light emitting device according to claim 6, wherein
the first light emitting layer has red as an emission color, and
the second light emitting layer has blue as an emission color.

9. The light emitting device according to claim 6, wherein
the first light emitting layer has red as an emission color, and
the second light emitting layer has a stack structure that includes a green fluorescent light emitting layer having green as an emission color, and a blue fluorescent light emitting layer having blue as an emission color.

10. The light emitting device according to claim 1, wherein
an insulating structure is provided between the first electrode and the organic layer, and
the insulating structure is formed in a columnar shape.

11. The light emitting device according to claim 1, wherein
an insulating structure is provided between the first electrode and the organic layer, and
the insulating structure is formed in a shape extending in a plane direction of the first electrode.

12. The light emitting device according to claim 11, further comprising
a counter region for the first electrode and the organic layer, wherein
the insulating structure is formed in a shape extending in a plurality of directions intersecting each other in a plane direction of the first electrode, and is formed to divide the counter region in a plan view of the substrate.

13. The light emitting device according to claim 11, further comprising
an insulating layer covering a periphery of the first electrode, wherein
an end portion of the insulating structure in a longitudinal direction of the insulating structure is joined to the insulating layer.

14. The light emitting device according to claim 1, further comprising
a plurality of sub-pixels corresponding to a plurality of color types, wherein
each of the sub-pixels includes the substrate, the first electrode, the organic layer, and the second electrode, and
the mixing layer is formed in the sub-pixel corresponding to at least one color type.

15. The light emitting device according to claim 14, wherein
each of the sub-pixels has a light emitting region, and,
in a case where a region in which the mixing layer is formed in the light emitting region is defined as a mixing region, and a proportion of the mixing region in the light emitting region is defined as an occupancy rate of the mixing region,
the sub-pixel corresponding to at least one color type has a first occupancy rate as the occupancy rate, and
the sub-pixel corresponding to at least another color type has a second occupancy rate as the occupancy rate, the second occupancy rate being different from the first occupancy rate.

16. The light emitting device according to claim 15, wherein
an insulating structure is provided between the first electrode and the organic layer at least in the sub-pixel having the first occupancy rate,
the insulating structure is formed in a columnar shape, and
a number and a pitch of the insulating structures are determined in accordance with the first occupancy rate.

17. The light emitting device according to claim 15, wherein
an insulating structure is provided between the first electrode and the organic layer at least in the sub-pixel having the first occupancy rate,
a counter region for the first electrode and the organic layer is provided,
the insulating structure is formed in a shape extending in a plurality of directions intersecting each other in a plane direction of the first electrode, and is formed to divide the counter region in a plan view of the substrate, and
a number of divisions of the counter region is determined in accordance with the first occupancy rate.

18. The light emitting device according to claim 1, wherein
an insulating structure is provided between the first electrode and the organic layer, and
the insulating structure has a structure in which a silicon nitride layer and a silicon oxide layer are stacked.

19. The light emitting device according to claim 1, further comprising
an insulating layer covering a periphery of the first electrode, wherein
an insulating structure is provided between the first electrode and the organic layer, and
the insulating structure includes the same material as the insulating layer.

20. The light emitting device according to claim 1, further comprising
a plurality of sub-pixels corresponding to a plurality of color types, wherein
each of the sub-pixels includes the substrate, the first electrode, the organic layer, and the second electrode, and has a light emitting region, and
the mixing layer is formed in the sub-pixel corresponding to at least one color type, and,
in the light emitting region of the sub-pixel including the mixing layer, in a case where a region in which the mixing layer is formed is set as a mixing region, and a region excluding the mixing region is set as a non-mixing region, an emission color of the mixing region and an emission color of the non-mixing region are different.

21. The light emitting device according to claim 20, wherein
at least one type of the plurality of sub-pixels includes a color conversion layer that converts a color of light generated in the organic layer.

22. The light emitting device according to claim 21, wherein,
in a case where the sub-pixel including the color conversion layer among the plurality of sub-pixels is set as a first sub-pixel, and the sub-pixels other than the first sub-pixel are set as second sub-pixels,
the mixing layer is formed in the first sub-pixel and at least one of the second sub-pixels, and,
in a case where a proportion of the mixing region in the light emitting region is defined as an occupancy rate of the mixing region, the occupancy rate determined for the first sub-pixel and the occupancy rate determined for the at least one of the second sub-pixels in which the mixing layer is formed are different from each other.

23. The light emitting device according to claim 22, wherein
the organic layer has a structure in which the plurality of functional layers including a plurality of types of the light emitting layers having different color types is stacked,
the plurality of types of the light emitting layers is common to a plurality of types of the sub-pixels, and
color types of the light emitting layers are blue and green.

24. The light emitting device according to claim 23, wherein
at least one type of a plurality of the sub-pixels is a red sub-pixel having red as an emission color, and
the red sub-pixel is the first sub-pixel, and includes a red-color conversion layer as the color conversion layer, the red-color conversion layer converting a color of light generated in the organic layer into red.

25. The light emitting device according to claim 20, wherein
the organic layer has a structure in which the plurality of functional layers including a plurality of types of the light emitting layers having different color types is stacked,
the plurality of types of the light emitting layers is common to a plurality of types of the sub-pixels,
color types of the light emitting layers are blue and red, and
the color conversion layer is a layer that emits green light.

26. The light emitting device according to claim 25, wherein
at least one type of a plurality of the sub-pixels is a green sub-pixel having green as an emission color, and
the green sub-pixel includes a green-color conversion layer that converts a color of light generated in the organic layer into green.

27. The light emitting device according to claim 25, wherein
a blue sub-pixel having blue as an emission color and a red sub-pixel having red an emission color are provided as a plurality of the sub-pixels,
the color conversion layer is a layer that emits green light, and
a color of light generated in the mixing region is stronger in blue than a color of light generated in the non-mixing region,
the color of the light generated in the non-mixing region is stronger in red than the color of the light generated in the mixing region, and,
in a case where a proportion of the mixing region in the light emitting region is set as an occupancy rate of the mixing region, the occupancy rate in the blue sub-pixel is higher than the occupancy rate in the red sub-pixel.

28. The light emitting device according to claim 25, wherein
a blue sub-pixel having blue as an emission color and a red sub-pixel having red an emission color are provided as a plurality of the sub-pixels,
the color conversion layer is a layer that emits green light, and
a color of light generated in the mixing region is stronger in red than a color of light generated in the non-mixing region,
the color of the light generated in the non-mixing region is stronger in blue than the color of the light generated in the mixing region, and,
in a case where a proportion of the mixing region in the light emitting region is set as an occupancy rate of the mixing region, the occupancy rate in the red sub-pixel is higher than the occupancy rate in the blue sub-pixel.

29. An electronic apparatus comprising
the display element according to claim 1.
